(19) United States
(12) Patent Application Publication
(10) Pub. No.: US 2026/0003273 A1
(43) Pub. Date: Jan. 1, 2026

(54) METHOD FOR MANUFACTURING CURED FILM

(71) Applicant: FUJIFILM Corporation, Tokyo (JP)

(72) Inventors: Hiroaki Idei, Shizuoka (JP); Norifumi Yokoyama, Shizuoka (JP)

(73) Assignee: FUJIFILM Corporation, Tokyo (JP)

(21) Appl. No.: 19/322,619

(22) Filed: Sep. 8, 2025

Related U.S. Application Data
(63) Continuation of application No. PCT/JP2024/009782, filed on Mar. 13, 2024.

(30) Foreign Application Priority Data
Mar. 31, 2023 (JP) 2023-058728

(51) Int. Cl. G03F 7/033; G03F 7/00; G03F 7/40

(52) U.S. Cl. CPC G03F 7/033; G03F 7/0007; G03F 7/40

(57) ABSTRACT

The present invention provides a method for manufacturing a cured film, in which positioning of a mask during exposure is easily performed and antireflection characteristics of the cured film to be obtained are excellent. The method for manufacturing a cured film of the present invention includes a step 1 of forming a curable composition layer on a support, a step 2 of performing registration between the support and an exposure mask, a step 3 of exposing the curable composition layer through the exposure mask, a step 4 of performing a development treatment on the curable composition layer after the exposure to form a cured film in a patterned shape, and a step 5 of performing a heating treatment on the patterned cured film, in which the curable composition contains a resin A, a resin B, and a polymerizable compound, an HSP distance between the resin A and the resin B is more than 1.5 MPa^{1/2}, and an HSP distance (A) between the resin A and the polymerizable compound is larger than an HSP distance (B) between the resin B and the polymerizable compound.

### CROSS-REFERENCE TO RELATED APPLICATIONS

This application is a Continuation of PCT International Application No. PCT/JP2024/009782 filed on Mar. 13, 2024, which claims priority under 35 U.S.C. § 119(a) to Japanese Patent Application No. 2023-058728 filed on Mar. 31, 2023. The above applications are hereby expressly incorporated by reference, in their entirety, into the present application.

### BACKGROUND OF THE INVENTION

### 1. Field of the Invention

The present invention relates to a method for manufacturing a cured film.

### 2. Description of the Related Art

In an image display apparatus such as a liquid crystal display device and in a solid-state imaging device such as a charge coupled device (CCD) image sensor and a complementary metal-oxide semiconductor (CMOS) image sensor, a color filter or a light shielding film is often disposed at a predetermined position. For example, in the liquid crystal display device, a light shielding film called a black matrix may be disposed between colored pixels on a color filter for the purpose of shielding light between the colored pixels and improving contrast. In addition, in the solid-state imaging element, a light shielding film may be applied for the purpose of preventing noise generation, improving image quality, and the like.

JP2011-145663A discloses that a light shielding film can be formed from a composition containing predetermined components, such as inorganic particles.

### SUMMARY OF THE INVENTION

One of methods of forming a light shielding film in a patterned manner is a method of forming a layer of a resist composition on a support such as a substrate, performing an exposure treatment through an exposure mask, and then performing a development treatment. Here, in a case of performing the above-described exposure treatment, an operation of performing registration of aligning a reference position between the exposure mask and the support, which is called alignment, is required.

In addition, as one of characteristics required for the light shielding film, it is also required to have excellent antireflection characteristics (low reflection properties).

As a result of attempting to form a light shielding film using the composition described in JP2011-145663A, the present inventors have found that, although the registration of the exposure mask using an alignment mark or the like is possible, a cured film to be obtained has insufficient antireflection characteristics (low reflection properties).

On the other hand, in a case where an attempt is made to form unevenness on a surface in order to improve the antireflection characteristics of the cured film, the unevenness is formed on the surface even in a state of a coating film before curing, and as a result, there is a problem that it is difficult to perform the registration on the exposure mask.

Therefore, an object of the present invention is to provide a method for manufacturing a cured film, in which positioning of a mask during exposure is easily performed and antireflection characteristics of the cured film to be obtained are excellent.

As a result of conducting an extensive investigation to achieve the objects, the present inventors have found that the objects can be achieved by the following constitution.

[1]A method for manufacturing a cured film, comprising:
a step 1 of forming a curable composition layer on a support;
a step 2 of performing registration between the support and an exposure mask;
a step 3 of exposing the curable composition layer through the exposure mask;
a step 4 of performing a development treatment on the curable composition layer after the exposure to form a cured film in a patterned shape; and
a step 5 of performing a heating treatment on the patterned cured film,
in which the curable composition contains a resin A, a resin B, and a polymerizable compound,
an HSP distance between the resin A and the resin B is more than 1.5 MPa^{1/2}, and
an HSP distance (A) between the resin A and the polymerizable compound is larger than an HSP distance (B) between the resin B and the polymerizable compound.

[2] The method for manufacturing a cured film according to [1],
in which at least one of a glass transition temperature of the resin A or a glass transition temperature of the resin B is a temperature lower than a heating temperature during the heating treatment by 120° C. or higher.

[3] The method for manufacturing a cured film according to [1] or [2],
in which a glass transition temperature of the resin B is 0° C. to 70° C.

[4] The method for manufacturing a cured film according to any one of [1] to [3],
in which the resin A contains a repeating unit A1 having an acid group and a repeating unit A2 having at least one group of a polyoxyalkylene group having an average addition number of 3 or more or a polyoxyalkylene carbonyl group having an average addition number of 3 or more,
a content of the repeating unit A2 is 35% by mass or more with respect to all repeating units of the resin A,
the resin B contains a repeating unit B1 derived from a monomer selected from the group consisting of an alkyl acrylate and an alkyl methacrylate, a repeating unit B2 having a hydroxyl group, and a repeating unit B3 having a carboxylic acid group, and
a content of the repeating unit B1 is 60% by mass or more with respect to all repeating units of the resin B.

[5] The method for manufacturing a cured film according to any one of [1] to [4], in which an acid value of the resin A is 50 mgKOH/g or more.

[6] The method for manufacturing a cured film according to any one of [1] to [5],
in which a shrinkage ratio of the polymerizable compound, which is defined by an expression (X), is 7% or more,

$$( 1 - ρ M / ρ P ) \times 100 … the expression ( X ) ,$$

in the expression (X),
ρM represents a specific gravity of the polymerizable compound measured in accordance with JIS-K-2249, and
ρP represents a specific gravity of a cured substance of the polymerizable compound measured in accordance with JIS-K-2249.

[7] The method for manufacturing a cured film according to any one of [1] to [6],
in which the curable composition further contains a coloring material.

[8] The method for manufacturing a cured film according to [7],
in which the coloring material includes a black coloring material.

[9] The method for manufacturing a cured film according to [8],
in which the black coloring material includes a black organic pigment.

[10]A method for manufacturing a cured film, comprising:
a step 11 of forming a curable composition layer on a support;
a step 12 of performing registration between the support and an exposure mask;
a step 13 of exposing the curable composition layer through the exposure mask; and
a step 14 of performing a development treatment on the curable composition layer after the exposure to form a cured film in a patterned shape,
in which the curable composition contains a resin C, a resin H, and a polymerizable compound,
an HSP distance between the resin C and the resin H is more than 1.5 MPa^{1/2}, and
a ratio T2/T1 of a dissolution rate T2 of the resin H in a developer used in the development treatment to a dissolution rate T1 of the resin C in the developer is 10.0 or more.

[11] The method for manufacturing a cured film according to [10],
in which the resin C contains a repeating unit C1 having an acid group and a repeating unit C2 having at least one group of a polyoxyalkylene group having an average addition number of 3 or more or a polyoxyalkylene carbonyl group having an average addition number of 3 or more,
a content of the repeating unit C2 is 35% by mass or more with respect to all repeating units of the resin C,
the resin H is an acrylic resin or a methacrylic resin, and
an acid value of the resin H is higher than an acid value of the resin C by 70 mgKOH/g or more.

[12] The method for manufacturing a cured film according to [10] or [11],
in which an acid value of the resin C is 50 mgKOH/g or more.

[13] The method for manufacturing a cured film according to any one of [10] to [12],
in which an acid value of the resin H is 140 mgKOH/g or more.

[14] The method for manufacturing a cured film according to any one of [10] to [13],
in which the curable composition further contains a coloring material.

[15] The method for manufacturing a cured film according to [14],
in which the coloring material includes a black coloring material.

[16] The method for manufacturing a cured film according to [15],
in which the black coloring material includes a black organic pigment.

According to the present invention, it is possible to provide a method for manufacturing a cured film, in which positioning of a mask during exposure is easily performed and antireflection characteristics of the cured film to be obtained are excellent.

### BRIEF DESCRIPTION OF THE DRAWINGS

FIG. 1 is a schematic plan view showing a configuration example of an alignment mark.

FIG. 2 is a schematic cross-sectional view taken along a line A-A in FIG. 1.

### DESCRIPTION OF THE PREFERRED EMBODIMENTS

Hereinafter, the present invention will be described in detail.

The description of the configuration requirements described below is made on the basis of representative embodiments of the present invention, but it should not be construed that the present invention is limited to those embodiments.

Hereinafter, meaning of each description in the present specification will be explained.

In the present specification, a numerical range represented by “to” means a range including numerical values before and after “to” as a lower limit value and an upper limit value.

A compound described in the present specification may include a structural isomer, an optical isomer, and an isotope unless otherwise specified. In addition, one kind of structural isomer, optical isomer, and isotope may be included, or two or more kinds thereof may be included.

In the present specification, with regard to a bonding direction of a divalent group (for example, —COO—), unless otherwise specified, in a case where Y in a compound represented by “X—Y—Z” is —COO—, the compound may be “X—O—CO—Z” or “X—CO—O—Z”.

In the present specification, regarding the description of a group (atomic group), in a case where whether the group is substituted or unsubstituted is not described, the group includes a group which has a substituent as well as a group which does not have a substituent. For example, an “alkyl group” includes not only an alkyl group (unsubstituted alkyl group) which does not have a substituent but also an alkyl group (substituted alkyl group) which has a substituent.

In addition, in the present specification, “actinic rays” or “radiations” refers to, for example, far ultraviolet rays, extreme ultraviolet rays (EUV: extreme ultraviolet lithography), X-rays, electron beams, and the like. In addition, “light” in the present specification means actinic rays and radiations. In the present specification, unless otherwise specified, “exposure” includes not only exposure with far ultraviolet rays, X-rays, EUV light, or the like but also drawing by particle beams such as electron beams and ion beams.

In the present specification, “(meth)acrylate” represents acrylate and methacrylate. In the present specification, “(meth)acryl” represents acryl and methacryl. In the present specification, “(meth)acryloyl” represents acryloyl and methacryloyl. In the present specification, “(meth)acrylamide” represents acrylamide and methacrylamide. In the present specification, a “monomeric substance” and a “monomer” have the same definition.

In the present specification, a weight-average molecular weight (Mw) is a value in terms of polystyrene, as measured by a gel permeation chromatography (GPC) method.

In the present specification, the GPC method is based on a method in which HLC-8020 GPC (manufactured by TOSOH CORPORATION) is used, TSKgel SuperHZM-H, TSKgel SuperHZ4000, and TSKgel SuperHZ2000 (manufactured by TOSOH CORPORATION, 4.6 mm ID×15 cm) are used as columns, and tetrahydrofuran (THF) is used as an eluent.

In the present specification, “acid value” can be calculated, for example, from the average content of acid groups in the compound.

In the present specification, a solid content in a composition means a composition layer formed of the composition, and in a case where the composition includes a solvent, the solid content means all components except the solvent. In addition, in a case where the components are components which form a composition layer, the components are considered to be solid contents even in a case where the components are liquid components.

Hereinafter, the method for manufacturing a cured film according to the present invention will be described in detail.

A first embodiment of the method for manufacturing a cured film according to the present invention (hereinafter, also referred to as “present manufacturing method”) is a method for manufacturing a cured film, including a step 1 of forming a curable composition layer on a support, a step 2 of performing registration between the support and an exposure mask, a step 3 of exposing the curable composition layer through the exposure mask, a step 4 of performing a development treatment on the curable composition layer after the exposure to form a cured film in a patterned shape, and a step 5 of performing a heating treatment on the patterned cured film, in which the curable composition contains a resin A, a resin B, and a polymerizable compound, an HSP distance between the resin A and the resin B is more than 1.5 MPa^{1/2}, and an HSP distance (A) between the resin A and the polymerizable compound is larger than an HSP distance (B) between the resin B and the polymerizable compound.

In addition, a second embodiment of the method for manufacturing a cured film according to the present invention is a method for manufacturing a cured film, including a step 11 of forming a curable composition layer on a support, a step 12 of performing registration between the support and an exposure mask, a step 13 of exposing the curable composition layer through the exposure mask, and a step 14 of performing a development treatment on the curable composition layer after the exposure to form a cured film in a patterned shape, in which the curable composition contains a resin C, a resin H, and a polymerizable compound, an HSP distance between the resin C and the resin H is more than 1.5 MPa^{1/2}, and a ratio T2/T1 of a dissolution rate T2 of the resin H in a developer used in the development treatment to a dissolution rate T1 of the resin C in the developer is 10.0 or more.

The mechanism by which the object of the present invention can be achieved by adopting the above-described configuration in the method for manufacturing a cured film according to the embodiment of the present invention (the first embodiment or the second embodiment) is not necessarily clear, but the present inventors have presumed as follows.

The mechanism by which the effect is obtained is not limited by the following supposition. In other words, even in a case where an effect is obtained by a mechanism other than the following, it is included in the scope of the present invention.

The curable composition used in the first embodiment is characterized in that the HSP distance between the resin A and the resin B is more than 1.5 MPa^{1/2}, and the HSP distance (A) between the resin A and the polymerizable compound is larger than the HSP distance (B) between the resin B and the polymerizable compound.

Since the HSP distance between the resin A and the resin B is more than 1.5 MPa^{1/2}, due to a difference in compatibility between the resin A and the resin B, a phase-separated structure (for example, a sea-island structure, a co-continuous structure, and a structure in which a sea-island structure and a co-continuous structure coexist) is generated in the curable composition layer, and a fine uneven structure can be formed on the cured film by the heating treatment in the step 5.

In addition, since the HSP distance (A) between the resin A and the polymerizable compound is larger than the HSP distance (B) between the resin B and the polymerizable compound, it is presumed that affinity between the resin B and the polymerizable compound is higher than affinity between the resin A and the polymerizable compound. As a result, the polymerizable compound is likely to be locally present in the sea portion or the island portion in the curable composition layer, the above-described uneven structure can be more effectively formed by curing shrinkage of the polymerizable compound in the step 5, and thus low reflection properties of the cured film can be further enhanced.

Here, the uneven structure based on the above-described phase-separated structure is not exhibited in the registration in the step 2, and does not interfere with visibility of the alignment mark or the like, so that positioning of the mask during the exposure can be easily performed.

In addition, similarly to the first embodiment, the curable composition used in the second embodiment is characterized in that, in addition to the feature point of the HSP distance between the resin C and the resin H, the ratio T2/T1 of the dissolution rate T2 of the resin H in the developer used in the development treatment to the dissolution rate T1 of the resin C in the developer is 10.0 or more.

As in the above-described case, the phase-separated structure is generated in the curable composition layer due to a difference in compatibility between the resin C and the resin H. In the above-described structure, in a case of the development treatment in the step 14, since the above-described ratio of T2/T1 is large, the resin H is easily developed with respect to the resin C, and thus a fine uneven structure is easily formed on the cured film, and a cured film having excellent low reflection properties is obtained.

In the second embodiment as well, the above-described uneven structure is not exhibited in the registration in the step 12, and does not interfere with visibility of the alignment mark or the like, so that positioning of the mask during the exposure can be easily performed.

Hereinafter, the fact that at least one of the effect of easily performing the registration between the support and the exposure mask during the exposure or the effect of excellent antireflection characteristics (low reflection properties) of the cured film after carrying out all the steps of the present manufacturing method is obtained is also referred to as “effect of the present invention is more excellent”.

Hereinafter, the first embodiment of the method for manufacturing a cured film according to the present invention (hereinafter, also referred to as “present manufacturing method”) will be described in detail.

### [[Method for Manufacturing Cured Film (First Embodiment)]]

The first embodiment of the present manufacturing method includes the step 1 to the step 5. Hereinafter, each of the steps will be described in detail.

### Step 1

Hereinafter, the curable composition used in the step 1 (hereinafter, also referred to as “curable composition 1”) and the procedure will be described in detail.

### [Curable Composition 1]

The curable composition 1 contains a resin A, a resin B, and a polymerizable compound. In addition, an HSP distance between the resin A and the resin B is more than 1.5 MPa^{1/2}, and an HSP distance (A) between the resin A and the polymerizable compound is larger than an HSP distance (B) between the resin B and the polymerizable compound.

The Hansen solubility parameters (HSP) are a kind of solubility parameters expressed by three components of a dispersion element (δ_{d}), a polarity element (δₚ), and a hydrogen bond element (δₕ).

In addition, the HSP distance is a parameter corresponding to a distance between coordinates of two different substances in a case where a point (δ_{d}, δₚ, or δₕ) in a three-dimensional space with three components of HSP of a certain substance as coordinates is considered. It can be estimated that, as the HSP distance is smaller, the affinity between the two substances is higher.

Since the HSP distance between the resin A and the resin B is more than 1.5 MPa^{1/2}, due to a difference in compatibility between the resin A and the resin B, a phase-separated structure (for example, a sea-island structure, a co-continuous structure, and a structure in which a sea-island structure and a co-continuous structure coexist) is generated in the curable composition layer, and a fine uneven structure can be formed on the cured film in the step 5 described later, resulting in a cured film with excellent low reflection properties.

In addition, since the HSP distance (A) between the resin A and the polymerizable compound is larger than the HSP distance (B) between the resin B and the polymerizable compound, it is presumed that affinity between the resin B and the polymerizable compound is higher than affinity between the resin A and the polymerizable compound. As a result, the polymerizable compound is likely to be locally present in the sea portion or the island portion in the curable composition layer, the above-described uneven structure can be more effectively formed by curing shrinkage of the polymerizable compound, and thus low reflection properties of the cured film can be further enhanced.

In a case where HSP of a first substance are δ_{d1}, δₚ₁, and δₕ₁, and HSP of the second substance are δ_{d2}, δₚ₂, and δₕ₂, an HSP distance between the first substance and the second substance can be calculated by an expression (2).

$$HSP distance = \sqrt{4 {( {δ}_{d 2} - {δ}_{d 1} )}^{2} + {( {δ}_{p 2} - {δ}_{p 1} )}^{2} + {( {δ}_{h 2} - {δ}_{h 1} )}^{2}} \qquad Expression ( 2 )$$

Here, the HSP can be uniquely calculated from chemical structures of the components at 25° C. by using the computer software Hansen Solubility Parameter in Practice (HSPiP) (http://www.hansen-solubility.com).

In the present invention, HSPiP ver. 5.4.08 (product sold by Video Workshop Question Co., Ltd.) is used to calculate the HSP distance between the respective components by calculating values of the dispersion element (δ_{d}), the polarity element (δₚ), and the hydrogen bond element (δₕ) of each component at 25° C.

The Hansen solubility parameters of the resin A and the resin B are calculated based on repeating units of each resin.

Specifically, three components of a dispersion element (δ_{d}), a polarity element (δₚ), and a hydrogen bond element (δₕ) of each repeating unit of the resin are obtained, and a mass fraction of each repeating unit is multiplied by each of these components and summed to calculate the dispersion element (δ_{d}), the polarity element (δₚ), and the hydrogen bond element (δₕ) of the resin.

For example, in a case where a resin has n kinds of repeating units, a hydrogen bond element (δₕ) of the resin can be calculated by using an equation (H) with a hydrogen bond element (δₕ) of a j-th (j is an integer of 1 or more) repeating unit of the resin and a mass fraction Nj of the j-th repeating unit with respect to all repeating units.

$$Hydrogen bond element ( {δ}_{h} ) = \sum δ PjNj \qquad ( H )$$

More specifically, for example, a case where a resin includes a first repeating unit having a hydrogen bond element of 4.0 MPa^{1/2} and a second repeating unit having a hydrogen bond element of 7.0 MPa^{1/2}, a content of the first repeating unit is 30% by mass with respect to all the repeating units of the first polymer, and a content of the second repeating unit is 70% by mass with respect to all the repeating units of the first polymer will be examined. In this case, a hydrogen bond element of the resin is calculated as 4.0×0.3+7.0×0.7=6.1 MPa^{1/2}.

In the above description, the hydrogen bond element (δₕ) has been described, but the dispersion element (δ_{d}) and the polarity element (δₚ) of the resin can also be calculated according to the same procedure.

In the calculation of the dispersion element (δ_{d}), the polarity element (δₚ), and the hydrogen bond element (δₕ) of each repeating unit, a value calculated using the above-described method can be used for a compound in which the terminal of each repeating unit structure is substituted with a hydrogen atom. Specifically, for example, as a dispersion element (δ_{d}), a polarity element (δₚ), and a hydrogen bond element (δₕ) of a repeating unit derived from methyl methacrylate, a dispersion element (δ_{d}), a polarity element (δₚ), and a hydrogen bond element (δₕ) of methyl propionate may be used.

### <Resin A>

The curable composition 1 contains the resin A. The resin A is not particularly limited as long as it satisfies the relationship of the above-described HSP distance with the resin B and polymerizable compound.

Examples of the resin A include a (meth)acrylic resin, an ester resin, an olefin resin, and a urethane resin.

Among these, the resin A preferably contains at least one of a repeating unit A1 having an acid group or a repeating unit A2 having at least one group of a polyoxyalkylene group having an average addition number of 3 or more or a polyoxyalkylene carbonyl group having an average addition number of 3 or more, and more preferably contains both the repeating unit A1 and the repeating unit A2.

—Repeating unit A1—

The repeating unit A1 functions as a pigment adsorbing group and can further improve developability of the resin A with respect to an alkali developer.

Examples of the acid group include a carboxylic acid group, a sulfonic acid group, a phosphoric acid group, and a phenolic hydroxyl group; and among these, a carboxylic acid group is preferable.

In the repeating unit A1, the number of acid groups may be one or more, and examples thereof include 1 to 6.

A specific structure of the repeating unit A1 is not particularly limited, but from the viewpoint that the effect of the present invention is more excellent, a repeating unit represented by Formula (AX1) is preferable.

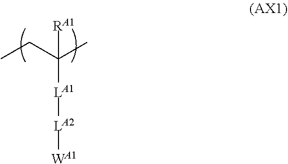

In the formula, R^{A} represents a hydrogen atom or an alkyl group having 1 to 5 carbon atoms.

The number of carbon atoms in the alkyl group represented by R^{A1} is preferably 1 to 3 and more preferably 1.

L^{A1} represents a single bond, —COO—, or CONR^{A2}—. R^{A2} has the same definition as the R^{A1} described above, and a suitable aspect thereof is also the same.

L^{A2} represents a single bond or a divalent linking group.

The kind of the divalent linking group is not particularly limited, and examples thereof include a divalent aliphatic hydrocarbon group, a divalent aromatic hydrocarbon group, —O—, —S—, —SO₂—, —NR^{A3}—, —CO—, and a group obtained by combining two or more of these groups.

The divalent aliphatic hydrocarbon group may be linear, branched, or cyclic. In addition, the number of carbon atoms is preferably 1 to 20 and more preferably 1 to 10.

Examples of the divalent aliphatic hydrocarbon group include an alkylene group, an alkenylene group, and an alkynylene group; and among these, an alkylene group is preferable.

The divalent aromatic hydrocarbon group preferably has 6 to 10 carbon atoms, and examples thereof include a phenylene group.

The divalent aliphatic hydrocarbon group and the divalent aromatic hydrocarbon group may further have a substituent. The substituent is not particularly limited, and may be, for example, an acid group such as a carboxylic acid group, a sulfonic acid group, a phosphoric acid group, and a phenolic hydroxyl group.

The R^{A3} has the same definition as the R^{A1} described above, and a suitable aspect thereof is also the same.

Among these, as the divalent linking group, a group obtained by combining two or more groups selected from the group consisting of an alkylene group which may have a substituent, a phenylene group which may have a substituent, —O—, and —CO— is preferable.

In Formula (AX1), the number of atoms excluding hydrogen atoms in a moiety represented by -L^{A1}-L^{A2}- is, for example, preferably less than 40.

W^{A1} represents an acid group.

Examples of the acid group include a carboxylic acid group, a sulfonic acid group, a phosphoric acid group, and a phenolic hydroxyl group; and among these, a carboxylic acid group is preferable.

From the viewpoint that the effect of the present invention is more excellent, the repeating unit A1 preferably contains one or more repeating units selected from the group consisting of a repeating unit represented by Formula (A11) to a repeating unit represented by Formula (A14).

In Formula (A13), n represents an average addition number, and is 1 or 2.

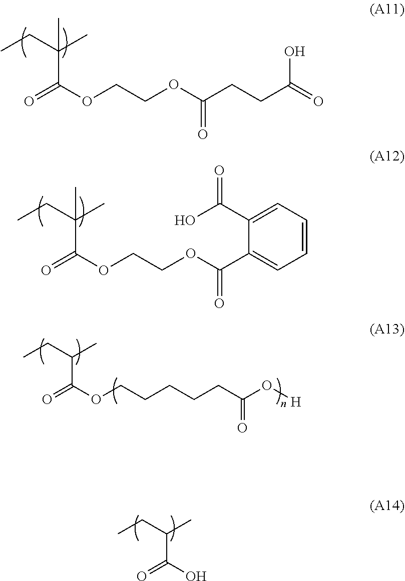

The resin A may contain only one kind of the repeating unit A1, or may contain two or more kinds thereof.

A content of the repeating unit A1 in the resin A is preferably 5% to 50% by mass, more preferably 5% to 40% by mass, and still more preferably 10% to 40% by mass with respect to all repeating units of the resin A.

In a case where two or more kinds of the repeating units A1 are used in combination, it is preferable that the total content thereof is within the above-described range.

### —Repeating Unit A2—

It is preferable that the resin A contains a repeating unit (repeating unit A2) having a group selected from the group consisting of a polyoxyalkylene group having an average addition number of 3 or more and a polyoxyalkylene carbonyl group having an average addition number of 3 or more. It is presumed that the repeating unit A2 acts to prevent reaggregation of a dispersoid such as a pigment, and contributes to the formation of the phase-separated structure in a case of being a cured film.

The oxyalkylene group represents a group represented by —O-AL-, and the oxyalkylene carbonyl group represents a group represented by —O-AL-CO—. AL represents an alkylene group.

In addition, the polyoxyalkylene group represents a group represented by —(O-AL)ₙ₁-, and the polyoxyalkylene carbonyl group represents a group represented by —(O-AL-CO)ₙ₂—.

In the polyoxyalkylene group and the polyoxyalkylene carbonyl group, a plurality of oxyalkylene groups (—O-AL-) may be the same or different from each other.

The number of carbon atoms in the alkylene group of the oxyalkylene group and the oxyalkylene carbonyl group (the number of carbon atoms in AL) is not particularly limited, but is preferably 2 to 10, more preferably 2 to 9, and still more preferably 2 to 7.

The average addition number (n1) in the polyoxyalkylene is 3 or more, preferably 4 or more, more preferably 5 or more, still more preferably 6 or more, particularly preferably 10 or more, and most preferably 15 or more. In addition, the upper limit value thereof is preferably 100 or less, more preferably 70 or less, and still more preferably 30 or less.

The average addition number (n2) in the oxyalkylene carbonyl group is 3 or more, preferably 4 or more, more preferably 5 or more, and still more preferably 6 or more. In addition, the upper limit value thereof is preferably 100 or less, more preferably 70 or less, and still more preferably 30 or less.

In the polyoxyalkylene group having an average addition number of 3 or more, alkylene moieties of a plurality of oxyalkylene groups may have the same number of carbon atoms or different numbers of carbon atoms. Examples of the case in which the alkylene moieties of the plurality of oxyalkylene groups have different numbers of carbon atoms include a configuration including an oxyethylene group and an oxypropylene group.

In addition, in the polyoxyalkylene carbonyl group having an average addition number of 3 or more, alkylene moieties of a plurality of polyoxyalkylene carbonyl groups may have the same number of carbon atoms or different numbers of carbon atoms. Specific examples of the case where the alkylene moieties of the plurality of oxyalkylene carbonyl groups have different numbers of carbon atoms include a configuration including an oxyethylene carbonyl group and an oxypropylene carbonyl group.

As the repeating unit A2, a repeating unit represented by any one of Formulae (1) to (3) is preferable, and a repeating unit represented by Formula (1) or Formula (3) is more preferable.

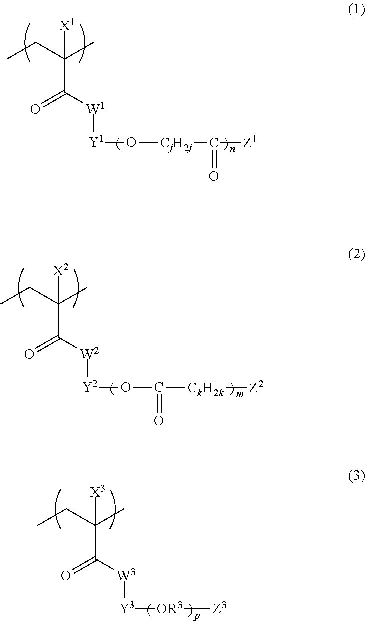

In Formulae (1) to (3), W¹, W², and W³ each independently represent an oxygen atom or NH. As W¹, W², and W¹, an oxygen atom is preferable.

In Formulae (1) to (3), X¹, X², and X³ each independently represent a hydrogen atom or a monovalent organic group. From the viewpoint of restriction on synthesis, X¹, X², and X³ are each independently preferably a hydrogen atom or an alkyl group having 1 to 12 carbon atoms (the number of carbon atoms), more preferably a hydrogen atom or a methyl group, and still more preferably a methyl group.

In Formulae (1) to (3), Y¹, Y², and Y³ each independently represent a divalent linking group. A structure of the divalent linking group represented by Y¹, Y², and Y³ is not particularly limited, and specific examples thereof include linking groups of (Y-1) to (Y-21). In the following structures, A and B mean moieties bonded to the left terminal group and the right terminal group in Formulae (1) to (3), respectively.

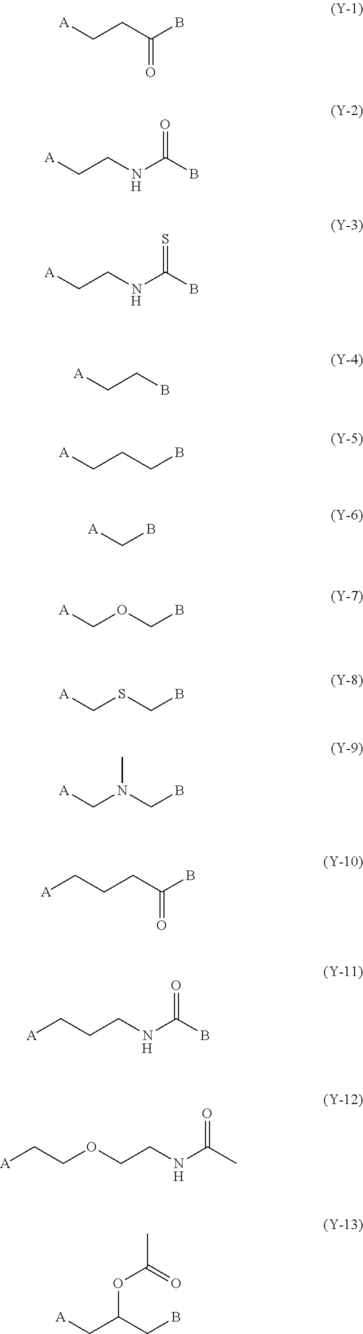

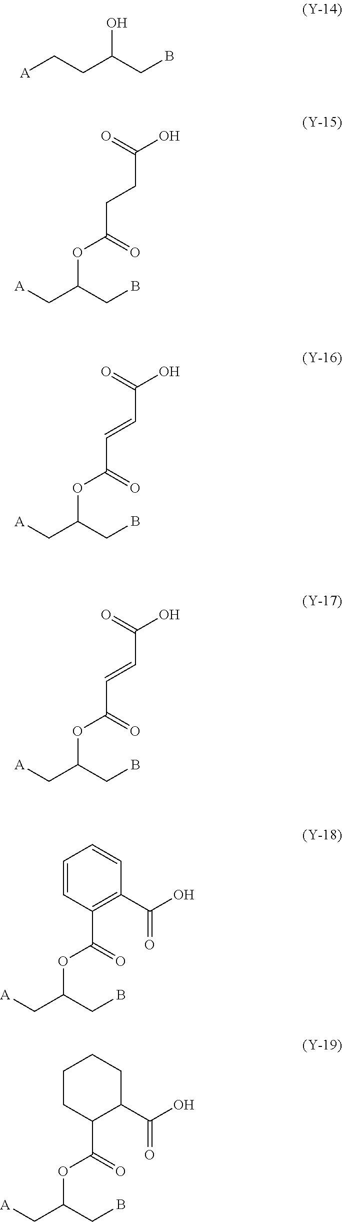

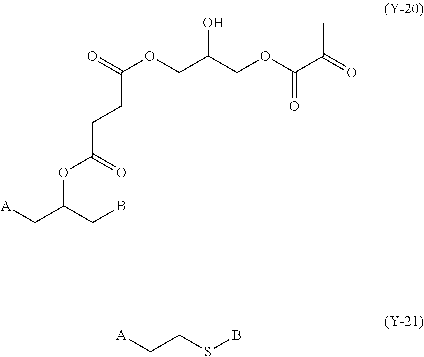

In Formulae (1) to (3), Z¹, Z², and Z³ each independently represent a hydroxyl group, an amino group, or a monovalent organic group. The organic group is not particularly limited, and specific examples thereof include an alkyl group, an alkoxy group, an aryloxy group, a heteroaryloxy group, an alkylthioether group, an arylthioether group, and a heteroarylthioether group.

An alkyl group moiety in the alkyl group, the alkoxy group, and the alkylthioether group represented by Z¹, Z², and Z³ may be linear, branched, or cyclic, and the number of carbon atoms is, for example, preferably 1 to 30. In addition, a methylene group in the alkoxy group may be substituted with —O—.

Among these, particularly from the viewpoint of improvement in dispersibility, the organic group represented by Z¹, Z², and Z³ is preferably a group exhibiting a steric repulsion effect, more preferably an alkyl group or alkoxy group having 5 to 24 carbon atoms, and still more preferably a branched alkyl group having 5 to 24 carbon atoms, a cyclic alkyl group having 5 to 24 carbon atoms, or an alkoxy group having 5 to 24 carbon atoms.

In addition, each of the above-described groups may have a substituent (for example, a hydroxyl group and an ethylenically unsaturated group such as a (meth)acryloyloxy group).

In a case where Z¹ in Formula (1) is a hydroxyl group, a moiety represented by —COZ¹ in the formula may be anionic (—COO—). In this case, examples of a counter cation include a quaternary ammonium salt.

In addition, in Formulae (1) and (2), n and m represent an average addition number, and represent a number of 3 or more. Among these, the lower limit value of n and m is preferably 4 or more, more preferably 5 or more, and still more preferably 6 or more. The upper limit value of n and m is preferably 100 or less, more preferably 70 or less, still more preferably 50 or less, and particularly preferably 30 or less.

In addition, in Formula (3), p represents an average addition number, and represents a number of 3 or more. Among the above, the lower limit value of p is preferably 4 or more, more preferably 5 or more, still more preferably 6 or more, even more preferably 10 or more, particularly preferably 15 or more, and most preferably 20 or more. The upper limit value of p is preferably 100 or less, more preferably 70 or less, still more preferably 50 or less, and particularly preferably 30 or less.

In addition, in Formulae (1) and (2), j and k each independently represent an integer of 2 to 10. From the viewpoint that the curable composition has more excellent temporal viscosity stability and developability, j and k in Formulae (1) and (2) are preferably an integer of 2 to 9, more preferably an integer of 2 to 7, still more preferably an integer of 4 to 6, and particularly preferably 5.

In addition, in Formula (3), R³ represents a branched or linear alkylene group. The number of carbon atoms in the above-described alkylene is preferably 2 to 10, more preferably 2 to 9, still more preferably 2 to 7, and particularly preferably 2 or 3. In a case where p is 2 to 100, a plurality of R³'s may be the same or different from each other.

As the repeating unit A2, the above-described repeating unit represented by Formula (1) or (3) is preferable, and the above-described repeating unit represented by Formula (1) is more preferable.

The resin A may contain only one kind of the repeating unit A2, or may contain two or more kinds thereof.

A content of the repeating unit A2 in the resin A is preferably 35% by mass or more, more preferably 40% by mass or more, and still more preferably 50% by mass or more with respect to all repeating units of the resin A. The upper limit value thereof is preferably 90% by mass or less, more preferably 80% by mass or less, and still more preferably 75% by mass or less.

In a case where two or more kinds of the repeating units A2 are used in combination, it is preferable that the total content thereof is within the above-described range.

### —Other Repeating Units (Repeating Unit A3)—

The resin A may contain another repeating unit (hereinafter, also referred to as “repeating unit A3”) other than the repeating units A1 and A2 described above.

Examples of the other repeating units include other repeating units having various functions, which are other than the above-described repeating units.

Examples of the other repeating units include a hydrophobic repeating unit (hereinafter, also referred to as “repeating unit A31”), a repeating unit having a curable group (hereinafter, also referred to as “repeating unit A32”), a repeating unit having a functional group capable of interacting with a pigment or the like (hereinafter, also referred to as “repeating unit A33”), and a repeating unit derived from a radical monomer selected from the group consisting of acrylonitriles and methacrylonitriles.

### (Repeating Unit A31)

The resin A may contain a hydrophobic repeating unit (repeating unit A31).

Examples of the repeating unit A31 include a repeating unit represented by Formula (AX2).

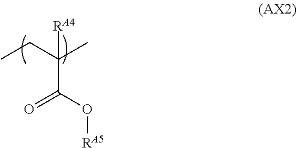

In the formula, R^{A4} represents a hydrogen atom or an alkyl group having 1 to 3 carbon atoms.

The number of carbon atoms in the alkyl group represented by R^{A4} is preferably 1 or 2 and more preferably 1.

R^{A5} represents a linear or branched alkyl group having 1 to 12 carbon atoms or an aralkyl group having 7 to 18 carbon atoms, and from the viewpoint that the effect of the present invention is more excellent, an aralkyl group having 7 to 18 carbon atoms is preferable.

The number of carbon atoms in the alkyl group represented by R^{A5} is preferably 1 to 8, more preferably 1 to 6, and still more preferably 1 to 4. In addition, a linear alkyl group is preferable.

The number of carbon atoms in the aralkyl group represented by R^{A} is preferably 7 to 18, more preferably 7 to 12, and still more preferably 7 to 10.

In addition, the alkyl group and the aralkyl group represented by R^{A} may have a substituent. The substituent is not particularly limited, and examples thereof include a hydroxyl group.

From the viewpoint that the effect of the present invention is more excellent, the repeating unit A31 is preferably a repeating unit having a benzyl group, and more preferably a repeating unit derived from benzyl (meth)acrylate.

The resin A may contain only one kind of the repeating unit A31, or may contain two or more kinds thereof.

A content of the repeating unit A31 in the resin A is preferably 5% to 50% by mass, more preferably 5% to 40% by mass, and still more preferably 10% to 40% by mass with respect to all repeating units of the resin A. In a case where two or more kinds of the repeating units A31 are used in combination, it is preferable that the total content thereof is within the above-described range.

### (Repeating Unit A32)

The resin A may contain a repeating unit (repeating unit A32) having a curable group.

Examples of the curable group include an ethylenically unsaturated group (for example, a (meth)acryloyl group, a vinyl group, a styryl group, and the like), and a cyclic ether group (for example, an epoxy group, an oxetanyl group, and the like). Among them, from the viewpoint that polymerization can be controlled by a radical reaction, as the curable group, an ethylenically unsaturated group is preferable. As the ethylenically unsaturated group, a (meth)acryloyl group is preferable.

A specific structure of the repeating unit A32 is not particularly limited, but a repeating unit represented by Formula (AX3) is preferable.

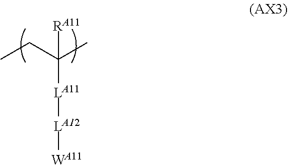

In the formula, R^{A11} represents a hydrogen atom or an alkyl group having 1 to 5 carbon atoms.

The number of carbon atoms in the alkyl group represented by R^{A11} is preferably 1 to 3 and more preferably 1.

L^{A11} represents a single bond, —COO—, or —CONR^{A12}—. R^{A12} has the same definition as the R^{A11} described above, and a suitable aspect thereof is also the same.

L^{A12} represents a single bond or a divalent linking group.

The kind of the divalent linking group is not particularly limited, and examples thereof include a divalent aliphatic hydrocarbon group, a divalent aromatic hydrocarbon group, —O—, —S—, —SO₂—, —NR^{A13}—, —CO—, and a group obtained by combining two or more of these groups.

The divalent aliphatic hydrocarbon group may be linear, branched, or cyclic. In addition, the number of carbon atoms is preferably 1 to 20 and more preferably 1 to 10.

Examples of the divalent aliphatic hydrocarbon group include an alkylene group, an alkenylene group, and an alkynylene group; and among these, an alkylene group is preferable.

The divalent aromatic hydrocarbon group preferably has 6 to 10 carbon atoms, and examples thereof include a phenylene group.

The divalent aliphatic hydrocarbon group and the divalent aromatic hydrocarbon group may further have a substituent. The substituent is not particularly limited, and examples thereof include an acid group such as a carboxylic acid group, a sulfonic acid group, a phosphoric acid group, and a phenolic hydroxyl group, and a hydroxyl group.

The R^{A13} has the same definition as the R^{A11} described above, and a suitable aspect thereof is also the same.

Among these, as the divalent linking group, a group obtained by combining two or more groups selected from the group consisting of an alkylene group which may have a substituent, —O—, and —CO— is preferable.

In Formula (AX3), the number of atoms excluding hydrogen atoms in a moiety represented by -L^{A11}-L^{A12}- is, for example, preferably less than 40.

W^{A11} represents a curable group.

Examples of the curable group represented by W^{A11} include the above-described curable groups.

The resin A may contain only one kind of the repeating unit A32, or may contain two or more kinds thereof.

A content of the repeating unit A32 in the resin A is preferably 5% to 50% by mass, more preferably 5% to 40% by mass, and still more preferably 10% to 40% by mass with respect to all repeating units of the resin A. In a case where two or more kinds of the repeating units A32 are used in combination, it is preferable that the total content thereof is within the above-described range.

### (Repeating Unit A33)

The resin A may contain a repeating unit (repeating unit A33) including a functional group capable of forming an interaction with a coloring material described later (a pigment or the like).

Examples of the functional group capable of interacting with the coloring material include a basic group, a coordinating group, and a reactive functional group.

Examples of the basic group include a primary amino group, a secondary amino group, a tertiary amino group, a heterocyclic ring containing an N atom, and an amide group; and among these, from the viewpoint of favorable adsorption power to the pigment or the like and high dispersibility, a tertiary amino group is preferable.

The resin A may contain only one kind of the repeating unit including a basic group, or may contain two or more kinds thereof.

A content of the repeating unit including a basic group in the resin A is preferably 0.01% to 50% by mass, and from the viewpoint of inhibiting deterioration of developability, more preferably 0.01% to 30% by mass with respect to all repeating units of the resin A. In a case where two or more kinds of the repeating units including a basic group are used in combination, it is preferable that the total content thereof is within the above-described range.

Examples of the coordinating group and the reactive functional group include an acetylacetoxy group, a trialkoxysilyl group, an isocyanate group, an acid anhydride, and an acid chloride; and among these, from the viewpoint of favorable adsorption power to a pigment or the like and high dispersibility with the pigment or the like, an acetylacetoxy group is preferable. The resin A may contain only one kind of the repeating unit including a coordinating group, or may contain two or more kinds thereof.

A content of the repeating unit including a coordinating group in the resin A is preferably 0.01% to 50% by mass and more preferably 0.01% to 30% by mass with respect to all repeating units of the resin A. In a case where two or more kinds of the repeating units including a coordinating group are used in combination, it is preferable that the total content thereof is within the above-described range.

The resin A may contain only one kind of the repeating unit including a reactive functional group, or may contain two or more kinds thereof.

A content of the repeating units having reactivity in the resin A is preferably 0.01% to 50% by mass and more preferably 0.01% to 30% by mass with respect to all repeating units of the resin A. In a case where two or more kinds of the repeating units having reactivity are used in combination, it is preferable that the total content thereof is within the above-described range.

The HSP distance between the resin A and the resin B is not particularly limited as long as it is more than 1.5 MPa^{1/2}, but is preferably more than 1.5 MPa^{1/2} and 5.0 MPa^{1/2} or less, and more preferably 2.0 to 4.0 MPa^{1/2}.

It is preferable that the HSP distance is more than 1.5 MPa^{1/2} because the phase-separated structure is likely to be generated in the curable composition layer. In addition, it is preferable that the HSP distance is equal to or less than an appropriate upper limit value (for example, 5.0 MPa^{1/2}) because the registration between the exposure mask in the step 2 described later and the support is facilitated.

A dispersion element (δ_{d}) of the Hansen solubility parameters of the resin A is preferably 14.0 to 18.0 MPa^{1/2} and more preferably 15.0 to 17.0 MPa^{1/2}.

A polarity element (δₚ) of the Hansen solubility parameters of the resin A is preferably 3.0 to 7.0 MPa^{1/2} and more preferably 4.0 to 6.0 MPa^{1/2}.

A hydrogen bond element (δₕ) of the Hansen solubility parameters of the resin A is preferably 3.0 to 11.0 MPa^{1/2} and more preferably 4.5 to 9.5 MPa^{1/2}.

From the viewpoint that the effect of the present invention is more excellent, a glass transition temperature of the resin A is a temperature lower than a temperature during the heating treatment in the step 5 described later by preferably 120° C. or higher, more preferably 150° C. or higher, and still more preferably 180° C. or higher. That is, a difference between the temperature during the heating treatment in the step 5 described later and the glass transition temperature of the resin A (Temperature during the heating treatment−Glass transition temperature of the resin A) is preferably 120° C. or higher.

The glass transition temperature of the resin A is often equal to or higher than the temperature lower than the temperature during the heating treatment in the step 5 described later by 250° C. That is, a difference between the temperature during the heating treatment in the step 5 described later and the glass transition temperature of the resin A (Temperature during the heating treatment−Glass transition temperature of the resin A) is often 250° C. or lower.

Among these, it is preferable that at least one of the glass transition temperature of the resin A or a glass transition temperature of the resin B, which will be described later, is a temperature lower than the temperature during the heating treatment in the step 5 by 120° C. or higher.

More specifically, the glass transition temperature of the resin A is preferably −40° C. to 100° C., more preferably −30° C. to 80° C., and still more preferably −20° C. to 50° C.

The glass transition temperature can be measured with DSC 3500 Sirius (manufactured by NETZSCH).

From the viewpoint that the effect of the present invention is more excellent, an acid value of the resin A is preferably 50 mgKOH/g or more, more preferably 55 mgKOH/g or more, and still more preferably 60 mgKOH/g or more. The upper limit value thereof is preferably 200 mgKOH/g or less, more preferably 170 mgKOH/g or less, still more preferably 100 mgKOH/g or less, and particularly preferably 80 mgKOH/g or less. In addition, a resin having a desired acid value can be obtained by changing the content of the repeating unit including an acid group, which is the constitutional component of the resin A.

A weight-average molecular weight of the resin A is preferably 5,000 to 100,000, more preferably 6,000 to 80,000, still more preferably 15,000 to 40,000, and most preferably 20,000 to 40,000.

A content of the resin A in the curable composition is not particularly limited, but is preferably 2% to 40% by mass, more preferably 5% to 30% by mass, and still more preferably 10% to 25% by mass with respect to the total solid content of the curable composition.

The resin A may be used alone or in combination of two or more thereof. In a case where two or more resins A are used in combination, the total content thereof is preferably within the above-described range.

### <Resin B>

The curable composition 1 contains the resin B. The resin B is not particularly limited as long as it satisfies the relationship of the above-described HSP distance with the resin A and polymerizable compound.

Examples of the resin B include a (meth)acrylic resin, an ester resin, an olefin resin, and a urethane resin.

Among these, it is preferable that the resin B does not contain the repeating unit having a group selected from the group consisting of a polyoxyalkylene group having an average addition number of 3 or more and a polyoxyalkylene carbonyl group having an average addition number of 3 or more.

The resin B preferably contains a repeating unit B1 derived from an alkyl (meth)acrylate, more preferably contains the repeating unit B1 and at least one of a repeating unit B2 having a hydroxyl group or a repeating unit B3 having a carboxylic acid group, and still more preferably contains all of the repeating unit B1, the repeating unit B2, and the repeating unit B3.

The resin B having the above-described configuration can improve adhesiveness of the cured film formed of the curable composition, and can form the phase-separated structure depending on the HSP distance with the resin A.

### —Repeating Unit B1—

The resin B preferably contains a repeating unit B1 derived from an alkyl (meth)acrylate. The repeating unit B1 represents a repeating unit different from the repeating unit B2 and the repeating unit B3 described later, and is a repeating unit including no hydroxyl group and carboxylic acid group.

An alkyl group linked to an ester bond in the alkyl (meth)acrylate may be linear, branched, or cyclic, but is preferably linear or branched from the viewpoint that the effect of the present invention is more excellent.

In addition, the number of carbon atoms in the above-described alkyl group is preferably 1 or more, and more preferably 4 or more from the viewpoint that the effect of the present invention is more excellent. The upper limit value thereof is preferably 20 or less, more preferably 12 or less, and still more preferably 10 or less.

The above-described alkyl group may or may not have a substituent, but from the viewpoint that the effect of the present invention is more excellent, it is preferable that the alkyl group does not have a substituent. Examples of the above-described substituent include a group other than a hydroxyl group and a carboxylic acid group.

The resin B may contain only one kind of the repeating unit B1, or may contain two or more kinds thereof.

A content of the repeating unit B1 in the resin B is preferably 10% by mass or more, more preferably 60% by mass or more, still more preferably 70% by mass or more, and particularly preferably 80% by mass or more with respect to all repeating units of the resin B. The upper limit value thereof is not particularly limited, but is preferably 99% by mass or less and more preferably 95% by mass or less. In a case where two or more kinds of the repeating units B1 are used in combination, it is preferable that the total content thereof is within the above-described range.

### —Repeating Unit B2—

The resin B preferably contains a repeating unit B2 having a hydroxyl group.

The repeating unit B2 is a repeating unit different from the above-described repeating unit B1, and preferably does not have a carboxylic acid group.

The number of hydroxyl groups in the repeating unit B2 may be 1 or more, and examples thereof include 1 to 6.

A specific structure of the repeating unit B2 is not particularly limited, but a repeating unit represented by Formula (BX1) is preferable.

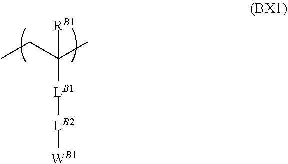

In the formula, R^{B1} represents a hydrogen atom or an alkyl group having 1 to 5 carbon atoms.

The number of carbon atoms in the alkyl group represented by R^{B1} is preferably 1 to 3 and more preferably 1.

L^{B1} represents a single bond, —COO—, or CONR^{B2}—. R^{B2} has the same definition as the R^{B1} described above, and a suitable aspect thereof is also the same.

L^{B2} represents a single bond or a divalent linking group.

The kind of the divalent linking group is not particularly limited, and examples thereof include a divalent aliphatic hydrocarbon group, a divalent aromatic hydrocarbon group, —O—, —S—, —SO₂—, —NR^{B3}—, —CO—, and a group obtained by combining two or more of these groups.

The divalent aliphatic hydrocarbon group may be linear, branched, or cyclic. In addition, the number of carbon atoms is preferably 1 to 20 and more preferably 1 to 10.

Examples of the divalent aliphatic hydrocarbon group include an alkylene group, an alkenylene group, and an alkynylene group; and among these, an alkylene group is preferable.

The divalent aromatic hydrocarbon group preferably has 6 to 10 carbon atoms, and examples thereof include a phenylene group.

The divalent aliphatic hydrocarbon group and the divalent aromatic hydrocarbon group may further have a substituent. The substituent is not particularly limited, and examples thereof include a hydroxyl group.

The R^{B3} has the same definition as the R^{B1} described above, and a suitable aspect thereof is also the same.

Among these, the divalent linking group is preferably an alkylene group which may have a substituent or an alkylene group which may include a group selected from —O— and —CO— and may have a substituent, and more preferably an alkylene group having 1 to 6 carbon atoms, which may have a substituent.

In Formula (BX1), the number of atoms excluding hydrogen atoms in a moiety represented by -L^{B1}-L^{B2}- is, for example, preferably less than 40.

W^{B1} represents a hydroxyl group.

From the viewpoint that the effect of the present invention is more excellent, the repeating unit B2 is preferably a repeating unit derived from 2-ethylhydroxy(meth)acrylate.

The resin B may contain only one kind of the repeating unit B2, or may contain two or more kinds thereof.

The lower limit value of a content of the repeating unit B2 in the resin B is preferably 1% by mass or more, more preferably 2% by mass or more, and still more preferably 5% by mass or more with respect to all repeating units of the resin B. The upper limit value thereof is preferably 50% by mass or less, more preferably 40% by mass or less, and still more preferably 30% by mass or less. In a case where two or more kinds of the repeating units B2 are used in combination, it is preferable that the total content thereof is within the above-described range.

### —Repeating Unit B3—

The resin B preferably contains a repeating unit B3 having a carboxylic acid group.

The repeating unit B3 is a repeating unit different from the above-described repeating unit B1 and the above-described repeating unit B2. The repeating unit B3 preferably does not have a hydroxyl group.

In the repeating unit B3, the number of carboxylic acid groups may be one or more, and examples thereof include 1 to 6.

Specific examples of the repeating unit B3 include the repeating unit represented by Formula (AX1) mentioned as the example of the repeating unit A1 contained in the resin A, in which the acid group represented by W^{A1} is a carboxylic acid group; and a suitable aspect thereof is also the same.

The resin B may contain only one kind of the repeating unit B3, or may contain two or more kinds thereof.

A content of the repeating unit B3 in the resin B is preferably 5% to 40% by mass, more preferably 5% to 30% by mass, and still more preferably 10% to 30% by mass with respect to all repeating units of the resin B. In a case where two or more kinds of the repeating units B3 are used in combination, it is preferable that the total content thereof is within the above-described range.

### —Other Repeating Units (Repeating Unit B4)—

The resin B may contain another repeating unit (hereinafter, also referred to as “repeating unit B4”) other than the repeating units B1 to B3 described above.

As the other repeating units, other repeating units having various functions, which are other than the above-described repeating units, may be contained.

As the other repeating units, a repeating unit having an aromatic ring is preferable, a repeating unit having a benzyl group or a repeating unit derived from styrenes (for example, styrene, a-methylstyrene, and the like) is more preferable, and a repeating unit derived from benzyl (meth)acrylate is still more preferable.

In addition, the resin B may contain a repeating unit selected from the group consisting of the repeating unit A31 to the repeating unit A33, exemplified as the other repeating units which can be contained in the resin A.

The resin B may contain only one kind of the repeating unit B4, or may contain two or more kinds thereof.

A content of the repeating unit B4 in the resin B is preferably 1% to 15% by mass, and more preferably 5% to 15% by mass with respect to all repeating units of the resin B. In a case where two or more kinds of the repeating units B41 are used in combination, it is preferable that the total content thereof is within the above-described range.

A dispersion element (δ_{d}) of the Hansen solubility parameters of the resin B is preferably 14.0 to 18.0 MPa^{1/2} and more preferably 15.0 to 17.0 MPa^{1/2}.

A polarity element (δₚ) of the Hansen solubility parameters of the resin B is preferably 2.0 to 7.0 MPa^{1/2} and more preferably 3.0 to 6.0 MPa^{1/2}.

A hydrogen bond element (δₕ) of the Hansen solubility parameters of the resin B is preferably 3.0 to 8.0 MPa^{1/2} and more preferably 4.0 to 7.0 MPa^{1/2}.

From the viewpoint that the effect of the present invention is more excellent, a glass transition temperature of the resin B is a temperature lower than a temperature during the heating treatment in the step 5 described later by preferably 120° C. or higher, more preferably 130° C. or higher, and still more preferably 150° C. or higher. That is, a difference between the temperature during the heating treatment in the step 5 described later and the glass transition temperature of the resin B (Temperature during the heating treatment−Glass transition temperature of the resin B) is preferably 120° C. or higher.

The glass transition temperature of the resin B is often equal to or higher than the temperature lower than the temperature during the heating treatment in the step 5 described later by 250° C. That is, a difference between the temperature during the heating treatment in the step 5 described later and the glass transition temperature of the resin B (Temperature during the heating treatment−Glass transition temperature of the resin B) is often 250° C. or lower. The glass transition temperature of the resin B is preferably −20° C. to 120° C., more preferably −20° C. to 100° C., still more preferably −5° C. to 80° C., even more preferably 0° C. to 70° C., and particularly preferably 30° C. to 70° C.

The glass transition temperature can be measured with DSC 3500 Sirius (manufactured by NETZSCH).

An acid value of the resin B is preferably 0 mgKOH/g or more, more preferably 20 mgKOH/g or more, still more preferably 40 mgKOH/g or more, and particularly preferably 55 mgKOH/g or more. The upper limit value thereof is preferably 150 mgKOH/g or less, more preferably 100 mgKOH/g or less, and still more preferably 90 mgKOH/g or less. In addition, a resin having a desired acid value can be obtained by changing the content of the repeating unit including an acid group, which is the constitutional component of the resin B.

A weight-average molecular weight of the resin B is preferably 5,000 to 100,000, more preferably 8,000 to 80,000, still more preferably 15,000 to 40,000, and most preferably 18,000 to 25,000.

A content of the resin B in the curable composition is not particularly limited, but is preferably 2% to 40% by mass, more preferably 5% to 35% by mass, and still more preferably 10% to 30% by mass with respect to the total solid content of the curable composition.

In addition, from the viewpoint that the effect of the present invention is more excellent, in the curable composition, a ratio of the content of the resin A to the total content of the resin A and the resin B (Content of the resin A/Total content of the resin A and the resin B) is preferably 0.30 to 0.50, more preferably 0.33 to 0.47, and still more preferably 0.35 to 0.45.

The resin B may be used alone or in combination of two or more thereof. In a case where two or more resins B are used in combination, the total content thereof is preferably within the above-described range.

### <Polymerizable Compound>

The curable composition 1 contains the polymerizable compound. The polymerizable compound is a compound different from the above-described resins A and B.

The polymerizable compound is, for example, preferably a compound having a polymerizable group capable of forming a covalent bond by generating a radical, a cation, or an anion with action of heat, light, an acid, a base, or the like; and the curing mechanism is not particularly limited, but a thermosetting compound or a photocurable compound is preferable.

Examples of the polymerizable group include an ethylenically unsaturated group.

Examples of the ethylenically unsaturated group include a vinyl group, a (meth)allyl group, a (meth)acryloyl group, a (meth)acryloyloxy group, a (meth)acrylamide group, and a vinylphenyl group.

A molecular weight of the polymerizable compound (in a case of having a molecular weight distribution, a weight-average molecular weight) is not particularly limited, but is preferably 2,500 or less, more preferably 2,000 or less, and still more preferably 1,500 or less. The lower limit thereof is preferably 50 or more.

The polymerizable compound is preferably a compound including an ethylenically unsaturated group (a group including an ethylenically unsaturated bond).

As the polymerizable compound, a compound including one or more ethylenically unsaturated bonds is preferable, a compound including two or more ethylenically unsaturated bonds is more preferable, a compound including three or more ethylenically unsaturated bonds is still more preferable, and a compound including four or more ethylenically unsaturated bonds is particularly preferable. The upper limit is, for example, 15 or less. Examples of the ethylenically unsaturated group include a vinyl group, a (meth)allyl group, and a (meth)acryloyl group.

Among these, the polymerizable compound is preferably a tri- to pentadeca-functional (meth)acrylate compound, and more preferably a tri- to hexa-functional (meth)acrylate compound.

As the polymerizable compound, a polyfunctional (meth)acrylate obtained by esterifying or partially esterifying a polyhydric alcohol such as trimethylolethane, ditrimethylolethane, trimethylolpropane, ditrimethylolpropane, pentaerythritol, dipentaerythritol, tripentaerythritol, glycerin, diglycerol, and trimethylolmelamine with (meth)acrylic acid is preferable.

More specific examples of such a polyfunctional (meth)acrylate include glycerin triacrylate, trimethylolpropane ethoxy triacrylate, pentaerythritol triacrylate, and pentaerythritol tetraacrylate.

In addition, as the polymerizable compound, for example, compounds described in paragraph [0050] of JP2008-260927A and paragraph [0040] of JP2015-068893A can be used, the contents of which are incorporated into the present specification.

As the polymerizable compound, a compound which includes one or more ethylenically unsaturated groups and has a boiling point equal to or higher than 100° C. under normal pressure is also preferable. For example, compounds described in paragraph [0227] of JP2013-029760A and paragraphs [0254] to [0257] of JP2008-292970A can be used, the contents of which are incorporated into the present specification.

As a commercially available product of the polymerizable compound, dipentaerythritol triacrylate (as a commercially available product, for example, KAYARAD D-330 manufactured by Nippon Kayaku Co., Ltd.), dipentaerythritol tetraacrylate (as a commercially available product, for example, KAYARAD D-320 manufactured by Nippon Kayaku Co., Ltd.), dipentaerythritol penta(meth)acrylate (as a commercially available product, for example, KAYARAD D-310 manufactured by Nippon Kayaku Co., Ltd.), dipentaerythritol hexa(meth)acrylate (as a commercially available product, for example, KAYARAD DPHA manufactured by Nippon Kayaku Co., Ltd., and A-DPH-12E manufactured by Shin-Nakamura Chemical Co., Ltd.), or a structure in which these (meth)acryloyl groups are bonded through an ethylene glycol residue or a propylene glycol residue (for example, SR454 and SR499 which are commercially available products from Sartomer) is preferable. Oligomer types thereof can also be used.

NK ESTER A-TMMT (pentaerythritol tetraacrylate, manufactured by Shin-Nakamura Chemical Co., Ltd.) KAYARAD RP-1040, KAYARAD DPEA-12LT, KAYARAD DPHA LT, KAYARAD RP-3060, and KAYARAD DPEA-12 (all trade names, manufactured by Nippon Kayaku Co., Ltd.) may be used.

In addition, as the polymerizable compound, urethane (meth)acrylate-based compound having both (meth)acryloyl group and urethane bond in the compound may be used, and for example, KAYARAD DPHA-40H (trade name, manufactured by Nippon Kayaku Co., Ltd.) may be used.

The preferred aspects of the polymerizable compound are shown below.

The polymerizable compound may have an acid group such as a carboxylic acid group, a sulfonic acid group, and a phosphoric acid group. The polymerizable compound including an acid group is preferably an ester of an aliphatic polyhydroxy compound and an unsaturated carboxylic acid, more preferably a polymerizable compound having an acid group by reacting a nonaromatic carboxylic acid anhydride with an unreacted hydroxyl group of an aliphatic polyhydroxy compound, and still more preferably a compound in which the aliphatic polyhydroxy compound in the ester is pentaerythritol and/or dipentaerythritol. Examples of a commercially available product thereof include ARONIX TO-2349, M-305, M-510, and M-520 manufactured by Toagosei Co., Ltd.

An acid value of the polymerizable compound including an acid group is preferably 0.1 to 40 mgKOH/g and more preferably 5 to 30 mgKOH/g. In a case where the acid value of the polymerizable compound is 0.1 mgKOH/g or more, development dissolution characteristics are favorable, and in a case where the acid value is 40 mgKOH/g or less, the polymerizable compound is advantageous in terms of production and/or handling. In addition, a photopolymerization performance is favorable, and curing properties are excellent.

As the polymerizable compound, a compound including a caprolactone structure is also a preferred aspect.

For example, the compound including a caprolactone structure is not particularly limited as long as the compound includes a caprolactone structure in a molecule; and examples thereof include F-caprolactone-modified polyfunctional (meth)acrylate obtained by esterifying or partially esterifying a polyhydric alcohol such as trimethylolethane, ditrimethylolethane, trimethylolpropane, ditrimethylolpropane, pentaerythritol, dipentaerythritol, tripentaerythritol, glycerin, diglycerol, and trimethylol melamine with (meth)acrylic acid and F-caprolactone. Among these, a compound which includes a caprolactone structure and is represented by Formula (Z-1) is preferable.

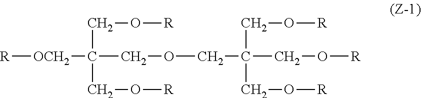

In Formula (Z-1), all six R's are groups represented by Formula (Z-2), or one to five among the six R's are groups represented by Formula (Z-2) and the others are groups represented by Formula (Z-3).

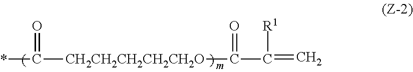

In Formula (Z-2), R¹ represents a hydrogen atom or a methyl group, m represents a number of 1 or 2, and * represents a bonding position.

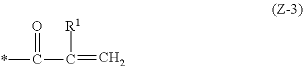

In Formula (Z-3), R¹ represents a hydrogen atom or a methyl group, and “*” represents a bonding position.

The polymerizable compound including a caprolactone structure is commercially available, for example, as a KAYARAD DPCA series from Nippon Kayaku Co., Ltd., and examples thereof include DPCA-20 (a compound in which m in Formulae (Z-1) to (Z-3) is 1, the number of groups represented by Formula (Z-2) is 2, and all of R's represent hydrogen atoms), DPCA-30 (a compound in which m in Formulae (Z-1) to (Z-3) is 1, the number of groups represented by Formula (Z-2) is 3, and all of R¹'s represent hydrogen atoms), DPCA-60 (a compound in which m in Formulae (Z-1) to (Z-3) is 1, the number of groups represented by Formula (Z-2) is 6, and all of R¹'s represent hydrogen atoms), and DPCA-120 (a compound in which m in Formulae (Z-1) to (Z-3) is 2, the number of groups represented by Formula (Z-2) is 6, and all of R's represent hydrogen atoms). In addition, examples of a commercially available product of the polymerizable compound including a caprolactone structure also include M-350 (trade name) (trimethylolpropane triacrylate) manufactured by Toagosei Co., Ltd.

As the polymerizable compound, a compound represented by Formula (Z-4) or Formula (Z-5) can also be used.

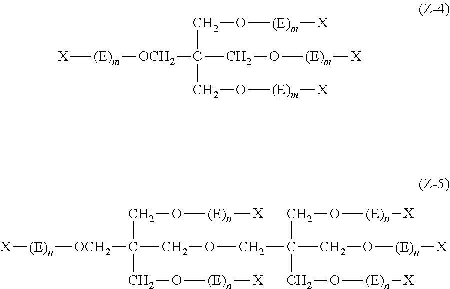

In Formula (Z-4) and Formula (Z-5), E represents —((CH₂)_{y}CH₂O)— or —((CH₂)_{y}CH(CH₃)O)—, y represents an integer of 0 to 10, and X represents a (meth)acryloyl group, a hydrogen atom, or a carboxylic acid group.

In Formula (Z-4), the total number of (meth)acryloyl groups is 3 or 4, m represents an integer of 0 to 10, and the sum of m's is an integer of 0 to 40.

In Formula (Z-5), the total number of (meth)acryloyl groups is 5 or 6, n represents an integer of 0 to 10, and the sum of n's is an integer of 0 to 60.

In Formula (Z-4), m is preferably an integer of 0 to 6 and more preferably an integer of 0 to 4.

In addition, the total number of m's is preferably an integer of 2 to 40, more preferably an integer of 2 to 16, and still more preferably an integer of 4 to 8.

In Formula (Z-5), n is preferably an integer of 0 to 6 and more preferably an integer of 0 to 4.

In addition, the total number of n's is preferably an integer of 3 to 60, more preferably an integer of 3 to 24, and still more preferably an integer of 6 to 12.

Furthermore, a form in which a terminal on the oxygen atom side of —((CH₂)_{y}CH₂O)— or —((CH₂)_{y}CH(CH₃)O)— in Formula (Z-4) or Formula (Z-5) is bonded to X is preferable.

The compound represented by Formula (Z-4) or Formula (Z-5) may be used alone or in combination of two or more thereof. In particular, aspects such as a form in which all of six X's in Formula (Z-5) are acryloyl groups, and a mixture of a compound in which all of six X's in Formula (Z-5) are acryloyl groups and a compound in which at least one among the six X's is a hydrogen atom are preferable. With such a configuration, the developability can be further improved.

In addition, the total content of the compound represented by Formula (Z-4) or (Z-5) in the polymerizable compound is preferably 20% by mass or more, and more preferably 50% by mass or more.

Among the compounds represented by Formula (Z-4) or (Z-5), a pentaerythritol derivative and/or a dipentaerythritol derivative are more preferable.

In addition, the polymerizable compound may include a cardo skeleton.

As the polymerizable compound including a cardo skeleton, a polymerizable compound including a 9,9-bisarylfluorene skeleton is preferable.

Examples of the polymerizable compound including a cardo skeleton include Oncoat EX series (manufactured by NAGASE & CO., LTD.) and OGSOL (manufactured by Osaka Gas Chemicals Co., Ltd.).

As the polymerizable compound, a compound including an isocyanuric acid skeleton as a core is also preferable. Examples of such a polymerizable compound include NK ESTER A-9300 (manufactured by Shin-Nakamura Chemical Co., Ltd.).

As described above, the HSP distance (A) between the resin A and the polymerizable compound is not particularly limited as long as it is larger than the HSP distance (B) between the resin B and the polymerizable compound; but a difference (HSP distance (A)−HSP distance (B)) between the HSP distance (A) and the HSP distance (B) is preferably 0.1 MPa^{1/2} or more, more preferably 0.5 MPa^{1/2} or more, and still more preferably 1.0 MPa^{1/2} or more. The upper limit thereof is preferably 5.0 MPa^{1/2} or less, more preferably 3.0 MPa^{1/2} or less, and still more preferably 2.0 MPa^{1/2} or less.

A dispersion element (δ_{d}) of the Hansen solubility parameters of the polymerizable compound is preferably 15.0 to 21.0 MPa^{1/2} and more preferably 16.0 to 20.0 MPa^{1/2}.

A polarity element (δₚ) of the Hansen solubility parameters of the polymerizable compound is preferably 0.1 to 5.0 MPa^{1/2} and more preferably 0.1 to 4.0 MPa^{1/2}.

A hydrogen bond element (δₕ) of the Hansen solubility parameters of the polymerizable compound is preferably 2.0 to 15.0 MPa^{1/2} and more preferably 3.0 to 14.0 MPa^{1/2}.

In a case where two or more polymerizable compounds are used, the Hansen solubility parameters of the polymerizable compound are calculated based on a mass fraction of each polymerizable compound.

Specifically, three components of a dispersion element (δ_{d}), a polarity element (δₚ), and a hydrogen bond element (δₕ) of each polymerizable compound are obtained, and a mass fraction of each polymerizable compound is multiplied by each of these components and summed to calculate the dispersion element (δ_{d}), the polarity element (δₚ), and the hydrogen bond element (δₕ) of the polymerizable compound.

For example, in a case where n kinds of the polymerizable compounds are used, a hydrogen bond element (δₕ) of the polymerizable compound can be calculated by using an equation (I) with a hydrogen bond element (δₕ) of a j-th (j is an integer of 1 or more) polymerizable compound and a mass fraction Nj of the j-th polymerizable compound with respect to all polymerizable compounds.

$$Hydrogen bond element ( {δ}_{h} ) = \sum δ PjNj \qquad ( I )$$

In the above description, the hydrogen bond element (δₕ) has been described, but the dispersion element (δ_{d}) and the polarity element (δₚ) of the polymerizable compound can also be calculated according to the same procedure.

From the viewpoint that the effect of the present invention is more excellent, a shrinkage ratio of the polymerizable compound is preferably 7% or more, more preferably 10% or more, and still more preferably 15% or more. The upper limit thereof is preferably 50% or less, and more preferably 30% or less.

The “shrinkage ratio of the polymerizable compound” in the present specification refers to a shrinkage ratio defined by the following expression (X).

$$Shrinkage ratio ( \% ) = ( 1 - ρ M / ρ P ) \times 100 \qquad Expression ( X )$$

In the expression (X), ρM represents a specific gravity of the polymerizable compound measured in accordance with JIS-K-2249. ρP represents a specific gravity of a cured substance of the polymerizable compound measured in accordance with JIS-K-2249.

The cured substance of the polymerizable compound refers to a cured substance produced by the following procedure.

### (Method for Producing Cured Substance)

A composition consisting of 0.5% by mass of a radical polymerization initiator (V-601; manufactured by FUJIFILM Wako Pure Chemical Corporation) and 99.5% by mass of the polymerizable compound is injected into a mold constituted of a glass plate and a gasket consisting of an ethylene-vinyl acetate copolymer, and casting polymerization is carried out to produce a cured substance. The polymerization is carried out using an air furnace, and the temperature is gradually raised from 30° C. to 90° C. over 18 hours, and then maintained at 90° C. for 2 hours. After the completion of the polymerization, the polymer is removed from the glass mold of the mold to obtain a cured substance.

A content of the ethylenically unsaturated group in the polymerizable compound (meaning a value obtained by dividing the number of ethylenically unsaturated groups in the polymerizable compound by the molecular weight (g/mol) of the polymerizable compound) is preferably 5.0 mmol/g or more. The upper limit thereof is preferably 20.0 mmol/g or less.

In a case where two or more polymerizable compounds are used, the above-described shrinkage ratio indicates a shrinkage ratio of a mixture of these polymerizable compounds. For example, in a case where a polymerizable compound A and a polymerizable compound B are used as the polymerizable compound, and a content of the polymerizable compound A is 90% by mass and a content of the polymerizable compound B is 10% by mass with respect to all the polymerizable compounds, the above-described measurement is performed using a mixture of the polymerizable compound A and the polymerizable compound B (Content of polymerizable compound A: Content of polymerizable compound B=90:10 (mass proportion)) as the “polymerizable compound” in (Method for producing cured substance).

A content of the polymerizable compound in the curable composition is preferably 5% by mass or more, more preferably 10% by mass or more, still more preferably 15% by mass or more, and particularly preferably 20% by mass or more with respect to the total solid content of the curable composition. In addition, the upper limit value thereof is preferably 60% by mass or less, more preferably 40% by mass or less, and still more preferably 35% by mass or less. The polymerizable compound may be used alone or in combination of two or more thereof. In a case where two or more polymerizable compounds are used in combination, it is preferable that the total amount thereof is within the above-described range.

### <Coloring Material>

The curable composition 1 may contain a coloring material, and it is preferable that the curable composition 1 further contains a coloring material. The coloring material is not particularly limited, and a known coloring material can be used.

Examples of the coloring material include a black coloring material, a chromatic coloring material, a white coloring material, and a near infrared absorber. In the present specification, the white coloring material includes not only a pure white coloring material but also includes a bright gray (for example, grayish-white, light gray, or the like) coloring material close to white.

The coloring material preferably includes at least one selected from the group consisting of a black coloring material, a chromatic coloring material, and a near infrared absorber, and more preferably includes at least one selected from the group consisting of a black coloring material and a chromatic coloring material.

It is also preferable that the coloring material includes one or more black coloring materials or chromatic coloring materials, and a near infrared absorber. In addition, a combination of two or more kinds of chromatic coloring materials may form black. For a combination of coloring materials which form black with the combination of two or more kinds of chromatic coloring materials, JP2013-077009A, JP2014-130338A, WO2015/166779A, and the like can be referred to.

The coloring material may be any of a pigment or a dye, but a pigment is preferable and an inorganic pigment is more preferable.

An average primary particle diameter of the above-described pigment is preferably 1 nm or more, more preferably 5 nm or more, and still more preferably 10 nm or more. The upper limit thereof is preferably less than 250 nm, more preferably 200 nm or less, still more preferably 180 nm, particularly preferably 150 nm or less, and most preferably 100 nm or less. In the present specification, in a case where the pigment is a commercially available product, a manufacturer's nominal value such as a catalog value can be adopted as the primary particle diameter of the pigment; but in a case where there is no catalog value, the primary particle diameter of the pigment can be obtained from an image obtained by observing primary particles of the pigment with a transmission electron microscope. Specifically, a projected area of the primary particles of the pigment is determined, and the corresponding circle-equivalent diameter is calculated as the primary particle diameter of the pigment. In addition, the average primary particle diameter in the present specification is the arithmetic average value of the primary particle diameters with respect to 400 primary particles of the pigment. In addition, the primary particles of the pigment refer to particles which are independent without aggregation.

### —Black Coloring Material—

In a case where the cured film obtained by the method for manufacturing a cured film according to the embodiment of the present invention is used as a light shielding film, the curable composition preferably contains a black coloring material. That is, the coloring material preferably includes a black coloring material.

The black coloring material is not particularly limited, and a known black coloring material can be used. In the present specification, the black coloring material means a coloring material which exhibits absorption over the entire wavelength range of 400 to 700 nm. Examples of the black coloring material include inorganic pigments (black pigments) such as carbon black, titanium black, and graphite.

The inorganic pigment preferably includes carbon black or titanium black, and more preferably includes titanium black.

### —Black Pigment—

For the black pigment, a plurality of pigments, each of which cannot be used by itself as a black pigment, may be combined and adjusted to be black as a whole, but a pigment which expresses black by itself is preferable. In addition, a black pigment that expresses black by itself and absorbs infrared rays may be used.

Here, the black pigment which absorbs infrared rays has absorption in a wavelength range in the infrared region (preferably, a wavelength of 650 to 1300 nm). A black pigment having a maximal absorption wavelength in a wavelength range of 675 to 900 nm is also preferable.

An average particle diameter of the black pigment is preferably 250 nm or less, more preferably 200 nm or less, and still more preferably 150 nm or less. From the viewpoint that handleability is more excellent, the above-described average particle diameter is preferably 1 nm or more, more preferably 5 nm or more, and still more preferably 20 nm or more.

The above-described average particle diameter is calculated according to the following method.

The curable composition is diluted with propylene glycol monomethyl ether acetate (PGMEA) to prepare a measurement solution having a concentration of solid contents of 0.2% by mass. Next, using a dynamic light scattering type particle size distribution measuring device (LB-500 (product name) manufactured by HORIBA, Ltd.) according to JIS 8826: 2005, the data of the measurement solution is taken 50 times using a 2 ml quartz cell for measurement at a temperature of 25° C., and the obtained number-based particle diameters are arithmetically averaged to obtain the average particle diameter.

It is noted that, in the above description, although the measurement solution is prepared using the curable composition, the measurement may be carried out using a coloring material dispersion liquid in which the black pigment is dispersed. For example, in a case where the curable composition contains particles other than the black pigment, the average particle diameter of the black pigment may be measured using a coloring material dispersion liquid in which the black pigment used in the preparation of the curable composition is dispersed. In addition, in a case where the curable composition contains particles other than the black pigment, the average particle diameter of the black pigment may be measured after separating the black pigment and the particles by any method.

As the black pigment, various known black pigments can be used. The black pigment may be an inorganic pigment or an organic pigment.

From the viewpoint that the effect of the present invention is more excellent, the black pigment is preferably an inorganic pigment, and more preferably carbon black, metal nitride particles, or metal oxynitride particles.

### Black Inorganic Pigment

The black inorganic pigment is not particularly limited as long as particles have light shielding properties and contain an inorganic compound, and a known inorganic pigment can be used.

Examples of the inorganic pigment include a metal oxide, a metal nitride, and a metal oxynitride, which contain a metal element of Group 4 such as titanium (Ti) and zirconium (Zr), a metal element of Group 5 such as vanadium (V) and niobium (Nb), or one or more metal elements selected from the group consisting of yttrium (Y), aluminum (A1), cobalt (Co), chromium (Cr), copper (Cu), manganese (Mn), ruthenium (Ru), iron (Fe), nickel (Ni), tin (Sn), and silver (Ag).

Among these, a metal oxide, a metal nitride, or a metal oxynitride, which contains one or two or more metal elements selected from the group consisting of titanium (Ti), zirconium (Zr), vanadium (V), yttrium (Y), aluminum (A1), and iron (Fe), is preferable. That is, the inorganic pigment may contain two or more kinds of metal atoms.

As the above-described metal oxide, metal nitride, and metal oxynitride, particles in which other metal atoms are further mixed may be used, and for example, metal nitride-containing particles containing atoms (preferably an oxygen atom and/or a sulfur atom) selected from Group 13 to Group 17 elements of the periodic table can be used.

In addition, the above-described metal oxide, metal nitride, and metal oxynitride may be coated with an inorganic substance and/or an organic substance.

Examples of the above-described inorganic substance include metal atoms contained in the above-described inorganic pigment.

Examples of the above-described organic substance include an organic substance having a hydrophobic group, and a silane compound is preferable.

Among these, as the inorganic pigment, from the viewpoint of suppressing occurrence of undercut during the formation of the cured film, a nitride or an oxynitride of one or more metals selected from the group consisting of titanium, vanadium, zirconium, niobium, and iron is more preferable, and a nitride or an oxynitride of zirconium or a nitride or an oxynitride of titanium (titanium black) is still more preferable.

The titanium black is black particles containing titanium oxynitride.

A surface of the titanium black can be modified, as necessary, according to the purpose of improving dispersibility, suppressing aggregating property, and the like. The titanium black can be coated with silicon oxide, titanium oxide, germanium oxide, aluminum oxide, magnesium oxide, or zirconium oxide, and can be subjected to a treatment with a water repellent substance as shown in JP2007-302836A.

A particle size of the titanium black is not particularly limited, but is preferably 10 to 45 nm and more preferably 12 to 20 nm. A specific surface area of the titanium black is not particularly limited, but in order to set water repellency after the surface treatment with a water repellent agent to be specified performance, a value measured by Brunauer, Emmett, Teller (BET) method is preferably 5 to 150 m²/g and more preferably 20 to 100 m²/g.

Examples of the titanium black include Titanium black 10S, 12S, 13R, 13M, 13M-C, 13R, 13R—N, and 13M-T (trade name, manufactured by Mitsubishi Materials Corporation), Tilack D (trade name, manufactured by Akokasei Co., Ltd.), and MT-150A (trade name, manufactured by TAYCA Co., Ltd.).

The curable composition also preferably contains the titanium black as a dispersoid containing titanium black and an Si atom. In this aspect, the titanium black is contained as the dispersoid in the curable composition. A content ratio (Si/Ti) of Si atoms to Ti atoms in the dispersoid is preferably 0.05 to 0.5, more preferably 0.07 to 0.4 in terms of mass. Here, the above-described dispersoid includes both those in which the titanium black is in a state of primary particle and those in which the titanium black is in a state of aggregate (secondary particle).

In addition, in a case where Si/Ti of the dispersoid is a predetermined value or more, a residue is less likely to remain in a removed portion in a case where a composition layer using the dispersoid is patterned by optical lithography or the like, and in a case where Si/Ti of the dispersoid is a predetermined value or less, light shielding performance tends to be good.

In order to change Si/Ti of the dispersoid (for example, to make it 0.05 or more), the following method can be used. First, a dispersion is obtained by dispersing titanium oxide and silica particles using a disperser, and by reducing the mixture at a high temperature (for example, 850° C. to 1000° C.), a dispersoid containing titanium black particles as a main component and containing Si and Ti can be obtained. The titanium black having the adjusted Si/Ti can be produced, for example, according to the method described in paragraphs [0005] and [0016] to [0021] of JP2008-266045A.

The content ratio (Si/Ti) of Si atoms to Ti atoms in the dispersoid is measured, for example, using the method (2-1) or the method (2-3) described in paragraphs [0054] to [0056] of WO2011/049090A.

In the dispersoid containing titanium black and Si atom, the above-described titanium black can be used. In addition, in the dispersoid, for the purpose of adjusting dispersibility, colorability, and the like, in addition to the titanium black, one or two or more black pigments consisting of composite oxides of a plurality of metals selected from Cu, Fe, Mn, V, Ni, and the like, cobalt oxide, iron oxide, carbon black, and aniline black may be used in combination as the dispersoid. In this case, it is preferable that the dispersoid consisting of titanium black occupies 50% by mass or more of the total dispersoid.

Examples of the black inorganic pigment also include carbon black.

Examples of the carbon black include furnace black, channel black, thermal black, acetylene black, and lamp black.

As the carbon black, carbon black produced by a known method such as an oil furnace method may be used, or a commercially available product may be used.

Examples of a commercially available product of the carbon black include inorganic pigments such as C. I. Pigment Black 7.

As the carbon black, surface-treated carbon black is preferable. By the surface treatment, a particle surface state of the carbon black can be reformed, and dispersion stability in the curable composition can be improved. Examples of the surface treatment include a coating treatment with a resin, a surface treatment for introducing an acidic group, and a surface treatment with a silane coupling agent.

As the carbon black, carbon black coated with a resin is preferable. By coating the surface of the carbon black particles with an insulating resin, light shielding properties and insulating properties of the cured film can be improved. In addition, reliability or the like of an image display apparatus can be improved by reducing a leakage current or the like. Therefore, the cured film is suitable for use in applications where light shielding properties and insulating properties are required.

Examples of the coating resin include an epoxy resin, polyamide, polyamidoimide, a novolac resin, a phenol resin, a urea resin, a melamine resin, polyurethane, a diallyl phthalate resin, an alkylbenzene resin, polystyrene, polycarbonate, polybutylene terephthalate, and modified polyphenylene oxide.

From the viewpoint that the light shielding properties and the insulating properties of the cured film are more excellent, a content of the coating resin is preferably 0.1% to 40% by mass and more preferably 0.5% to 30% by mass with respect to the total of the carbon black and the coating resin.

Examples of the inorganic pigment used as the black pigment include zirconium of JP2017-222559A, WO2019/130772, WO2019/059359, and JP2009-091205A, the contents of which are incorporated into the present specification.

### Black Organic Pigment

The black pigment may be an organic pigment, and the black coloring material preferably includes a black organic pigment. The organic pigment used as the black pigment is not particularly limited as long as particles have light shielding properties and contain an organic compound, and a known organic pigment can be used.

In the present invention, examples of the organic pigment include a bisbenzofuranone compound, an azomethine compound, a perylene compound, and an azo compound; and among these, a bisbenzofuranone compound or a perylene compound is preferable.

Examples of the bisbenzofuranone compound include the compounds described in JP2010-534726A, JP2012-515233A, and JP2012-515234A, and the like. The bisbenzofuranone compound is available, for example, as “Irgaphor Black” (trade name) manufactured by BASF.

Examples of the perylene compound include the compounds described in JP1987-001753A (JP-S62-001753A) and JP1988-026784B (JP-S63-026784B). The perylene compound is available as C. I. Pigment Black 21, 30, 31, 32, 33, and 34.

### —Chromatic Coloring Material—

In a case where the cured film obtained by the method for manufacturing a cured film according to the embodiment of the present invention is used as a color filter, the curable composition preferably contains a chromatic coloring material.

Examples of the chromatic coloring material include a coloring material having a maximal absorption wavelength in a wavelength range of 400 to 700 nm. Examples thereof include a green coloring material, a red coloring material, a yellow coloring material, a violet coloring material, a blue coloring material, and an orange coloring material.

Examples of the green coloring material include a phthalocyanine compound and a squarylium compound, and a phthalocyanine compound is preferable.

In addition, as the green coloring material, the compounds described in paragraph [0043] of WO2021/182268A can also be used.

Examples of the red coloring material include a diketopyrrolopyrrole compound, an anthraquinone compound, an azo compound, a naphthol compound, an azomethine compound, a xanthene compound, a quinacridone compound, a perylene compound, and a thioindigo compound; and a diketopyrrolopyrrole compound, an anthraquinone compound, or an azo compound is preferable, and a diketopyrrolopyrrole compound is more preferable. In addition, the red coloring material is preferably a pigment. Specific examples of the red coloring material include red pigments such as Color Index (C. I.) Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 269, 270, 272, 279, 291, 294, 295, 296, and 297. In addition, as the red coloring material, the compounds described in paragraphs [0048] and [0049] of WO2021/182268A can also be used.

Examples of the yellow coloring material include an azo compound, an azomethine compound, an isoindoline compound, a pteridine compound, a quinophthalone compound, a perylene compound, and an azobarbituric acid nickel complex. As the yellow coloring material, a pigment is preferable; an azo pigment, an azomethine pigment, an isoindoline pigment, a pteridin pigment, a quinophthalone pigment, or a perylene pigment is more preferable; and an azo pigment or an azomethine pigment is still more preferable. Specific examples of the yellow coloring material include yellow pigments such as C. I. Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, 214, 215, 228, 231, 232, 233, 234, 235, and 236.

In addition, as the yellow coloring material, the compounds described in paragraphs [0045] to [0047] of WO2021/182268A can also be used.

Examples of the orange coloring material include orange pigments such as C. I. Pigment Orange 2, 5, 13, 16, 17:1, 31, 34, 36, 38, 43, 46, 48, 49, 51, 52, 55, 59, 60, 61, 62, 64, 71, and 73.

Examples of the violet coloring material include violet pigments such as C. I. Pigment Violet 1, 19, 23, 27, 32, 37, 42, 60, and 61.

Examples of the blue coloring material include C. I. Pigment Blue 1, 2, 15, 15:1, 15:2, 15:3, 15:4, 15:6, 16, 22, 29, 60, 64, 66, 79, 80, 87, and 88. In addition, as the blue coloring material, the compounds described in paragraph [0044] of WO2021/182268A can also be used.

A dye can also be used as the chromatic coloring material. As the dye, a known dye can be used without any particular limitation. Examples thereof include a pyrazoleazo-based dye, an anilinoazo-based dye, a triarylmethane-based dye, an anthraquinone-based dye, an anthrapyridone-based dye, a benzylidene-based dye, an oxonol-based dye, a pyrazolotriazoleazo-based dye, a pyridoneazo-based dye, a cyanine-based dye, a phenothiazine-based dye, a pyrrolopyrazoleazomethine-based dye, a xanthene-based dye, a phthalocyanine-based dye, a benzopyran-based dye, an indigo-based dye, and a pyrromethene-based dye.

### —White Coloring Material—

Examples of the white coloring material include inorganic pigments (white pigments) such as titanium oxide, strontium titanate, barium titanate, zinc oxide, magnesium oxide, zirconium oxide, aluminum oxide, barium sulfate, silica, talc, mica, aluminum hydroxide, calcium silicate, aluminum silicate, and zinc sulfide.

In addition, as the white pigment, the titanium oxide described in “Titanium Oxide-Physical Properties and Applied Technology, written by Manabu Kiyono, pages 13 to 45, published on Jun. 25, 1991, published by Gihodo Shuppan Co., Ltd.” can also be used.

The white pigment is preferably particles having a titanium atom, more preferably titanium oxide. In addition, the white pigment is preferably particles having a refractive index of 2.10 or more with respect to light having a wavelength of 589 nm. The above-described refractive index is preferably 2.10 to 3.00 and more preferably 2.50 to 2.75.

The white pigment is not limited to a compound formed of a single inorganic substance, and may be particles combined with other materials. For example, it is preferable to use a particle having a pore or other materials therein, a particle having a number of inorganic particles attached to a core particle, or a core-shell composite particle composed of a core particle formed of polymer particles and a shell layer formed of inorganic fine nanoparticles. With regard to the core-shell composite particle composed of a core particle formed of polymer particles and a shell layer formed of inorganic fine nanoparticles, reference can be made to, for example, the descriptions in paragraphs [0012] to [0042] of JP2015-047520A, the contents of which are incorporated into the present specification.

As the white pigment, hollow inorganic particles can also be used. The hollow inorganic particles refer to inorganic particles having a structure with a cavity therein, and the cavity is enclosed by an outer shell. As the hollow inorganic particles, hollow inorganic particles described in JP2011-075786A, WO2013/061621A, JP2015-164881A, and the like can be used, the contents of which are incorporated herein by reference.

### —Near Infrared Absorber—

The near infrared absorber may be any of a pigment or a dye, but a pigment is preferable and an organic pigment is more preferable.

The near infrared absorber is preferably a compound having a maximal absorption wavelength in a wavelength range of more than 700 nm and 1,400 nm or less. The maximal absorption wavelength of the near infrared absorber is preferably 1,200 nm or less, more preferably 1,000 nm or less, and still more preferably 950 nm or less.

In addition, in the near infrared absorber, A₅₅₀/Aₘₐₓ, which is a ratio of an absorbance A₅₅₀ at a wavelength of 550 nm to an absorbance Aₘₐₓ at the maximal absorption wavelength, is preferably 0.1 or less, more preferably 0.05 or less, still more preferably 0.03 or less, and particularly preferably 0.02 or less. The lower limit thereof is not particularly limited, but for example, can be 0.0001 or more and may be 0.0005 or more.

The near infrared absorber is not particularly limited, and examples thereof include a pyrrolopyrrole compound, a copper compound, a cyanine compound, a phthalocyanine compound, an iminium compound, a thiol complex-based compound, a transition metal oxide-based compound, a squarylium compound, a naphthalocyanine compound, a quaterylene compound, a merocyanine compound, an oxonol compound, an iminium compound, a dithiol compound, a triarylmethane compound, a pyrromethene compound, an azomethine compound, an anthraquinone compound, a dibenzofuranone compound, a dithiolene metal complex, a dithiol metal complex-based compound, and a croconium compound.

As the phthalocyanine compound, naphthalocyanine compound, iminium compound, cyanine compound, squarylium compound, and croconium compound, compounds described in paragraphs 0010 to 0081 of JP2010-111750A may also be used, the contents of which are incorporated herein by reference. Regarding the cyanine compound, reference can be made to, for example, “Functional Dyes, written by Makoto OKAWARA, Masaru MATSUOKA, Teijiro KITAO, and Tsuneaki HIRASHIMA, Kodansha Scientific Ltd.”, the contents of which are incorporated herein by reference.

As the colorant having the above-described spectral characteristics, compounds described in paragraphs 0004 to 0016 of JP1995-164729A (JP-H07-164729A) and/or compounds described in paragraphs 0027 to 0062 of JP2002-146254A, or near infrared absorbing particles consisting of crystallites of oxides containing Cu and/or P described in paragraphs 0034 to 0067 of JP2011-164583A and having a number average aggregated particle diameter of 5 to 200 nm can also be used.

As the compound having a maximal absorption wavelength in a wavelength range of 675 to 900 nm, at least one selected from the group consisting of a cyanine compound, a pyrrolopyrrole compound, a squarylium compound, a phthalocyanine compound, and a naphthalocyanine compound is preferable.

Regarding the pyrrolo pyrrole compound, reference can be made to paragraphs 0049 to 0062 of JP2010-222557A, the contents of which are incorporated into the present specification. Regarding the cyanine compound and the squarylium compound, reference can be made to paragraphs 0022 to 0063 of WO2014/088063A, paragraphs 0053 to 0118 of WO2014/030628A, paragraphs 0028 to 0074 of JP2014-59550A, paragraphs 0013 to 0091 of WO2012/169447A, paragraphs 0019 to 0033 of JP2015-176046A, paragraphs 0053 to 0099 of JP2014-63144A, paragraphs 0085 to 0150 of JP2014-52431A, paragraphs 0076 to 0124 of JP2014-44301A, paragraphs 0045 to 0078 of JP2012-8532A, paragraphs 0027 to 0067 of JP2015-172102A, paragraphs 0029 to 0067 of JP2015-172004A, paragraphs 0029 to 0085 of JP2015-40895A, paragraphs 0022 to 0036 of JP2014-126642A, paragraphs 0011 to 0017 of JP2014-148567A, paragraphs 0010 to 0025 of JP2015-157893A, paragraphs 0013 to 0026 of JP2014-095007A, paragraphs 0013 to 0047 of JP2014-80487A, paragraphs 0007 to 0028 of JP2013-227403A, and the like, the contents of which are incorporated into the present specification.

A content of the coloring material is preferably 10% to 90% by mass, more preferably 25% to 80% by mass, still more preferably 30% to 80% by mass, and particularly preferably 30% to 70% by mass with respect to the total solid content of the curable composition. The curable composition may include only one kind of the coloring material or two or more kinds thereof. In a case of containing two or more kinds thereof, the total amount thereof is preferably within the above-described range.

### <Photopolymerization Initiator>

The curable composition 1 preferably further contains at least one component selected from the group consisting of a photopolymerization initiator, a thermal crosslinking compound, a surfactant, and a solvent, which will be described in detail later, in addition to the above-described components. Hereinafter, each of the above-described components will be described in detail.

The photopolymerization initiator is not particularly limited as long as the photopolymerization initiator can initiate the polymerization of the polymerizable compound, and known photopolymerization initiators can be used.

As the photopolymerization initiator, for example, a photopolymerization initiator exhibiting photosensitivity from an ultraviolet range to a visible light range is preferable. In addition, the photopolymerization initiator may be an activator which generates active radicals by causing a certain action with a photoexcited sensitizer, or an initiator which initiates cationic polymerization according to the type of the polymerizable compound.

As the photopolymerization initiator, a so-called radical polymerization initiator is preferable.

Examples of the photopolymerization initiator include a halogenated hydrocarbon derivative (for example, a compound including a triazine skeleton, a compound including an oxadiazole skeleton, or the like), an acyl phosphine compound such as acyl phosphine oxide, hexaaryl biimidazole, an oxime compound such as an oxime derivative, an organic peroxide, a thio compound, a ketone compound, an aromatic onium salt, an aminoacetophenone compound, and hydroxyacetophenone.

Regarding specific examples of the photopolymerization initiator, reference can be made to, for example, paragraphs 0265 to 0268 of JP2013-029760A, the contents of which are incorporated into the present specification.

### (Oxime Compound)

As the photopolymerization initiator, an oxime ester-based polymerization initiator (oxime compound) is preferable. In particular, an oxime compound has high sensitivity and high polymerization efficiency, and easily designs the content of the pigment in the curable composition to be high, which is preferable.

Examples of the oxime compound include the compound described in JP2001-233842A, the compound described in JP2000-080068A, and the compound described in JP2006-342166A.

Examples of the oxime compound include 3-benzoyloxyiminobutan-2-one, 3-acetoxyiminobutan-2-one, 3-propionyloxyiminobutan-2-one, 2-acetoxyiminopentan-3-one, 2-acetoxyimino-1-phenylpropan-1-one, 2-benzoyloxyimino-1-phenylpropan-1-one, 3-(4-toluenesulfonyloxy)iminobutan-2-one, and 2-ethoxycarbonyloxyimino-1-phenylpropan-1-one.

Furthermore, the compounds described in J. C. S. Perkin II (1979) pp. 1653 to 1660, J. C. S. Perkin II (1979) pp. 156 to 162, Journal of Photopolymer Science and Technology (1995) pp. 202 to 232, JP2000-066385A, JP2000-080068A, JP2004-534797A, and JP2006-342166A can also be mentioned.

Examples of a commercially available product thereof also include IRGACURE-OXE01 (manufactured by BASF SE), IRGACURE-OXE02 (manufactured by BASF SE), IRGACURE-OXE03 (manufactured by BASF SE), and IRGACURE-OXE04 (manufactured by BASF SE). In addition, examples thereof also include TR-PBG-304 (manufactured by TRONLY), ADEKA ARKLS NCI-730, ADEKA ARKLS NCI-831, and ADEKA ARKLS NCI-930 (manufactured by ADEKA CORPORATION), and N-1919 (carbazole and oxime ester skeleton-containing photoinitiator (manufactured by ADEKA CORPORATION)). In addition, examples thereof also include Omnirad 1316 (IGM Resins B.V.).

In addition, examples of oxime compounds other than the above-described oxime compounds include the compound which is described in JP2009-519904A and in which oxime is linked to a N-position of carbazole; the compound which is described in U.S. Pat. No. 7,626,957B and in which a hetero substituent is introduced into a benzophenone moiety; the compounds which are described in JP2010-015025A and US2009/292039A and in which a nitro group is introduced into the moiety of a coloring agent; the ketoxime compound described in WO2009/131189A; the compound which is described in U.S. Pat. No. 7,556,910B and includes a triazine skeleton and an oxime skeleton in the same molecule; and the compound which is described in JP2009-221114A, has an absorption maximum at 405 nm, and exhibits favorable sensitivity with respect to a light source of a g-line.

Reference can be made to, for example, paragraphs 0274 and 0275 of JP2013-029760A, the contents of which are incorporated into the present specification.

Examples of the photopolymerization initiator also include a fluorine atom-containing oxime compound. Examples of the fluorine atom-containing oxime compound include the compound described in JP2010-262028A; the compounds 24 and 36 to 40 described in JP2014-500852A; and the compound (C-3) described in JP2013-164471A. The contents thereof are incorporated into the present specification.

Examples of the polymerization initiator also include compounds represented by Formulae (1) to (4).

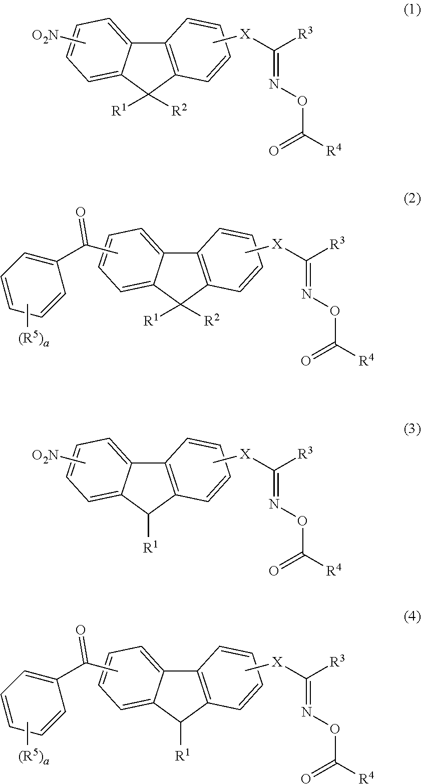

In Formula (1), R¹ and R² each independently represent an alkyl group having 1 to 20 carbon atoms, an alicyclic hydrocarbon group having 4 to 20 carbon atoms, an aryl group having 6 to 30 carbon atoms, or an aryl alkyl group having 7 to 30 carbon atoms, in a case where R¹ and R² each represent a phenyl group, the phenyl groups may be bonded to each other to form a fluorene group, R³ and R⁴ each independently represent a hydrogen atom, an alkyl group having 1 to 20 carbon atoms, an aryl group having 6 to 30 carbon atoms, an aryl alkyl group having 7 to 30 carbon atoms, or a heterocyclic group having 4 to 20 carbon atoms, and X represents a direct bond or a carbonyl group.

In Formula (2), R¹, R², R³, and R⁴ have the same definitions as R¹, R², R³, and R⁴ in Formula (1), R⁵ represents —R⁶, —OR⁶, —SR⁶, —COR⁶, —CONR⁶R⁶, —NR⁶COR⁶, —OCOR⁶, —COOR⁶, —SCOR⁶, —OCSR⁶, —COSR⁶, —CSOR⁶, —CN, a halogen atom, or a hydroxyl group, R⁶ represents an alkyl group having 1 to 20 carbon atoms, an aryl group having 6 to 30 carbon atoms, an aryl alkyl group having 7 to 30 carbon atoms, or a heterocyclic group having 4 to 20 carbon atoms, X represents a direct bond or a carbonyl group, and a represents an integer of 0 to 4.

In Formula (3), R¹ represents an alkyl group having 1 to 20 carbon atoms, an alicyclic hydrocarbon group having 4 to 20 carbon atoms, an aryl group having 6 to 30 carbon atoms, or an aryl alkyl group having 7 to 30 carbon atoms, R³ and R⁴ each independently represent a hydrogen atom, an alkyl group having 1 to 20 carbon atoms, an aryl group having 6 to 30 carbon atoms, an aryl alkyl group having 7 to 30 carbon atoms, or a heterocyclic group having 4 to 20 carbon atoms, and X represents a direct bond or a carbonyl group.

In Formula (4), R¹, R³, and R⁴ have the same definitions as R¹, R³, and R⁴ in Formula (3), R⁵ represents —R⁶, —OR⁶, —SR⁶, —COR⁶, —CONR⁶R⁶, —NR⁶COR⁶, —OCOR⁶, —COOR⁶, —SCOR⁶, —OCSR⁶, —COSR⁶, —CSOR⁶, —CN, a halogen atom, or a hydroxyl group, R⁶ represents an alkyl group having 1 to 20 carbon atoms, an aryl group having 6 to 30 carbon atoms, an aryl alkyl group having 7 to 30 carbon atoms, or a heterocyclic group having 4 to 20 carbon atoms, X represents a direct bond or a carbonyl group, and a represents an integer of 0 to 4.

Examples of the compounds represented by Formula (1) and Formula (2) include the compound described in paragraphs 0076 to 0079 of JP2014-137466A. The contents thereof are incorporated into the present specification.

In addition, as the photopolymerization initiator, a compound represented by Formula (1) is also preferable.

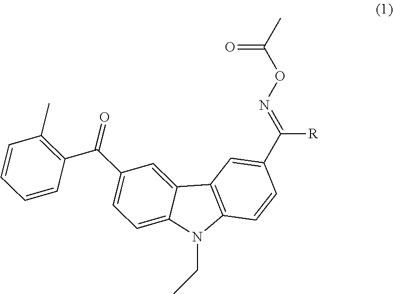

In Formula (1), R represents a group represented by Formula (1a).

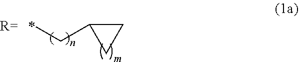

In Formula (1a), n represents an integer of 1 to 5. m represents an integer of 1 to 6. * represents a bonding position.
m is preferably 3 or 4.

For example, the compound represented by Formula (1) can be synthesized according to the synthesis method described in JP2012-519191A.

The oxime compound preferably has a maximal absorption wavelength in a wavelength range of 350 to 500 nm, more preferably has a maximal absorption wavelength in a wavelength range of 360 to 480 nm, and still more preferably has a high absorbance at wavelengths of 365 nm and 405 nm.

From the viewpoint of sensitivity, a molar absorption coefficient of the oxime compound at 365 nm or 405 nm is preferably 1,000 to 300,000, more preferably 2,000 to 300,000, and still more preferably 5,000 to 200,000.

The molar absorption coefficient of the compound can be measured by known methods, but for example, it is preferable that the measurement is carried out with an ultraviolet and visible spectrophotometer (Cary-5 polymerization initiator manufactured by Varian, Inc.) at a concentration of 0.01 g/L using ethyl acetate.

In addition, as the photopolymerization initiator, the compounds described in paragraph 0052 of JP2008-260927A, paragraphs 0033 to 0037 of JP2010-097210A, and paragraph 0044 of JP2015-068893A can also be used, the contents of which are incorporated into the present specification.

A content of the photopolymerization initiator in the curable composition is preferably 0.5% to 20% by mass, more preferably 1.0% to 10% by mass, and still more preferably 1.5% to 8% by mass with respect to the total solid content of the curable composition.

The photopolymerization initiator may be used singly or in combination of two or more thereof. In a case where two or more photopolymerization initiators are used in combination, it is preferable that the total amount thereof is within the above-described range.

### <Thermal Crosslinking Compound>

The curable composition 1 may contain a thermal crosslinking compound, and the thermal crosslinking compound may be an epoxy group-containing compound.

Examples of the epoxy group-containing compound include a compound having one or more epoxy groups, and a compound having two or more epoxy group is preferable. It is preferable that 1 to 100 epoxy groups are included. The upper limit thereof may be 10 or less or 5 or less, for example. The lower limit thereof is preferably 2 or more.

In addition, the epoxy group-containing compound means a component different from the above-described dispersant, alkali-soluble resin, and polymerizable compound.

An epoxy equivalent (=molecular weight of epoxy group-containing compound/number of epoxy groups) of the epoxy group-containing compound is preferably equal to or less than 500 g/equivalent, more preferably 100 to 400 g/equivalent, and still more preferably 100 to 300 g/equivalent.

The epoxy group-containing compound may be a low-molecular-weight compound (for example, the molecular weight is less than 2,000) or a high-molecular-weight compound (macromolecule) (for example, the molecular weight is 2,000 or more, and in a case of a polymer, the weight-average molecular weight is 2,000 or more). A weight-average molecular weight of the epoxy group-containing compound is preferably 200 to 100,000 and more preferably 500 to 50,000. The upper limit of the weight-average molecular weight is more preferably 10,000 or less, still more preferably 5,000 or less, and particularly preferably 3,000 or less.

A commercially available product may be used for the epoxy group-containing compound. Examples thereof include EHPE 3150 (manufactured by Daicel Corporation), EOCN-1020 (manufactured by Nippon Kayaku Co., Ltd.), EPICLON N-695 (manufactured by DIC Corporation), and CELLOXIDE 2021P (manufactured by Daicel Corporation).

Moreover, examples of the epoxy group-containing compound also include the compounds described in paragraphs 0034 to 0036 of JP2013-011869A, paragraphs 0147 to 0156 of JP2014-043556A, and paragraphs 0085 to 0092 of JP2014-089408A. The contents of the above-described documents are incorporated into the present specification.

A content of the thermal crosslinking compound in the curable composition is not particularly limited, but is preferably 0.001% to 10% by mass, more preferably 0.01% to 8% by mass, and still more preferably 0.01% to 6% by mass with respect to the total solid content of the curable composition.

The thermal crosslinking compound may be used alone or in combination of two or more thereof. In a case where the curable composition contains two or more kinds of thermal crosslinking compounds, it is preferable that the total content thereof is within the above-described range.

### <Surfactant>

The curable composition 1 may contain a surfactant.

Examples of the surfactant include a silicone-based surfactant, a fluorine-based surfactant, a nonionic surfactant, a cationic surfactant, and an anionic surfactant.

Among them, from the viewpoint that the effect of the present invention is more excellent, a silicone-based surfactant is preferable.

Examples of the silicone-based surfactant include a linear polymer consisting of a siloxane bond and a modified siloxane polymer with an organic group introduced in the side chain and/or the terminal.

As a suitable aspect of the silicone-based surfactant, from the viewpoint that the effect of the present invention is more excellent, an aromatic group-modified silicone-based surfactant (silicone-based surfactant having an aromatic group) is preferable, and a phenyl-modified silicone-based surfactant (silicone-based surfactant having a phenyl group) is more preferable.

A content of the surfactant in the curable composition is not particularly limited, but is preferably 0.001% to 2.0% by mass, more preferably 0.005% to 0.5% by mass, and still more preferably 0.01% to 0.1% by mass with respect to the total solid content of the curable composition.

The surfactant may be used alone or in combination of two or more thereof. In a case where two or more surfactants are used in combination, the total amount thereof is preferably within the above-described range.

### <Solvent>

The curable composition 1 may contain a solvent.

The solvent is not particularly limited and a known solvent can be used, and examples thereof include an organic solvent and water.

Examples of the organic solvent include acetone, methyl ethyl ketone, cyclohexane, ethylene dichloride, tetrahydrofuran, toluene, ethylene glycol monomethyl ether, ethylene glycol monoethyl ether, ethylene glycol dimethyl ether, 1-methoxy-2-propanol (propylene glycol monomethyl ether, PGME), propylene glycol monoethyl ether, acetylacetone, cyclohexanone, cyclopentanone, diacetone alcohol, ethylene glycol monomethyl ether acetate, ethylene glycol ethyl ether acetate, ethylene glycol monoisopropyl ether, ethylene glycol monobutyl ether acetate, 3-methoxypropanol, diethylene glycol monomethyl ether, diethylene glycol monoethyl ether, diethylene glycol dimethyl ether, diethylene glycol diethyl ether, propylene glycol monomethyl ether acetate (PGMEA), propylene glycol monoethyl ether acetate, 3-methoxypropyl acetate, N,N-dimethylformamide, dimethyl sulfoxide, γ-butyrolactone, ethyl acetate, butyl acetate, methyl lactate, N-methyl-2-pyrrolidone, ethyl lactate, 3-methoxybutanol, 1,3-butanediol, 2,3-butanediol, propylene glycol, ethylene glycol, dimethyl sulfoxide, and γ-valerolactone; but the organic solvent is not limited thereto.

A content of the solid contents in the curable composition is preferably 10% to 90% by mass, more preferably 10% to 50% by mass, and still more preferably 15% to 30% by mass with respect to the total mass of the curable composition.

The solvent may be used alone or in combination of two or more thereof. In a case where two or more kinds of solvents are used in combination, the total content thereof is preferably adjusted so that the total solid content of the curable composition is within the above-described range.

### <Other Optional Components>

The curable composition 1 may further contain optional components other than the above-described components. Examples thereof include a silane coupling agent, an ultraviolet absorber, a polymerization inhibitor, a sensitizer, a co-sensitizer, a crosslinking agent, a curing accelerator, a filler, a heat curing accelerator, a plasticizer, a diluent, and an oil sensitizing agent; and known additives such as an adhesion promoter to the surface of the substrate and other auxiliaries (for example, conductive particles, a filling agent, an anti-foaming agent, a flame retardant, a leveling agent, a peeling accelerator, an antioxidant, a fragrance, a surface tension adjuster, a chain transfer agent, and the like) may be added as necessary.

Regarding these components, reference can be made to, for example, the descriptions in paragraphs 0183 to 0228 of JP2012-003225A (corresponding to paragraphs 0237 to 0309 of US2013/0034812A), paragraphs 0101, 0102, 0103, 0104, and 0107 to 0109 of JP2008-250074A, and paragraphs 0159 to 0184 of JP2013-195480A, the contents of which are incorporated into the present specification.

In the curable composition 1, it is preferable that a content of the particles having a large particle size is small. More specifically, in a (volume-based) particle diameter distribution obtained by measuring the curable composition 1 with a particle size distribution analyzer, a proportion of particles having a particle size of 200 nm or more (hereinafter, also simply referred to as “specific particles”) is preferably 5% or less. Among these, the proportion of the specific particles is more preferably 3% or less, and still more preferably 1% or less. The lower limit thereof is not particularly limited, but may be, for example, 0%.

The particle diameter distribution can be measured, for example, with a particle size distribution analyzer Nanotrac UPA (manufactured by MicrotracBEL Corp.) to measure a measurement solution obtained by diluting the curable composition or a solvent (propylene glycol monomethyl ether acetate or the like) to any concentration (1% by mass or the like). Examples of the particles which can be measured with the above-described particle size distribution analyzer include the above-described coloring materials in a particulate form (coloring material particles) and fillers other than the coloring materials.

### [Method for Producing Curable Composition 1]

A method for producing the curable composition 1 is not particularly limited, but it is preferable to produce a dispersion composition in which a pigment is dispersed, and then mix the obtained dispersion composition with other components to obtain a composition.

The dispersion composition is preferably prepared by mixing the pigment, the resin A, and the solvent. Moreover, it is also preferable that a polymerization inhibitor is introduced into the dispersion composition.

The dispersion composition can be prepared by mixing the respective components described above by known mixing methods (for example, mixing methods using a stirrer, a homogenizer, a high-pressure emulsification device, a wet-type pulverizer, a wet-type disperser, or the like).

After the preparation of the dispersion composition, the dispersion composition, the resin B, the polymerizable compound, and other optional components can be mixed and prepared.

In the preparation of the curable composition, each component may be blended together, or each component may be dissolved or dispersed in a solvent and then sequentially blended. In addition, the input order and the operation conditions during the formulation are not particularly limited.

For the purpose of removing foreign matters, reducing defects, and the like, the curable composition 1 is preferably filtered through a filter.

A pore diameter of the filter is preferably 0.1 to 7.0 μm, more preferably 0.2 to 2.5 μm, still more preferably 0.2 to 1.5 μm, and particularly preferably 0.3 to 0.7 km. In a case where the pore diameter is within the above range, it is possible to reliably remove fine foreign matters such as impurities and aggregates contained in a pigment while suppressing filtration clogging of the pigment (including the black pigment).

It is preferable that the curable composition 1 does not contain impurities such as metals, metal salts containing halogens, acids, and alkalis. The content of impurities included in these materials is preferably 1 ppm by mass or less, more preferably 1 ppb by mass or less, still more preferably 100 ppt by mass or less, particularly preferably 10 ppt by mass or less, and it is most preferable that the impurities are not substantially included (below the detection limit of a measuring device).

Furthermore, the impurities can be measured using an inductively coupled plasma mass spectrometer (manufactured by Agilent Technologies, Inc., Agilent 7500cs model).

### Procedure of Step 1

The step 1 is a step of forming a curable composition layer on a support using the above-described curable composition 1.

As the support, a substrate having an alignment mark, which serves as a reference for the registration between the support and the exposure mask, is preferable. In a case where the substrate having an alignment mark is used as the support, the curable composition layer may be formed on the substrate so as to cover the alignment mark. That is, the curable composition layer may be formed on the alignment mark.

As the substrate, for example, a glass substrate, a silicon substrate (may be subjected to a hydrophobic treatment or the like with hexamethyldisilazane), or a solid-state imaging element substrate on which a charge coupled device (CCD), a complementary metal-oxide semiconductor (CMOS), or the like (light-receiving element) is provided on the silicon substrate can be used.

In addition, in order to improve adhesion with the upper layer, prevent the diffusion of substances, and planarize the surface of the substrate, an undercoat layer may be provided on the support, as needed.

Examples of a method for applying the curable composition onto the support include various coating methods such as a slit coating method, an ink jet method, a spin coating method, a cast coating method, a roll coating method, and a screen printing method. A film thickness of the composition layer is preferably 0.1 to 10 μm, more preferably 0.2 to 5 μm, and still more preferably 0.2 to 3 μm.

It is preferable that the composition layer applied onto the support is dried (pre-baked) by heating. The pre-baking can be performed, for example, using a hot plate or an oven.

From the viewpoint that the effect of the present invention is more excellent, a pre-baking temperature is preferably 50° C. to 140° C., more preferably 60° C. to 120° C., and still more preferably 70° C. to 100° C. From the viewpoint that the effect of the present invention is more excellent, a pre-baking time is preferably 10 to 300 seconds, more preferably 60 to 240 seconds, and still more preferably 80 to 200 seconds.

In a case where at least one of the heating temperature or the heating time is within the above-described range, visibility of the alignment mark or the like is not impaired, and thus, in the step 2 described later, the registration between the support and the exposure mask can be easily performed.

From the viewpoint that the visibility of the alignment mark or the like is not impaired and the positioning of the mask during exposure can be easily performed, it is preferable that a surface roughness of the curable composition layer obtained in the step 1 is in an appropriate range.

More specifically, it is preferable that an arithmetic average surface roughness Ra(a) of the curable composition layer obtained in the step 1, an average length Rsm(a) of elements, and a root-mean-square tilt RΔq(a) are in appropriate numerical ranges. In the present specification, Ra(a), Rsm(a), and RΔq(a) represent values measured in accordance with JIS-B-0601:2013.

Ra(a) is preferably 0.00 to 0.05 m and more preferably 0.00 to 0.02 km.

Rsm(a) is preferably 3 to 200 m and more preferably 5 to 100 μm.

RΔq(a) is preferably 0.0° to 3.5° and more preferably 0.0° to 1.0°.

### Step 2

The step 2 is a step of performing registration between the support on which the curable composition layer is formed in the step 1, and an exposure mask.

By performing the present step, a relative positional relationship between the support and the exposure mask is adjusted, and a predetermined position of the curable composition layer is exposed during the exposure described later.

Examples of a method of performing the registration between the support and the exposure mask include a method of using an alignment mark. As described above, examples thereof include a method of using a substrate having an alignment mark as the support and performing the registration between the support and the exposure mask based on the alignment mark. As described above, the curable composition layer may be formed on the alignment mark.

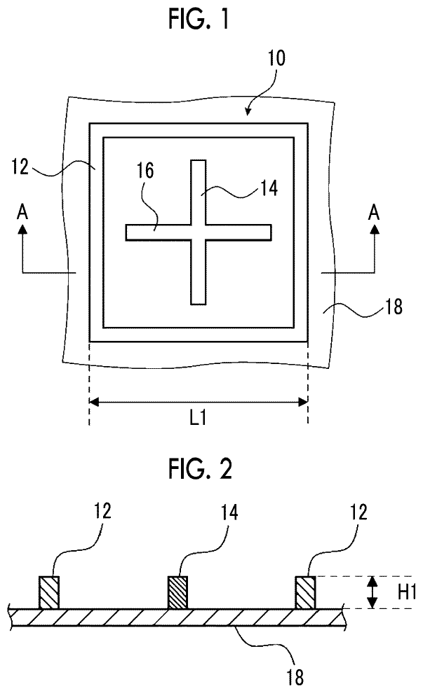

A shape of the alignment mark is not particularly limited, and examples thereof include examples shown in FIGS. 1 and 2. FIG. 1 is a schematic plan view of the alignment mark. FIG. 2 is a schematic cross-sectional view taken along a line A-A in FIG. 1. An alignment mark 10 shown in FIGS. 1 and 2 is disposed on a support 18. The alignment mark 10 has a square frame portion 12 and a cross-shaped mark in which two lines (a vertical line 14 and a horizontal line 16) intersect each other, which is disposed inside the frame portion 12.

In FIG. 1, L1 indicates a length of one side of the outer periphery of the frame portion 12, and may be, for example, approximately 60 am. In FIG. 2, H1 indicates a height of the frame portion 12, and may be 0.6 km.

The procedure for performing the registration between the support and the exposure mask is not particularly limited, and a known method can be used. For example, the position of the alignment mark may be detected by visual observation, an optical microscope, an optical sensor, image processing using a camera, or the like; and the exposure mask may be registered with the position.

### Step 3

The step 3 is a step of exposing the curable composition layer through the exposure mask registered in the above-described step 2.

Specifically, the exposure treatment is a step of exposing the composition layer formed in the above-described step 1 by irradiating the composition layer with actinic rays or radiations to cure a light irradiation region of the composition layer.

The exposure mask is not particularly limited, but light irradiation is preferably performed through a photo mask having a patterned opening portion.

The exposure is preferably performed by irradiation with radiation, ultraviolet rays such as a g-line, an h-line, and an i-line are particularly preferable as the radiations which can be used during the exposure, and a high-pressure mercury lamp is preferable as a light source. The irradiation intensity is preferably 5 to 1,500 mJ/cm² and more preferably 10 to 1,000 mJ/cm².

### Step 4

The step 4 is a step of performing a development treatment on the curable composition layer after the exposure to form a cured film in a patterned shape.

By this step, the composition layer in the light exposed region in the exposure step is eluted, and only the photocured portion remains.

A type of a developer used in the development step is not particularly limited, but an alkali developer which does not damage the underlying imaging element and circuit or the like is desirable.

A development temperature is preferably 20° C. to 30° C.

A development time is preferably 20 to 90 seconds. In order to further remove the residues, in recent years, the development may be performed for 120 to 180 seconds. Furthermore, in order to improve residue removability, a step of shaking off the developer every 60 seconds and further supplying a fresh developer may be repeated several times.

As the alkali developer, an alkaline aqueous solution prepared by dissolving an alkaline compound in water so that the concentration is 0.001% to 10% by mass (preferably, 0.01% to 5% by mass) is preferable.

Examples of the alkaline compound include sodium hydroxide, potassium hydroxide, sodium carbonate, sodium silicate, sodium metasilicate, aqueous ammonia, ethylamine, diethylamine, dimethylethanolamine, tetramethylammonium hydroxide, tetraethylammonium hydroxide, tetrapropylammonium hydroxide, tetrabutylammonium hydroxy, benzyltrimethylammonium hydroxide, choline, pyrrole, piperidine, and 1,8-diazabicyclo[5.4.0]-7-undecene (among these, organic alkalis are preferable).

In a case where an alkali developer is used, it is generally preferable to perform a rinsing treatment with water or the like after the development.

### Step 5

The step 5 is a step of performing a heating treatment (post-baking) on the patterned cured film obtained in the step 4. By the present step, the polymerizable compound in the curable composition is completely cured and shrunk to form a fine uneven structure on the surface of the cured film, and thus a film having excellent antireflection characteristics can be obtained.

The lower limit of the heating temperature of the post-baking is preferably 100° C. or higher, more preferably 150° C. or higher, still more preferably 200° C. or higher, particularly preferably 220° C. or higher, and most preferably 240° C. or higher.

The upper limit of the heating temperature of the post-baking is preferably 300° C. or lower, and more preferably 260° C. or lower.

The post-baking can be performed continuously or batchwise using a heating unit such as a hot plate, a convection oven (hot-air circulating dryer), and a radio-frequency heater. Among these, it is preferable that the post-baking is performed using a hot plate.

The post-baking is preferably performed in an atmosphere of a low oxygen concentration. The oxygen concentration is preferably 19% by volume or less, more preferably 15% by volume or less, still more preferably 10% by volume or less, particularly preferably 7% by volume or less, and most preferably 3% by volume or less. The lower limit thereof is not particularly limited, but is practically 10 ppm by volume or more.

[[Method for Manufacturing Cured Film (Second Embodiment)]]Hereinafter, the second embodiment of the present manufacturing method will be described in detail.

The second embodiment of the present manufacturing method includes the step 11 to the step 14. Hereinafter, each of the steps will be described in detail.

### Step 11

The step 11 is a step of forming a curable composition layer on a support, in which the curable composition contains a resin C, a resin H, and a polymerizable compound, an HSP distance between the resin C and the resin H is more than 1.5 MPa^{1/2}, and a ratio T2/T1 of a dissolution rate T2 of the resin H in a developer used in the development treatment to a dissolution rate T1 of the resin C in the developer is 10.0 or more.

Hereinafter, the curable composition used in the step 11 (hereinafter, also referred to as “curable composition 2”) and the procedure will be described in detail.

### [Curable Composition 2]

The curable composition 2 contains a resin C, a resin H, and a polymerizable compound. In addition, an HSP distance between the resin C and the resin H is more than 1.5 MPa^{1/2}, and a ratio T2/T1 of a dissolution rate T2 of the resin H in a developer used in the development treatment to a dissolution rate T1 of the resin C in the developer is 10.0 or more.

The definition and calculation method of the HSP distance are as described in detail, regarding the HSP distance between the resin A and the resin B contained in the curable composition 1.

In addition, the technical significance of the HSP distance between the resin C and the resin H being more than 1.5 MPa^{1/2} is as described in the technical significance of the HSP distance between the resin A and the resin B being more than 1.5 MPa^{1/2}.

### <Resin C>

The curable composition 2 contains the resin C. The resin C is not particularly limited as long as the relationship of the HSP distance and the relationship of the dissolution rate with the resin H are satisfied as described above.

The resin C preferably contains at least one of a repeating unit C1 having an acid group or a repeating unit C2 having at least one group of a polyoxyalkylene group having an average addition number of 3 or more or a polyoxyalkylene carbonyl group having an average addition number of 3 or more, and more preferably contains both the repeating unit C1 and the repeating unit C2.

Specific aspects and suitable aspects of the repeating unit C1 and the repeating unit C2, and a preferred content of each repeating unit with respect to all repeating units of the resin C are the same as those of the repeating unit A1 and the repeating unit A2. Among these, the content of the repeating unit C2 is preferably 35% by mass or more with respect to all repeating units of the resin C.

In addition, the resin C may contain the above-described repeating unit A3, and a preferred content of the repeating unit A3 with respect to all repeating units of the resin C is the same as that of the resin A.

The HSP distance between the resin C and the resin H is not particularly limited as long as it is more than 1.5 MPa^{1/2}, but is preferably more than 1.5 MPa^{1/2} and 5.0 MPa^{1/2} or less, and more preferably 2.0 to 4.0 MPa^{1/2}.

Suitable ranges of a dispersion element (δ_{d}), a polarity element (δₚ), and a hydrogen bond element (δₕ) of the Hansen solubility parameters of the resin C are respectively the same as the suitable ranges of the dispersion element (δ_{d}), the polarity element (δₚ), and the hydrogen bond element (δₕ) of the Hansen solubility parameters of the resin A.

Suitable ranges of a dispersion element (δ_{d}), a polarity element (δₚ), and a hydrogen bond element (δₕ) of the Hansen solubility parameters of the resin H are respectively the same as the suitable ranges of the dispersion element (δ_{d}), the polarity element (δₚ), and the hydrogen bond element (δₕ) of the Hansen solubility parameters of the resin B.

As described above, the ratio T2/T1 of the dissolution rate T2 (μm/sec) of the resin H in a developer used in the development treatment to the dissolution rate T1 (μm/sec) of the resin C in the developer is 10.0 or more.

From the viewpoint that the effect of the present invention is more excellent, the ratio T2/T1 is preferably 12.0 or more, and more preferably 15.0 or more. The upper limit thereof is not particularly limited, but is preferably 25.0 or less.

In a case where the ratio T2/T1 is within the above-described range, the resin H is easily developed with respect to the resin C in the step 14, and thus a fine uneven structure is easily formed on the cured film, and a cured film having excellent low reflection properties is obtained.

T1 and T2 are values obtained by the following procedure.

### (Measurement of Dissolution Rate)

The resin C or the resin H is diluted with PGMEA so that the solid content is 30% by mass, applied onto a silicon wafer using a spin coater, and heated at 90° C. for 2 minutes to dry the organic solvent, thereby obtaining a resin film having a film thickness of 10 μm. Next, the resin film is immersed in a developer (25° C.) used in the development treatment of the step 4 described later for 60 seconds, and then the film thickness after the immersion is measured with a film thickness meter. From the obtained measurement results, the dissolution rate of the resin is calculated based on the following expression (T).

Dissolution rate(μm/sec)=Amount of change in film thickness (μm)/Development time (sec) Expression (T)

From the viewpoint that the effect of the present invention is more excellent, an acid value of the resin C is preferably 50 mgKOH/g or more, more preferably 55 mgKOH/g or more, and still more preferably 60 mgKOH/g or more. The upper limit value thereof is preferably 200 mgKOH/g or less, more preferably 170 mgKOH/g or less, still more preferably 100 mgKOH/g or less, and particularly preferably 80 mgKOH/g or less. In addition, a resin having a desired acid value can be obtained by changing the content of the repeating unit including an acid group, which is the constitutional component of the resin C.

A weight-average molecular weight of the resin C is preferably 5,000 to 100,000, more preferably 6,000 to 80,000, still more preferably 15,000 to 40,000, and most preferably 20,000 to 40,000.

A content of the resin C in the curable composition 2 is not particularly limited, but is preferably 2% to 40% by mass, more preferably 5% to 30% by mass, and still more preferably 10% to 25% by mass with respect to the total solid content of the curable composition. The resin C may be used alone or in combination of two or more thereof. In a case where two or more resins A are used in combination, the total content thereof is preferably within the above-described range.

### <Resin H>

The curable composition 2 contains the resin H. The resin H is not particularly limited as long as the relationship of the HSP distance and the relationship of the dissolution rate with the resin C are satisfied as described above, but an acrylic resin or a methacrylic resin, in which an acid value is higher than the acid value of the resin C by 70 mgKOH/g or more, is preferable. In addition, it is also preferable that the resin H does not contain the repeating unit having a group selected from the group consisting of a polyoxyalkylene group having an average addition number of 3 or more and a polyoxyalkylene carbonyl group having an average addition number of 3 or more.

The resin H preferably contains the repeating unit B3 having a carboxylic acid group, and more preferably contains the repeating unit B3 having a carboxylic acid group and at least one repeating unit of the repeating unit B1 derived from an alkyl (meth)acrylate and the repeating unit B4. In addition, the resin H may contain the repeating unit B2.

Specific aspects and suitable aspects of the repeating units B1 to B4 are as described in detail for the resin B.

Among these, as the repeating unit B1 in the resin H, a repeating unit derived from an alkyl (meth)acrylate, in which the number of carbon atoms in an alkyl moiety in the alkyl (meth)acrylate is 1 to 4, is preferable.

Among these, the repeating unit B3 in the resin H is preferably a repeating unit derived from acrylic acid.

Among these, as the repeating unit B4 in the resin H, a repeating unit derived from benzyl (meth)acrylate is preferable.

In a case where the resin H contains the repeating unit B1, a content of the repeating unit B1 is preferably 10% by mass or more, more preferably 60% by mass or more, and still more preferably 70% by mass or more with respect to all repeating units of the resin H. The upper limit value thereof is not particularly limited, but is preferably 99% by mass or less and more preferably 95% by mass or less.

In a case where the resin H contains the repeating unit B3 having a carboxylic acid group, a content of the repeating unit B3 having a carboxylic acid group is preferably 15% to 50% by mass, and more preferably 20% to 40% by mass with respect to all repeating units of the resin H.

In a case where the resin H contains the repeating unit B4, a content of the repeating unit B4 is preferably 0% to 80% by mass, and more preferably 0% to 75% by mass with respect to all repeating units of the resin H.

From the viewpoint that the effect of the present invention is more excellent, it is preferable that the acid value of the resin H is higher than the acid value of the resin C. Specifically, the acid value of the resin H is higher than the acid value of the resin C by preferably 70 mgKOH/g or more, more preferably 100 mgKOH/g or more, and still more preferably 120 mgKOH/g or more. In addition, a difference between the acid value of the resin H and the acid value of the resin C (Acid value of resin H−Acid value of resin C) is preferably 200 mgKOH/g or less.

In addition, from the viewpoint that the effect of the present invention is more excellent, the acid value of the resin H is preferably 140 mgKOH/g or more, more preferably 160 mgKOH/g or more, and still more preferably 180 mgKOH/g or more. The upper limit value thereof is preferably 250 mgKOH/g or less, more preferably 230 mgKOH/g or less, and still more preferably 200 mgKOH/g or less. In addition, a resin having a desired acid value can be obtained by changing the content of the repeating unit including an acid group, which is the constitutional component of the resin H.

A weight-average molecular weight of the resin H is preferably 5,000 to 100,000, more preferably 8,000 to 80,000, still more preferably 15,000 to 40,000, and most preferably 18,000 to 25,000.

A content of the resin H in the curable composition 2 is not particularly limited, but is preferably 2% to 40% by mass, more preferably 5% to 35% by mass, and still more preferably 10% to 30% by mass with respect to the total solid content of the curable composition.

In addition, from the viewpoint that the effect of the present invention is more excellent, in the curable composition 2, a ratio of the content of the resin C to the total content of the resin C and the resin C (Content of the resin C/Total content of the resin C and the resin H) is preferably 0.30 to 0.50, more preferably 0.33 to 0.47, and still more preferably 0.35 to 0.45.

The resin H may be used alone or in combination of two or more thereof. In a case where two or more resins H are used in combination, the total content thereof is preferably within the above-described range.

Specific aspects and suitable aspects of each component contained in the curable composition 2, other than the resin C and the resin H, and each component which may be contained are the same as the specific aspects and suitable aspects of each component contained in the curable composition 1 and each component which may be contained.

In the curable composition 2, it is preferable that a content of the particles having a large particle size is small. More specifically, in a (volume-based) particle diameter distribution obtained by measuring the curable composition 2 with a particle size distribution analyzer, a proportion of particles having a particle size of 200 nm or more (hereinafter, also simply referred to as “specific particles”) is preferably 5% or less. Among these, the proportion of the specific particles is more preferably 3% or less, and still more preferably 1% or less. The lower limit thereof is not particularly limited, but may be, for example, 0%.

The particle diameter distribution can be measured, for example, with a particle size distribution analyzer Nanotrac UPA (manufactured by MicrotracBEL Corp.) to measure a measurement solution obtained by diluting the curable composition or a solvent (propylene glycol monomethyl ether acetate or the like) to any concentration (1% by mass or the like).

Examples of the particles which can be measured with the above-described particle size distribution analyzer include the above-described coloring materials in a particulate form (coloring material particles) and fillers other than the coloring materials.

### [Method for Producing Curable Composition 2]

A method for producing the curable composition 2 is not particularly limited, and examples thereof include the same production method as the method for producing the curable composition 1.

### Procedure of Step 11

The step 11 is a step of forming a curable composition layer on a support using the above-described curable composition 2. As the support, the support used in the above-described step 1 can be used. In addition, the specific procedure can be performed in the same manner as the procedure of the step 1 described above.

### Step 12

The step 12 is a step of performing registration between the support on which the curable composition layer is formed in the step 11, and an exposure mask. The specific procedure of the step 12 can be performed in the same manner as the procedure of the step 2 described above.

### Step 13

The step 13 is a step of performing an exposure treatment on the curable composition layer through the exposure mask registered in the above-described step 12. The specific procedure of the step 13 can be performed in the same manner as the procedure of the step 3 described above.

### Step 14

The step 14 is a step of performing a development treatment on the curable composition layer after the exposure to form a cured film in a patterned shape. The specific procedure of the step 14 can be performed in the same manner as the procedure of the step 4 described above.

### Other Steps

The second embodiment of the present manufacturing method may include other steps. Examples of the other steps include a post-baking step. It is preferable to perform the post-baking step after the step 14 because a hardness of the cured film is improved.

The post-baking step is preferably performed under the same conditions as in the above-described step 5.

### [[Physical Properties of Cured Film]]

Hereinafter, physical properties of the cured film obtained by the present manufacturing method will be described in detail.

In the cured film, from the viewpoint of having excellent antireflection characteristics (low reflection properties), an average value of specular reflectivity of light having a wavelength of 400 to 700 nm per film thickness of 3.5 m in a case where light having a wavelength of 350 to 1,200 nm is incident is preferably less than 5%, more preferably less than 3%, and still more preferably less than 1%. The lower limit value thereof is not particularly limited, but is generally 0% or more.

More specifically, the average value of the above-described specular reflectivity is preferably less than 2.0% in a case of an incidence angle of 5°, preferably less than 5% in a case of an incidence angle of 45°, and preferably less than 10% in a case of an incidence angle of 60°.

As a method of measuring the average value of the reflectivity of the light shielding film, for example, a light shielding film is formed on a glass substrate, a spectrometer (for example, VAR unit or the like of a spectrometer V7200 manufactured by JASCO Corporation) is used for obtaining a specular reflectivity spectrum at any incidence angle (for example, 5°, 45°, or 60°), and an average value of the reflectivity in a wavelength range of 400 to 700 nm is obtained.

In addition, in order to exhibit the above-described low reflection properties, a surface roughness of the cured film is preferably in an appropriate range.

More specifically, it is preferable that an arithmetic average surface roughness Ra(b) of the cured film, an average length Rsm(b) of elements, and a root-mean-square tilt RΔq(b) are in appropriate numerical ranges. In the present specification, Ra(b), Rsm(b), and RΔq(b) represent values measured in accordance with JIS-B-0601:2013.

Ra(b) is preferably 0.06 to 0.50 m and more preferably 0.15 to 0.30 μm.

In addition, from the viewpoint that the effect of the present invention is more excellent, a difference (Ra(b)−Ra(a)) between the Ra(a) and Ra(b) is preferably 0.05 to 0.30 μm.

Rsm(b) is preferably 1 to 50 m and more preferably 2 to 30 μm.

RΔq(b) is preferably 3° to 25° and more preferably 5° to 10°.

In addition, from the viewpoint that the effect of the present invention is more excellent, a difference (RΔq(b)−RΔq(a)) between the RΔq(b) and RΔq(a) is preferably 3° to 15°.

A film thickness of the cured film is preferably 0.1 to 6.0 am, more preferably 1.0 to 5.0 m, and still more preferably 1.0 to 3.5 μm. The cured film may be thinner or thicker than the above range depending on the application.

The cured film obtained by the method for manufacturing a cured film according to the embodiment of the present invention is preferably used as a light shielding film.

In the light shielding film obtained by the method for manufacturing a cured film according to the embodiment of the present invention, from the viewpoint of excellent light shielding properties, an optical density (OD) per film thickness of 3.5 m in a wavelength range of 400 to 1,100 nm is preferably more than 2.0, more preferably 2.5 or more, and still more preferably 3.0 or more. In addition, the upper limit value thereof is not particularly limited, but is preferably 10 or less, in general.

In the present specification, the expression that the optical density per film thickness of 3.5 μm in a wavelength range of 400 to 1,100 nm is 3.0 or more means that an optical density per film thickness of 3.5 m in the entire wavelength range of 400 to 1,100 nm is 3.0 or more.

As a method of measuring the optical density of the light shielding film, first, the light shielding film is formed on a glass substrate, and the optical density can be measured using a spectrophotometer (for example, U-4100 or the like manufactured by Hitachi High-Tech Corporation).

### <Solid-State Imaging Element and Solid-State Imaging Device>

The cured film can be suitably used as a light shielding film in a solid-state imaging element.

An aspect in which the solid-state imaging element includes the light shielding film is not particularly limited, and examples thereof include an aspect in which a plurality of photodiodes and light-receiving elements consisting of polysilicon or the like constituting a light-receiving area of a solid-state imaging element (a CCD image sensor, a CMOS image sensor, or the like) are provided on a substrate, and the solid-state imaging element includes the light shielding film on a surface side (for example, a portion other than light receiving sections and/or pixels for adjusting color, and the like) of a support on which the light-receiving elements are formed or on a side opposite to the surface on which the light-receiving elements are formed.

In addition, in a case where the light shielding film is used as a light attenuation film, for example, in a case where the light attenuation film is disposed so that a part of light passes through the light attenuation film and then is incident on the light-receiving elements, a dynamic range of the solid-state imaging element can be improved.

The solid-state imaging device includes the above-described solid-state imaging element.

### <Image Display Apparatus>

The light shielding film is also preferably applied to an image display apparatus.

In other words, the image display apparatus according to the present invention is an image display apparatus including the light shielding film according to the embodiment of the present invention.

Examples of the form in which the image display apparatus includes the light shielding film include a form in which a color filter which includes a black matrix including a light shielding film is applied to the image display apparatus.

Next, a black matrix and a color filter including the black matrix will be described, and a liquid crystal display device including such a color filter will be described as a specific example of the image display apparatus.

### (Black Matrix)

It is also preferable that the light shielding film is included in the black matrix. The black matrix is incorporated into a color filter, a solid-state imaging element, and an image display apparatus such as a liquid crystal display device in some cases.

Examples of the black matrix include those described above; a black rim provided in the peripheral portion of an image display apparatus such as a liquid crystal display device; a lattice-like and/or stripe-like black portion between pixels of red, blue, and green; and a dot-like and/or linear black pattern for shielding a thin film transistor (TFT) from light. The definition of the black matrix is described in, for example, “Glossary of liquid crystal display manufacturing device”, written by Yasuhira KANNO, 2nd edition, NIKKAN KOGYO SHIMBUN, LTD., 1996, p. 64.

In order to improve the display contrast and to prevent image quality deterioration resulting from current leakage of light in a case of an active matrix driving-type liquid crystal display device using a thin film transistor (TFT), the black matrix preferably has high light shielding properties (the optical density OD is 3 or more).

The method for manufacturing the black matrix is not particularly limited, but the black matrix can be manufactured in the same manner as the method for manufacturing a light shielding film described above. Specifically, by applying the curable composition onto a substrate to form a composition layer and performing exposure and development on the composition layer, a patterned light shielding film (black matrix) can be manufactured. A film thickness of the light shielding film (black matrix) is preferably 0.1 to 4.0 μm.

The above-described substrate is not particularly limited, but preferably has a transmittance of 80% or more for visible light (wavelength of 400 to 800 nm). Examples of a material of such a substrate include glass such as soda lime glass, alkali-free glass, quartz glass, and borosilicate glass, and plastic such as a polyester-based resin and a polyolefin-based resin; and from the viewpoint of chemical resistance and heat resistance, alkali-free glass, quartz glass, or the like is preferable.

### (Color Filter)

It is also preferable that the light shielding film is included in the color filter.

The aspect in which the color filter includes the light shielding film is not particularly limited, but examples thereof include a color filter including a substrate and the above-described black matrix. That is, examples thereof include a color filter comprising colored pixels of red, green, and blue which are formed in the opening portion of the black matrix formed on a substrate.

The color filter including the black matrix can be manufactured, for example, by the following method.

First, in an opening portion of a patterned black matrix formed on a substrate, a coating film (composition layer) of a curable composition containing each of pigments corresponding to the respective colored pixels of the color filter is formed. The composition for each color is not particularly limited, known compositions can be used, but in the composition described in the present specification, it is preferable that a composition in which the black pigment is replaced with a colorant corresponding to each pixel is used.

Subsequently, the composition layer is subjected to exposure through a photo mask having a pattern corresponding to the opening portion of the black matrix. Next, colored pixels can be formed in the opening portion of the black matrix by removing a non-exposed portion by a development treatment, and then performing baking. In a case where the series of operations are performed using, for example, a composition for each color including red, green, and blue pigments, a color filter having red, green, and blue pixels can be manufactured.

### (Liquid Crystal Display Device)

It is also preferable that the light shielding film is included in the liquid crystal display device. The aspect in which the liquid crystal display device includes the light shielding film is not particularly limited, and examples thereof include an aspect in which the liquid crystal display device includes a color filter including the black matrix (light shielding film) described above.

Examples of the liquid crystal display device include an aspect in which the liquid crystal display device comprises a pair of substrates disposed to face each other and a liquid crystal compound sealed into the space between the substrates. The substrates are as described above as the substrate for a black matrix.

Examples of a specific aspect of the liquid crystal display device include a laminate having polarizing plate/substrate/color filter/transparent electrode layer/alignment film/liquid crystal layer/alignment film/transparent electrode layer/thin film transistor (TFT) element/substrate/polarizing plate/backlight unit in this order from the user side.

In addition, the liquid crystal display device is not limited to the above-described liquid crystal display devices, and examples thereof include the liquid crystal display devices described in “Electronic display device (written by Akio SASAKI, Kogyo Chosakai Publishing Co., Ltd., published in 1990)”, “Display Device (written by Sumiaki IBUKI, Sangyo Tosho Publishing Co., Ltd., published in 1989)”, or the like. In addition, examples thereof include the liquid crystal display device described in “Next-Generation Liquid Crystal Display Technology (edited by Tatsuo UCHIDA, Kogyo Chosakai Publishing Co., Ltd., published in 1994)”.

### <Infrared Sensor>

It is preferable that the light shielding film is included in the infrared sensor.

Next, a solid-state imaging device to which the above-described infrared sensor is applied will be described.

The above-described solid-state imaging device includes a lens optical system, a solid-state imaging element, an infrared emission diode, and the like. Furthermore, regarding each of the configurations of the solid-state imaging device, reference can be made to paragraphs 0032 to 0036 of JP2011-233983A, the contents of which are incorporated into the specification of the present specification.

### <Cover Glass and Optical Filter>

It is also preferable that the light shielding film is used for an optical filter and cover glass incorporated in the solid-state imaging device. Examples of the optical filter include an IR cut filter. By forming the present light shielding film in the peripheral portion of the optical filter or the cover glass, it is possible to suppress occurrence of flare or ghost.

For each configuration of the above-described optical filter with a light shielding film and the solid-state imaging device, reference can be made to paragraphs 0009 to 0012 of JP2014-132333A; and for each configuration of the above-described cover glass with a light shielding film and the solid-state imaging device, reference can be made to paragraphs 0017 to 0020, 0037, and 0040 of JP2021-092605A, the contents of which are incorporated herein by reference.

### EXAMPLES

Hereinbelow, the present invention will be described in more detail with reference to Examples.

The materials, the amounts of materials used, the proportions, the treatment details, the treatment procedure, and the like shown in Examples below may be modified as appropriate as long as the modifications do not depart from the spirit of the present invention. Therefore, the scope of the present invention should not be construed as being limited to Examples shown below.

### [[Preparation and Evaluation of Curable Composition]]

### [Various Components Used for Preparing Curable Composition]

Hereinafter, components used for preparing the curable composition used in each evaluation will be described in detail.

### [Resin A]

Table 1 shows formulations and respective characteristics of resins A (resins A-1 to A-10).

As the resins A-1 to A-10, synthesized resins were used. Hereinafter, a synthesis example of the resin A-1 will be shown as an example. The resins A-2 to A-10 were synthesized in the same manner as in the synthesis example of the resin A-1, except that the type and blending ratio of the raw material monomers were changed.

### <Synthesis of Resin A-1>

20.0 g of methacrylic acid (manufactured by FUJIFILM Wako Pure Chemical Corporation), 130.0 g of PME-1000 (manufactured by NOF Corporation), and 50.0 g of benzyl methacrylate (manufactured by FUJIFILM Wako Pure Chemical Corporation) were added to 233% by mass of propylene glycol monomethyl ether acetate with respect to the total mass of the raw material monomers, and the mixture was heated to 80° C. under a nitrogen stream. Next, 2 mol % of dodecanethiol and 0.5% by mass of a thermal polymerization initiator (V-601 manufactured by FUJIFILM Wako Pure Chemical Corporation) with respect to the total mass of the above-described raw material monomers were added thereto, and the mixture was stirred for 2 hours. Next, 0.5% by mass of a thermal polymerization initiator (V-601, manufactured by FUJIFILM Wako Pure Chemical Corporation) with respect to the total mass of the above-described raw material monomers was added thereto, and the mixture was further stirred for 2 hours. Thereafter, 0.5% by mass of a thermal polymerization initiator (V-601, manufactured by FUJIFILM Wako Pure Chemical Corporation) with respect to the total mass of the above-described raw material monomers was added thereto, and the mixture was heated to 90° C. and stirred for 2 hours to synthesize a resin A-1.

Weight-average molecular weights of the resins A-1 to A-10 were in a range of 13,000 to 45,000.

Table 1 is shown below. Table 1 is composed of Table 1-1 and Table 1-2, and for example, the resin A-1 contains the repeating unit A1 and the repeating unit A2 described in Table 1-1, and the repeating unit A3 described in Table 1-2.

In Table 1, the column of “Content (% by mass)” indicates the content (% by mass) of each repeating unit with respect to all the repeating units.

In Table 1, the numerical values of the dispersion element (δ_{d}), the polarity element (δₚ), and the hydrogen bond element (δₕ) of each resin, which are described in the column of “HSP”, are values at 25° C. calculated using HSPiP ver. 5.4.08 (product sold by Video Workshop Question Co., Ltd.), as described above.

In Table 1, the glass transition temperature described in the column of “Tg (° C.)” was measured by a differential scanning calorimetry (DSC) device (DSC 3500 Sirius, manufactured by NETZSCH).

In Table 1, each numerical value described in the column of “Dissolution rate T1 (μm/sec)” was measured by the following procedure.

### (Measurement of Dissolution Rate)

The dissolution rate of each resin was measured as follows. First, the obtained resin was diluted with PGMEA so that the solid content is 30% by mass, applied onto a silicon wafer using a spin coater, and then heated at 90° C. for 2 minutes to dry the organic solvent, thereby obtaining a resin film having a film thickness of 10 μm. Next, the resin film was immersed in an alkaline developer CD-2000 (manufactured by FUJIFILM Electronic Materials Co., Ltd.) at 25° C. for 60 seconds, and then a film thickness after the immersion was measured with a film thickness meter. From the obtained measurement results, the dissolution rate of the resin was calculated based on the following expression (T). The alkali developer CD-2000 (manufactured by FUJIFILM Electronic Materials Co., Ltd.) is a developer used in the development treatment, as will be described later.

$$Dissolution rate ( μ m / sec ) = Amount of change in film thickness ( μ m ) / Development time ( sec ) \qquad Expression ( T )$$

TABLE 1

| | Formulation of resin A | |
|---|---|---|
| | Repeating unit having acid group (repeating unit A1) | |
| Table | | Content |
| 1-1 | Structure | (% by mass) |
| A-1 | 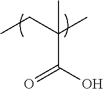 | 10 |
| A-2 | 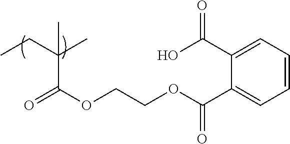 | 30 |
| A-3 | 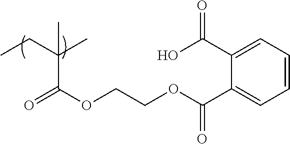 | 30 |
| A-4 | 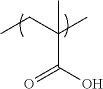 | 10 |
| A-5 | 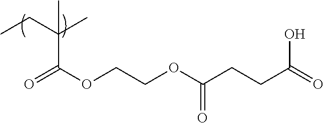 | 25 |
| A-6 | 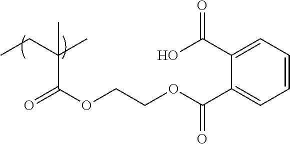 | 30 |
| A-7 | 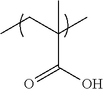 | 10 |
| A-8 | 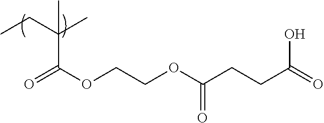 | 28 |
| A-9 | 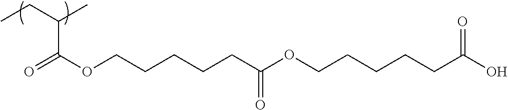 | 33 |
| A-10 | 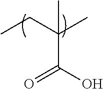 | 30 |
| | Formulation of resin A | |
| | Repeating unit having one or more groups of polyoxyalkylene group and polyoxyalkylene carbonyl group having | |
| | specific average addition number (repeating unit A2) | |
| TABLE | | Content |
| 1-1 | Structure | (% by mass) |
| A-1 | 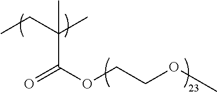 | 65 |
| A-2 | 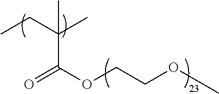 | 50 |
| A-3 | 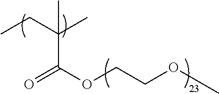 | 50 |
| A-4 | 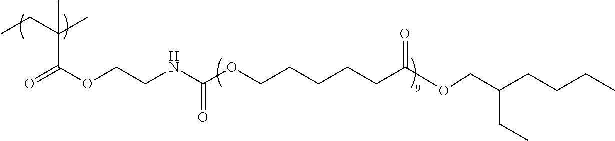 | 65 |
| A-5 | 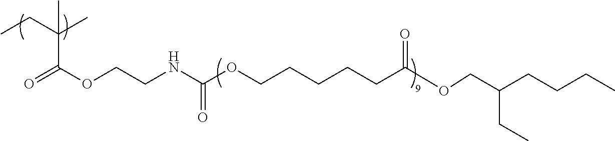 | 65 |
| A-6 | 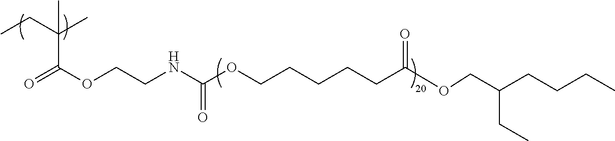 | 50 |
| A-7 | 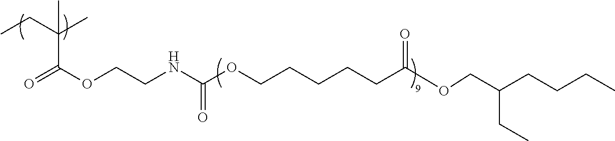 | 65 |
| A-8 | 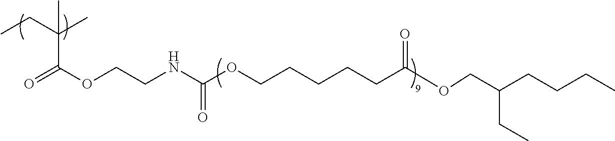 | 42 |
| A-9 | 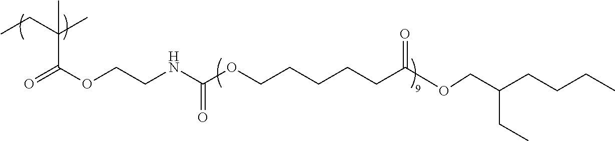 | 37 |
| A-10 | 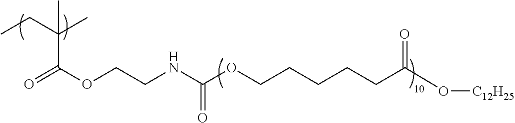 | 70 |

TABLE 2

| | Formulation and physical properties of resin A | | | | | | | |
|---|---|---|---|---|---|---|---|---|
| | Other repeating units (repeating unit A3) | | Acid | | | | | |
| | | Content | value | | | | | Dissolution |
| TABLE | | (% by | (mgKOH/ | HSP | | | Tg | rate T1 |
| 1-2 | Structure | mass) | g) | δ d | δ p | δ h | (° C.) | (μm/sec) |
| A-1 | 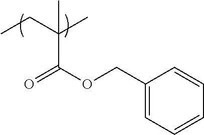 | 25 | 65.8 | 15.7 | 4.7 | 9.1 | 50 | 0.19 |
| A-2 | 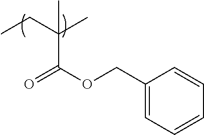 | 20 | 61.0 | 15.8 | 4.8 | 8.1 | 45 | 0.14 |
| A-3 | 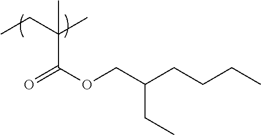 | 20 | 61.0 | 15.5 | 4.6 | 7.8 | 15 | 0.15 |
| A-4 | 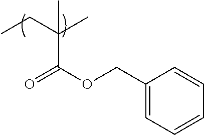 | 25 | 65.8 | 16.6 | 4.3 | 3.9 | 30 | 0.03 |
| A-5 | 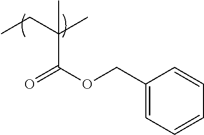 | 10 | 61.5 | 16.7 | 5.0 | 4.8 | 35 | 0.04 |
| A-6 | 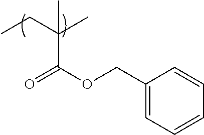 | 20 | 61.0 | 16.5 | 4.4 | 4.1 | 38 | 0.05 |
| A-7 | 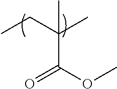 | 25 | 65.8 | 16.2 | 4.7 | 3.8 | 40 | 0.04 |
| A-8 | 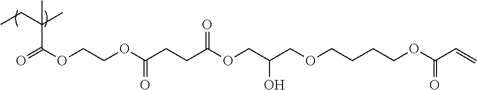 | 30 | 68.9 | 16.3 | 5.0 | 5.1 | −10 | 0.06 |
| A-9 | 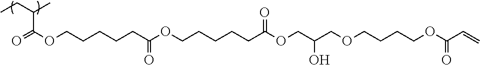 | 30 | 62.2 | 16.2 | 5.0 | 4.8 | −21 | 0.06 |

| | | | | | | |
|---|---|---|---|---|---|---|
| A-10 | 170 | 16.5 | 4.7 | 5.2 | 30 | 0.35 |

Table 2 shows structures of resins B (resins B-1 to B-12).

As the resins B-1 to B-12, synthesized resins were used. Hereinafter, a synthesis example of the resin B-1 will be shown as an example. The resins B-2 to B-12 were synthesized in the same manner as in the synthesis example of the resin B-1, except that the type and blending ratio of the raw material monomers were changed.

### <Synthesis of Resin B-1>

172.0 g of methyl methacrylate (manufactured by FUJIFILM Wako Pure Chemical Corporation), 20.0 g of methacrylic acid (manufactured by FUJIFILM Wako Pure Chemical Corporation), and 8.0 g of 2-hydroxyethyl methacrylate (manufactured by FUJIFILM Wako Pure Chemical Corporation) were mixed to prepare a raw material monomer solution. In addition, 2 mol % of a thermal polymerization initiator (V-601 manufactured by FUJIFILM Wako Pure Chemical Corporation) with respect to the total mass of the above-described raw material monomers and 111% by mass of 1-methoxy-2-propanol with respect to the total mass of the above-described raw material monomers were mixed to prepare a mixed solution A. Next, the above-described raw material monomer mixed solution and 74% by mass of 1-methoxy-2-propanol with respect to the total mass of the above-described raw material monomers were mixed with each other to prepare a mixed solution B, the mixed solution B was heated to 80° C., and then the mixed solution A was added dropwise to the mixed solution B over 2 hours (dropwise polymerization), and the mixture was heated at 80° C. for 2 hours after the dropwise addition and further heated at 90° C. for 3 hours, thereby synthesizing a resin B-1.

Weight-average molecular weights of the resins B-1 to B-12 were in a range of 12,000 to 30,000.

Table 2 is shown below. Table 2 is composed of Table 2-1 and Table 2-2.

In Table 2, the column of “Content (% by mass)” indicates the content (% by mass) of each repeating unit with respect to all the repeating units.

In Table 2, each numerical value described in the column of “HSP” and the column of “Tg (° C.)” was calculated or measured by the same procedure as each numerical value described for Table 1.

TABLE 3

| | Formulation of resin B | | | | | |
|---|---|---|---|---|---|---|
| | Repeating unit derived from | | Repeating unit having | | | |
| | alkyl (methyl)acrylate | | hydroxyl group | | | |
| | (repeating unit B1) | | (repeating unit B2) | | Repeating unit having | |
| | | Content | | Content | carboxylic acid group repeating unit B3) | |
| | | (% by | | (% by | | Content |
| TABLE 2-1 | Structure | mass) | Structure | mass | Structure | (% by mass) |
| B-1 | 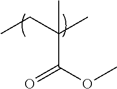 | 86 | 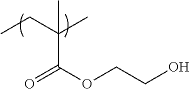 | 4 | 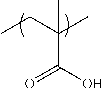 | 10 |
| B-2 | 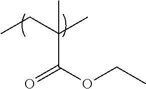 | 86 | 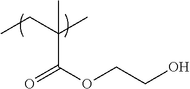 | 4 | 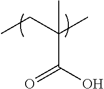 | 10 |
| B-3 | 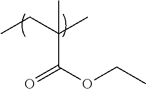 | 72 | 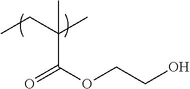 | 3 | 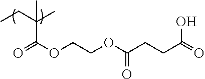 | 25 |
| B-4 | 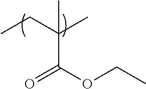 | 81 | 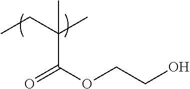 | 4 | 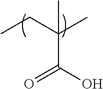 | 15 |
| B-5 | 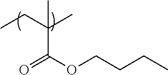 | 85 | 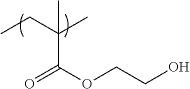 | 5 | 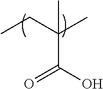 | 10 |
| B-6 | 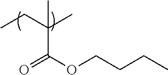 | 88.7 | 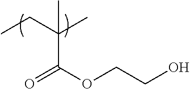 | 3 | 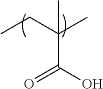 | 8.3 |
| B-7 | 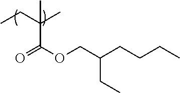 | 86 | 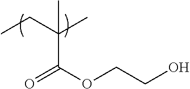 | 4 | 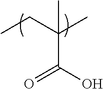 | 10 |
| B-8 | 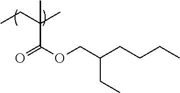 | 60 | 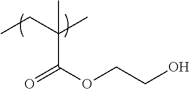 | 30 | 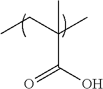 | 10 |
| B-9 | 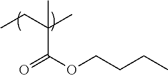 | 83 | 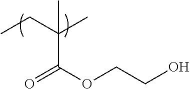 | 3 | 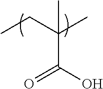 | 14 |
| B-10 | 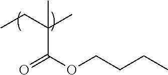 | 81 | 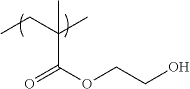 | 3 | 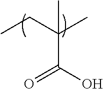 | 16 |
| B-11 | 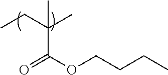 | 86 | | | 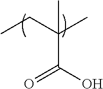 | 14 |
| B-12 | 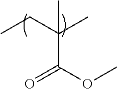 | 11 | 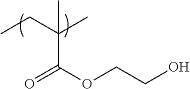 | 5 | 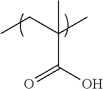 | 17 |

TABLE 4

| | Formulation and physical properties of resin B | | | | | | |
|---|---|---|---|---|---|---|---|
| | Other repeating units (repeating unit B4) | | | | | | |
| | | Content | Acid value | HSP | | | Tg |
| Table 2-2 | Structure | (% by mass) | (mgKOH/g) | δ d | δ p | δ h | (° C.) |
| B-1 | | | 65.8 | 15.6 | 5.2 | 6.8 | 112 |
| B-2 | | | 65.8 | 15.5 | 4.7 | 6.1 | 77 |
| B-3 | | | 61.5 | 15.8 | 5.2 | 6.8 | 50 |
| B-4 | | | 98.6 | 15.5 | 4.7 | 6.4 | 82 |
| B-5 | | | 65.8 | 15.7 | 3.9 | 5.6 | 65 |
| B-6 | | | 54.6 | 15.7 | 3.8 | 5.4 | 63 |
| B-7 | | | 65.8 | 15.8 | 3.0 | 4.5 | 6 |
| B-8 | | | 65.8 | 15.9 | 4.2 | 6.5 | 26 |
| B-9 | | | 92.1 | 15.7 | 3.9 | 5.7 | 70 |
| B-10 | | | 105.2 | 15.7 | 3.9 | 5.9 | 72 |
| B-11 | | | 92.1 | 15.6 | 3.8 | 5.5 | 69 |
| B-12 | 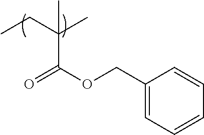 | 67 | 133.6 | 16.7 | 4.2 | 6.6 | 80 |

### [Resin H]

Structures of resins H (resins H-1 to H-4) are shown in Table 3. Table 3 is composed of Table 3-1 and Table 3-2, and for example, the resin H-1 contains the repeating unit B3 described in Table 3-1 and the repeating unit B4 described in Table 3-2.

The resins H-1 to H-4 were synthesized in the same manner as in the synthesis example of the resin B-1, except that the type and blending ratio of the raw material monomers were changed.

In Table 3, the column of “Content (% by mass)” indicates the content (% by mass) of each repeating unit with respect to all the repeating units.

In Table 3, each numerical value described in the column of “HSP”, the column of “Tg (° C.)”, and the column of “Dissolution rate T2 (μm/sec)” was calculated or measured by the same procedure as each numerical value described for Table 1.

TABLE 5

| | Formulation of resin H | | | | | |
|---|---|---|---|---|---|---|
| | Repeating unit derived from alkyl (meth)acrylate | | Repeating unit having hydroxyl group | | Repeating unit having carboxlic acid | |
| | (repeating unit B1) | | (repeating unit B2) | | group (repeating unit B3) | |
| | | Content | | Content | | Content |
| TABLE 3-1 | Structure | (% by mass) | Structure | (% by mass) | Structure | (% by mass) |
| H-1 | | | | | 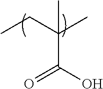 | 25 |
| H-2 | 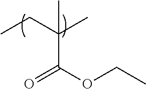 | 75 | | | 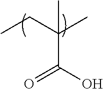 | 25 |
| H-3 | 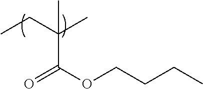 | 75 | | | 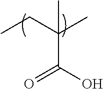 | 25 |
| H-4 | 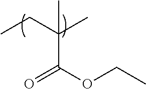 | 78 | | | 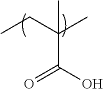 | 22 |
| B-12 | 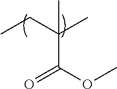 | 11 | 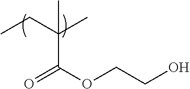 | 5 | 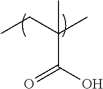 | 17 |

TABLE 6

| | Formulation and physical properties of resin H | | | | | | | |
|---|---|---|---|---|---|---|---|---|
| | Other repeating units (repeating unit B4) | | | | | | | |
| | | Content | Acid value | HSP | | | Tg | Dissolution rate T2 |
| Table 3-2 | Structure | (% by mass) | (mgKOH/g) | δ d | δ p | δ h | (° C.) | (μm/sec) |
| H-1 | 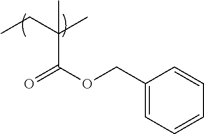 | 75 | 196.4 | 16.8 | 4.1 | 6.7 | 66 | 0.85 |
| H-2 | | | 164.4 | 15.5 | 4.7 | 6.7 | 95 | 0.75 |
| H-3 | | | 164.4 | 15.6 | 3.9 | 6.2 | 83 | 0.60 |
| H-4 | | | 144.7 | 15.5 | 4.6 | 6.6 | 91 | 0.50 |
| B-12 | 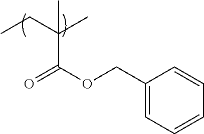 | 67 | 133.6 | 16.7 | 4.2 | 6.6 | 80 | 0.25 |

### [Polymerizable Compound]

Polymerizable compounds (C-1 to C-6) are shown in Table 4.

In Table 4, each numerical value described in the column of “Shrinkage ratio (%)” was measured by the following procedure.

The polymerizable compound C-1 in Table 4 was a mixture of two kinds of monomers, and a mass ratio of the compound on the left side and the compound on the right side (Mass of compound on left side:Mass of compound on right side) was 50:50.

### (Measurement of Shrinkage Ratio)

The shrinkage ratio of the polymerizable compound was obtained by obtaining a specific gravity ρM (g/cm³) of the polymerizable compound and a specific gravity ρP (g/cm³) of a cured substance of the polymerizable compound, and calculating from the following expression.

$$Shrinkage ratio ( \% ) = ( 1 - ρ M / ρ P ) \times 100$$

The cured substance of the polymerizable compound was produced by the method described below, and the specific gravity of the polymerizable compound and the cured substance was measured according to JIS-K-2249.

### (Method for Producing Cured Substance)

A composition consisting of 0.5% by mass of a radical polymerization initiator (V-601; manufactured by FUJIFILM Wako Pure Chemical Corporation) and 99.5% by mass of the polymerizable compound was injected into a mold constituted of a glass plate and a gasket consisting of an ethylene-vinyl acetate copolymer, and casting polymerization was carried out to produce a cured substance. The polymerization was carried out using an air furnace, and the temperature was gradually raised from 30° C. to 90° C. over 18 hours, and then maintained at 90° C. for 2 hours. After the completion of the polymerization, the polymer was removed from the glass mold of the mold to obtain a cured substance.

TABLE 7

| | Formulation and physical properties of polymerizable compound | | | | | |
|---|---|---|---|---|---|---|
| | | | | | | Shrinkage |
| Table | | Product | | | | rate |
| 4 | Structure | name | δ d | δ p | δ h | (%) |
| C-1 | 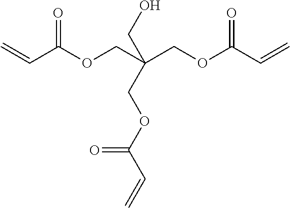 [SMILES: C=CC(=O)OCC(CO)(COC(=O)C=C)COC(=O)C=C] | — | 16.7 | 3.15 | 7.4 | 16.3 |
| | 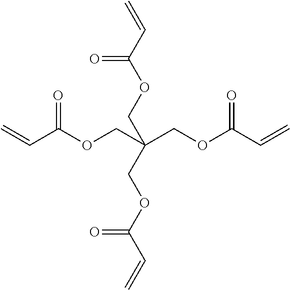 [SMILES: C=CC(=O)OCC(COC(=O)C=C)(COC(=O)C=C)COC(=O)C=C] | | | | | |
| C-2 | 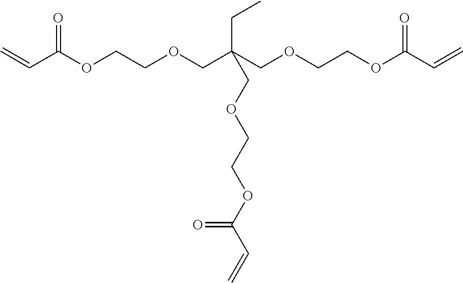 [SMILES: C=CC(=O)OCCOCC(CC)(COCCOC(=O)C=C)COCCOC(=O)C=C] | EBECRYL 160S (manufactured by Daicel Ornex Co.) | 16.2 | 2.6 | 6.7 | 20.1 |
| C-3 | 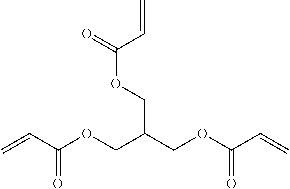 [SMILES: C=CC(=O)OCC(COC(=O)C=C)COC(=O)C=C] | M-930 (manufactured by Toagosei Co., Ltd.) | 16.5 | 3.7 | 6.5 | 14.8 |
| C-4 | 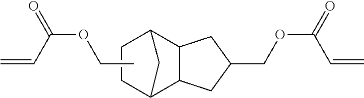 | EBECRYL 130 (manufactured by Daicel Ornex Co.) | 17.2 | 3 | 3.7 | 5.9 |
| C-5 | 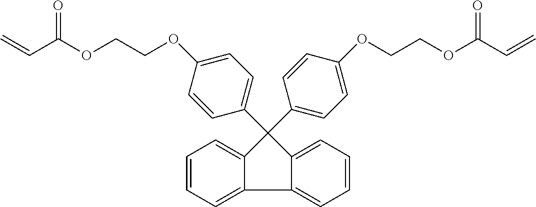 [SMILES: C=CC(=O)OCCOc1ccc(C2(c3ccc(OCCOC(=O)C=C)cc3)c3ccccc3-c3ccccc32)cc1] | OGSOL EA-0200 (manufactured by Osaka Gas Chemicals Co., Ltd.) | 19.9 | 3.1 | 3.5 | 0.5 |
| C-6 | 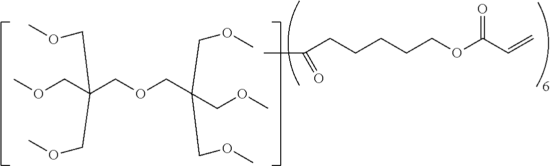 | KAYARAD DPCA-60 (manufactured by Nippon Kayaku Co., Ltd.) | 16.3 | 0.1 | 13.3 | 8 |

### Coloring Materials (D-1 to D-6) are Shown Below.

D-1: TiON (titanium oxynitride)
D-2: Spectrasense Black K0087 (perylene-based black pigment)
D-3: IRGAFOR BLACK SO 100 (benzodifuranone-based black pigment)
D-4: carbon black (CB)
D-5: Pigment Red 177
D-6: Pigment Blue 60

### [Photopolymerization Initiator]

Photopolymerization initiators (E-1 to E-3) are shown below.
E-1: IRGACURE OXE02 (manufactured by BASF SE, oxime ester-based polymerization initiator)
E-2: ADEKA ARKLS NCI-831E (manufactured by ADEKA Corporation, oxime ester-based polymerization initiator)
E-3: compound having the following structure (oxime ester-based polymerization initiator)

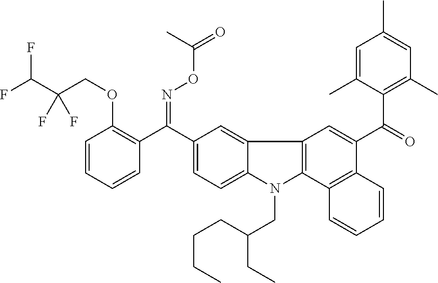 [SMILES: CCCCC(CC)Cn1c2ccc(/C(=N\OC(C)=O)c3ccccc3OCC(F)(F)C(F)F)cc2c2cc(C(=O)c3c(C)cc(C)cc3C)c3ccccc3c21]

### [Thermal Crosslinking Compound]

Thermal crosslinking compounds (F-1 to F-3) are shown below.
F-1: CELLOXIDE 2021P (manufactured by Daicel Corporation, 3,4-epoxycyclohexylmethyl 3,4-epoxycyclohexane carboxylate)
F-2: EOCN-1020 (manufactured by Nippon Kayaku Co., Ltd., cresol-novolac type epoxy resin)
F-3: EHPE-3150 (manufactured by Daicel Corporation, polyfunctional alicyclic epoxy resin)

### [Surfactant]

A surfactant (W-1) is shown below.
W-1: KF6001 (manufactured by Shin-Etsu Chemical Co., Ltd.)

### [Solvent]

Solvents are shown below.
PGMEA: propylene glycol monomethyl ether acetate
PGME: 1-methoxy-2-propanol
Butyl acetate
CyP: cyclopentanone

### [Preparation of Pigment Dispersion Liquid]

Components shown in Table 5 were mixed in the blending amounts (part by mass) shown in Table 5, 230 parts by mass of zirconia beads having a diameter of 0.3 mm were added thereto, the mixture was subjected to a dispersion treatment for 5 hours using a paint shaker, and the beads were separated by filtration to produce each pigment dispersion liquid (pigment dispersion liquids 1 to 20).

The part by mass of the resin A is described as part by mass of a resin solid content excluding the solvent described in <Synthesis of resin A-1>.

Table 5 is shown below.

TABLE 8

| | Coloring material | | Resin A | | Solvent | |
|---|---|---|---|---|---|---|
| | | Part by | | Part by | | Part by |
| Table 5 | Type | mass | Type | mass | Type | mass |
| Pigment dispersion liquid 1 | D-2 | 25.0 | A-1 | 7.5 | PGMEA/butyl acetate | 40.5/27.0 |
| Pigment dispersion liquid 2 | D-2 | 25.0 | A-2 | 7.5 | PGMEA/butyl acetate | 40.5/27.0 |
| Pigment dispersion liquid 3 | D-2 | 25.0 | A-3 | 7.5 | PGMEA/butyl acetate | 40.5/27.0 |
| Pigment dispersion liquid 4 | D-2 | 25.0 | A-4 | 7.5 | PGMEA/butyl acetate | 40.5/27.0 |
| Pigment dispersion liquid 5 | D-2 | 25.0 | A-5 | 7.5 | PGMEA/butyl acetate | 40.5/27.0 |
| Pigment dispersion liquid 6 | D-2 | 25.0 | A-6 | 7.5 | PGMEA/butyl acetate | 40.5/27.0 |
| Pigment dispersion liquid 7 | D-2 | 25.0 | A-7 | 7.5 | PGMEA/butyl acetate | 40.5/27.0 |
| Pigment dispersion liquid 8 | D-2 | 25.0 | A-8 | 7.5 | PGMEA/butyl acetate | 40.5/27.0 |
| Pigment dispersion liquid 9 | D-2 | 25.0 | A-9 | 7.5 | PGMEA/butyl acetate | 40.5/27.0 |
| Pigment dispersion liquid 10 | D-2 | 25.0 | A-10 | 7.5 | PGMEA/butyl acetate | 40.5/27.0 |
| Pigment dispersion liquid 11 | D-1 | 25.0 | A-1 | 7.5 | PGMEA/butyl acetate | 40.5/27.0 |
| Pigment dispersion liquid 12 | D-1 | 25.0 | A-6 | 7.5 | PGMEA/butyl acetate | 40.5/27.0 |
| Pigment dispersion liquid 13 | D-3 | 25.0 | A-1 | 7.5 | PGMEA/butyl acetate | 40.5/27.0 |
| Pigment dispersion liquid 14 | D-3 | 25.0 | A-6 | 7.5 | PGMEA/butyl acetate | 40.5/27.0 |
| Pigment dispersion liquid 15 | D-4 | 25.0 | A-1 | 7.5 | PGMEA/butyl acetate | 40.5/27.0 |
| Pigment dispersion liquid 16 | D-4 | 25.0 | A-6 | 7.5 | PGMEA/butyl acetate | 40.5/27.0 |
| Pigment dispersion liquid 17 | D-5/D-6 | 12.5/12.5 | A-1 | 7.5 | PGMEA/butyl acetate | 40.5/27.0 |
| Pigment dispersion liquid 18 | D-5/D-6 | 12.5/12.5 | A-6 | 7.5 | PGMEA/butyl acetate | 40.5/27.0 |
| Pigment dispersion liquid 19 | D-1/D-5 | 20/5 | A-1 | 7.5 | PGMEA/butyl acetate | 40.5/27.0 |
| Pigment dispersion liquid 20 | D-3/D-5/D-6 | 15/5/5 | A-6 | 7.5 | PGMEA/butyl acetate | 40.5/27.0 |

### [Preparation of Curable Composition]

As shown in Table 6 or Table 7, each component was mixed in the blending amount (part by mass) shown in the table to prepare each curable composition of Examples and Comparative Examples.

In Table 6, each curable composition of Examples is a composition in the first embodiment; and in Table 7, each curable composition of Examples is a composition in the second embodiment.

In Tables 6 and 7, the part by mass of the pigment dispersion liquid is described as the total amount of the solution including the solvent, and the part by mass of the resin B or the resin H is described as part by mass of a resin solid content excluding the solvent described in

### <Synthesis of Resin B-1>.

In Tables 6 and 7, each numerical value described in each column of “Tg (° C.)”, “Shrinkage ratio (%)”, “Dissolution rate T1 (μm/sec)”, and “Dissolution rate T2 (μm/sec)” has the same meaning as each numerical value described in Tables 1 to 4.

In Tables 6 and 7, the HSP distance between the respective components, described in the column of “HSP distance”, was calculated based on each numerical value of the dispersion element (δ_{d}), the polarity element (δₚ), and the hydrogen bond element (δₕ) of the resin A, the resin B, the resin H, and the polymerizable compound described in Tables 1 to 4. The unit of the numerical value in the column of “HSP distance” is MPa^{1/2}.

Tables 6 and 7 are shown below.

TABLE 9

| | Formulation of curable composition | | | | | | | | | |
|---|---|---|---|---|---|---|---|---|---|---|
| | Pigment dispersion liquid | | Resin B | | Polymerizable | | Photopolymerization | | Thermal crosslinking | |
| | | Part by | | Part by | compound | | initiator | | compound | |
| Table 6-1 | Type | mass | Type | mass | Type | Part by mass | Type | Part by mass | Type | Part by mass |
| Example 1 | Pigment dispersion liquid 1 | 57.84 | B-5 | 7.03 | C-2 | 7.15 | E-2 | 2.06 | F-3 | 0.78 |
| Example 2 | Pigment dispersion liquid 2 | 57.84 | B-5 | 7.03 | C-2 | 7.15 | E-2 | 2.06 | F-3 | 0.78 |
| Example 3 | Pigment dispersion liquid 3 | 57.84 | B-5 | 7.03 | C-2 | 7.15 | E-2 | 2.06 | F-3 | 0.78 |
| Example 4 | Pigment dispersion liquid 4 | 57.84 | B-5 | 7.03 | C-2 | 7.15 | E-2 | 2.06 | F-3 | 0.78 |
| Example 5 | Pigment dispersion liquid 5 | 57.84 | B-5 | 7.03 | C-2 | 7.15 | E-2 | 2.06 | F-3 | 0.78 |
| Example 6 | Pigment dispersion liquid 6 | 57.84 | B-5 | 7.03 | C-2 | 7.15 | E-2 | 2.06 | F-3 | 0.78 |
| Example 7 | Pigment dispersion liquid 7 | 57.84 | B-5 | 7.03 | C-2 | 7.15 | E-2 | 2.06 | F-3 | 0.78 |
| Example 8 | Pigment dispersion liquid 8 | 57.84 | B-5 | 7.03 | C-2 | 7.15 | E-2 | 2.06 | F-3 | 0.78 |
| Example 9 | Pigment dispersion liquid 9 | 57.84 | B-5 | 7.03 | C-2 | 7.15 | E-2 | 2.06 | F-3 | 0.78 |
| Example 10 | Pigment dispersion liquid 10 | 57.84 | B-5 | 7.03 | C-2 | 7.15 | E-2 | 2.06 | F-3 | 0.78 |
| Example 11 | Pigment dispersion liquid 11 | 57.84 | B-5 | 7.03 | C-2 | 7.15 | E-2 | 2.06 | F-3 | 0.78 |
| Example 12 | Pigment dispersion liquid 12 | 57.84 | B-5 | 7.03 | C-2 | 7.15 | E-2 | 2.06 | F-3 | 0.78 |
| Example 13 | Pigment dispersion liquid 13 | 57.84 | B-5 | 7.03 | C-2 | 7.15 | E-2 | 2.06 | F-3 | 0.78 |
| Example 14 | Pigment dispersion liquid 14 | 57.84 | B-5 | 7.03 | C-2 | 7.15 | E-2 | 2.06 | F-3 | 0.78 |
| Example 15 | Pigment dispersion liquid 15 | 57.84 | B-5 | 7.03 | C-2 | 7.15 | F-2 | 2.06 | F-3 | 0.78 |
| Example 16 | Pigment dispersion liquid 16 | 57.84 | B-5 | 7.03 | C-2 | 7.15 | E-2 | 2.06 | F-3 | 0.78 |
| Example 17 | Pigment dispersion liquid 17 | 57.84 | B-5 | 7.03 | C-2 | 7.15 | E-2 | 2.06 | F-3 | 0.78 |
| Example 18 | Pigment dispersion liquid 18 | 57.84 | B-5 | 7.03 | C-2 | 7.15 | E-2 | 2.06 | F-3 | 0.78 |
| Example 19 | Pigment dispersion liquid 19 | 57.84 | B-5 | 7.03 | C-2 | 7.15 | F-2 | 2.06 | F-3 | 0.78 |
| Example 20 | Pigment dispersion liquid 20 | 57.84 | B-5 | 7.03 | C-2 | 7.15 | E-2 | 2.06 | F-3 | 0.78 |
| Example 21 | Pigment dispersion liquid 1 | 57.84 | B-1 | 7.03 | C-2 | 7.15 | E-2 | 2.06 | F-3 | 0.78 |
| Example 22 | Pigment dispersion liquid 1 | 57.84 | B-2 | 7.03 | C-2 | 7.15 | F-2 | 2.06 | F-3 | 0.78 |
| Example 23 | Pigment dispersion liquid 1 | 57.84 | B-3 | 7.03 | C-2 | 7.15 | E-2 | 2.06 | F-3 | 0.78 |
| Example 24 | Pigment dispersion liquid 1 | 57.84 | B-4 | 7.03 | C-2 | 7.15 | E-2 | 2.06 | F-3 | 0.78 |
| Example 25 | Pigment dispersion liquid 1 | 57.84 | B-6 | 7.03 | C-2 | 7.15 | E-2 | 2.06 | F-3 | 0.78 |
| Example 26 | Pigment dispersion liquid 1 | 57.84 | B-7 | 7.03 | C-2 | 7.15 | E-2 | 2.06 | F-3 | 0.78 |
| Example 27 | Pigment dispersion liquid 1 | 57.84 | B-8 | 7.03 | C-2 | 7.15 | E-2 | 2.06 | F-3 | 0.78 |
| Example 28 | Pigment dispersion liquid 1 | 57.84 | B-9 | 7.03 | C-2 | 7.15 | E-2 | 2.06 | F-3 | 0.78 |
| Example 29 | Pigment dispersion liquid 1 | 57.84 | B-10 | 7.03 | C-2 | 7.15 | E-2 | 2.06 | F-3 | 0.78 |
| Example 30 | Pigment dispersion liquid 1 | 57.84 | B-11 | 7.03 | C-2 | 7.15 | E-2 | 2.06 | F-3 | 0.78 |
| Example 31 | Pigment dispersion liquid 1 | 57.84 | B-5 | 7.03 | C-1 | 7.15 | E-2 | 2.06 | F-3 | 0.78 |
| Example 32 | Pigment dispersion liquid 1 | 57.84 | B-5 | 7.03 | C-3 | 7.15 | E-2 | 2.06 | F-3 | 0.78 |
| Example 33 | Pigment dispersion liquid 1 | 57.84 | B-5 | 7.03 | C-4 | 7.15 | E-2 | 2.06 | F-3 | 0.78 |
| Example 34 | Pigment dispersion liquid 1 | 57.84 | B-5 | 7.03 | C-5 | 7.15 | E-2 | 2.06 | F-3 | 0.78 |
| Example 35 | Pigment dispersion liquid 1 | 57.84 | B-5 | 7.03 | C-2 | 7.15 | E-1 | 1.03 | F-3 | 0.78 |
| Example 36 | Pigment dispersion liquid 12 | 57.84 | B-5 | 7.03 | C-2 | 7.15 | E-3 | 2.06 | F-3 | 0.78 |
| Example 37 | Pigment dispersion liquid 1 | 57.84 | B-5 | 7.03 | C-2 | 7.15 | E-2 | 2.06 | F-1 | 0.78 |
| Example 38 | Pigment dispersion liquid 12 | 57.84 | B-5 | 7.03 | C-2 | 7.15 | E-2 | 2.06 | F-2 | 0.39 |
| Comparative | Pigment dispersion liquid 10 | 57.84 | B-12 | 7.03 | C-6 | 7.15 | E-2 | 2.06 | F-3 | 0.78 |
| Example 1 | | | | | | | | | | |
| Comparative | Pigment dispersion liquid 10 | 57.84 | B-12 | 7.03 | C-4 | 7.15 | E-2 | 2.06 | F-3 | 0.78 |
| Example 2 | | | | | | | | | | |
| Comparative | Pigment dispersion liquid 4 | 57.84 | B-1 | 7.03 | C-5 | 7.15 | E-2 | 2.06 | F-3 | 0.78 |
| Example 3 | | | | | | | | | | |

TABLE 10

| | Formulation of curable composition | | | | | | Polymerizable |
|---|---|---|---|---|---|---|---|
| | Solvent | | Surfactant | | Resin A | Resin B | compound |
| | | Part by | | Part by | Tg | Tg | Shrinkage ratio |
| Table 6-2 | Type | mass | Type | mass | (° C.) | (° C.) | (%) |
| Example 1 | PGME/CyP | 13.12/12.00 | W-1 | 0.02 | 50 | 65 | 20.1 |
| Example 2 | PGME/CyP | 13.12/12.00 | W-1 | 0.02 | 45 | 65 | 20.1 |
| Example 3 | PGME/CyP | 13.12/12.00 | W-1 | 0.02 | 15 | 65 | 20.1 |
| Example 4 | PGME/CyP | 13.12/12.00 | W-1 | 0.02 | 30 | 65 | 20.1 |
| Example 5 | PGME/CyP | 13.12/12.00 | W-1 | 0.02 | 35 | 65 | 20.1 |
| Example 6 | PGME/CyP | 13.12/12.00 | W-1 | 0.02 | 38 | 65 | 20.1 |
| Example 7 | PGME/CyP | 13.12/12.00 | W-1 | 0.02 | 40 | 65 | 20.1 |
| Example 8 | PGME/CyP | 13.12/12.00 | W-1 | 0.02 | −10 | 65 | 20.1 |
| Example 9 | PGME/CyP | 13.12/12.00 | W-1 | 0.02 | −21 | 65 | 20.1 |
| Example 10 | PGME/CyP | 13.12/12.00 | W-1 | 0.02 | 30 | 65 | 20.1 |
| Example 11 | PGME/CyP | 13.12/12.00 | W-1 | 0.02 | 50 | 65 | 20.1 |
| Example 12 | PGME/CyP | 13.12/12.00 | W-1 | 0.02 | 38 | 65 | 20.1 |
| Example 13 | PGME/CyP | 13.12/12.00 | W-1 | 0.02 | 50 | 65 | 20.1 |
| Example 14 | PGME/CyP | 13.12/12.00 | W-1 | 0.02 | 38 | 65 | 20.1 |
| Example 15 | PGME/CyP | 13.12/12.00 | W-1 | 0.02 | 50 | 65 | 20.1 |
| Example 16 | PGME/CyP | 13.12/12.00 | W-1 | 0.02 | 38 | 65 | 20.1 |
| Example 17 | PGME/CyP | 13.12/12.00 | W-1 | 0.02 | 50 | 65 | 20.1 |
| Example 18 | PGME/CyP | 13.12/12.00 | W-1 | 0.02 | 38 | 65 | 20.1 |
| Example 19 | PGME/CyP | 13.12/12.00 | W-1 | 0.02 | 50 | 65 | 20.1 |
| Example 20 | PGME/CyP | 13.12/12.00 | W-1 | 0.02 | 38 | 65 | 20.1 |
| Example 21 | PGME/CyP | 13.12/12.00 | W-1 | 0.02 | 50 | 112 | 20.1 |
| Example 22 | PGME/CyP | 13.12/12.00 | W-1 | 0.02 | 50 | 77 | 20.1 |
| Example 23 | PGME/CyP | 13.12/12.00 | W-1 | 0.02 | 50 | 50 | 20.1 |
| Example 24 | PGME/CyP | 13.12/12.00 | W-1 | 0.02 | 50 | 82 | 20.1 |
| Example 25 | PGME/CyP | 13.12/12.00 | W-1 | 0.02 | 50 | 63 | 20.1 |
| Example 26 | PGME/CyP | 13.12/12.00 | W-1 | 0.02 | 50 | 6 | 20.1 |
| Example 27 | PGME/CyP | 13.12/12.00 | W-1 | 0.02 | 50 | 26 | 20.1 |
| Example 28 | PGME/CyP | 13.12/12.00 | W-1 | 0.02 | 50 | 70 | 20.1 |
| Example 29 | PGME/CyP | 13.12/12.00 | W-1 | 0.02 | 50 | 72 | 20.1 |
| Example 30 | PGME/CyP | 13.12/12.00 | W-1 | 0.02 | 50 | 69 | 20.1 |
| Example 31 | PGME/CyP | 13.12/12.00 | W-1 | 0.02 | 50 | 65 | 16.3 |
| Example 32 | PGME/CyP | 13.12/12.00 | W-1 | 0.02 | 50 | 65 | 14.8 |
| Example 33 | PGME/CyP | 13.12/12.00 | W-1 | 0.02 | 50 | 65 | 5.9 |
| Example 34 | PGME/CyP | 13.12/12.00 | W-1 | 0.02 | 50 | 65 | 0.5 |
| Example 35 | PGME/CyP | 13.12/12.00 | W-1 | 0.02 | 50 | 65 | 20.1 |
| Example 36 | PGME/CyP | 13.12/12.00 | W-1 | 0.02 | 38 | 65 | 20.1 |
| Example 37 | PGME/CyP | 13.12/12.00 | W-1 | 0.02 | 50 | 65 | 20.1 |
| Example 38 | PGME/CyP | 13.12/12.00 | W-1 | 0.02 | 38 | 65 | 20.1 |
| Comparative | PGME/CyP | 13.12/12.00 | W-1 | 0.02 | 30 | 80 | 8.0 |
| Example 1 | | | | | | | |
| Comparative | PGME/CyP | 13.12/12.00 | W-1 | 0.02 | 30 | 80 | 5.9 |
| Example 2 | | | | | | | |
| Comparative | PGME/CyP | 13.12/12.00 | W-1 | 0.02 | 30 | 112 | 0.5 |
| Example 3 | | | | | | | |

TABLE 11

| | HSP distance | | | |
|---|---|---|---|---|
| | | HSP distance | HSP distance | HSP |
| | HSP distance | A between | B between | distance |
| | between | resin A and | resin B and | A − HSP |
| | resin A and | polymerizable | polymerizable | distance |
| Table 6-3 | resin B | compound | compound | B |
| Example 1 | 3.6 | 3.4 | 2.0 | 1.4 |
| Example 2 | 2.6 | 2.7 | 2.0 | 0.7 |
| Example 3 | 2.3 | 2.7 | 2.0 | 0.7 |
| Example 4 | 2.5 | 3.3 | 2.0 | 1.4 |
| Example 5 | 2.4 | 3.2 | 2.0 | 1.2 |
| Example 6 | 2.3 | 3.3 | 2.0 | 1.3 |
| Example 7 | 2.2 | 3.6 | 2.0 | 1.6 |
| Example 8 | 1.6 | 2.9 | 2.0 | 0.9 |
| Example 9 | 1.7 | 3.0 | 2.0 | 1.0 |
| Example 10 | 1.7 | 2.6 | 2.0 | 0.6 |
| Example 11 | 3.6 | 3.4 | 2.0 | 1.4 |
| Example 12 | 2.3 | 3.3 | 2.0 | 1.3 |
| Example 13 | 3.6 | 3.4 | 2.0 | 1.4 |
| Example 14 | 2.3 | 3.3 | 2.0 | 1.3 |
| Example 15 | 3.6 | 3.4 | 2.0 | 1.4 |
| Example 16 | 2.3 | 3.3 | 2.0 | 1.3 |
| Example 17 | 3.6 | 3.4 | 2.0 | 1.4 |
| Example 18 | 2.3 | 3.3 | 2.0 | 1.3 |
| Example 19 | 3.6 | 3.4 | 2.0 | 1.4 |
| Example 20 | 2.3 | 3.3 | 2.0 | 1.3 |
| Example 21 | 2.3 | 3.4 | 2.9 | 0.5 |
| Example 22 | 3.0 | 3.4 | 2.6 | 0.8 |
| Example 23 | 2.4 | 3.4 | 2.7 | 0.7 |
| Example 24 | 2.7 | 3.4 | 2.5 | 0.9 |
| Example 25 | 3.8 | 3.4 | 2.1 | 1.3 |
| Example 26 | 5.0 | 3.4 | 2.4 | 1.0 |
| Example 27 | 2.7 | 3.4 | 1.7 | 1.7 |
| Example 28 | 3.5 | 3.4 | 2.0 | 1.5 |
| Example 29 | 3.3 | 3.4 | 1.9 | 1.5 |
| Example 30 | 3.7 | 3.4 | 2.0 | 1.4 |
| Example 31 | 3.6 | 3.1 | 2.8 | 0.3 |
| Example 32 | 3.6 | 3.3 | 1.9 | 1.4 |
| Example 33 | 3.6 | 6.5 | 3.7 | 2.8 |
| Example 34 | 3.6 | 10.3 | 8.7 | 1.6 |
| Example 35 | 3.6 | 3.4 | 2.0 | 1.4 |
| Example 36 | 2.3 | 3.3 | 2.0 | 1.3 |
| Example 37 | 3.6 | 3.4 | 2.0 | 1.4 |
| Example 38 | 2.3 | 3.3 | 2.0 | 1.3 |
| Comparative | 1.5 | 9.3 | 8.0 | 1.3 |
| Example 1 | | | | |
| Comparative | 1.5 | 2.7 | 3.2 | −0.5 |
| Example 2 | | | | |
| Comparative | 3.7 | 6.7 | 9.5 | −2.8 |
| Example 3 | | | | |

TABLE 12

| | Formulation of curable composition | | | | | | | | | |
|---|---|---|---|---|---|---|---|---|---|---|
| | | | | | | | | | Thermal | |
| | | | | | Polymerizable | | Photopolymerization | | crosslinking | |
| | Pigment dispersion liquid | | Resin H | | compound | | initiator | | compound | |
| | | Part by | | Part by | | Part by | | Part by | | Part by |
| Table 7-1 | Type | mass | Type | mass | Type | mass | Type | mass | Type | mass |
| Example 101 | Pigment dispersion | 57.84 | H-1 | 7.03 | C-2 | 7.15 | E-2 | 2.06 | F-3 | 0.78 |
| | liquid 6 | | | | | | | | | |
| Example 102 | Pigment dispersion | 57.84 | H-2 | 7.03 | C-2 | 7.15 | E-2 | 2.06 | F-3 | 0.78 |
| | liquid 6 | | | | | | | | | |
| Example 103 | Pigment dispersion | 57.84 | H-3 | 7.03 | C-2 | 7.15 | E-2 | 2.06 | F-3 | 0.78 |
| | liquid 6 | | | | | | | | | |
| Example 104 | Pigment dispersion | 57.84 | H-4 | 7.03 | C-2 | 7.15 | E-2 | 2.06 | F-3 | 0.78 |
| | liquid 6 | | | | | | | | | |
| Comparative | Pigment dispersion | 57.84 | B-12 | 7.03 | C-6 | 7.15 | E-2 | 2.06 | F-3 | 0.78 |
| Example 101 | liquid 10 | | | | | | | | | |

TABLE 13

| | Formulation of curable composition | | | | Resin A | Resin H | | |
|---|---|---|---|---|---|---|---|---|
| | Solvent | | Surfactant | | Dissolution | Dissolution | HSP distance | Rate |
| | | Part by | | Part by | rate T1 | rate T2 | HSP distance between resin A | ratio |
| Table 7-2 | Type | mass | Type | mass | (μm/sec) | (μm/sec) | and resin H | T2/T1 |
| Example 101 | PGME/CyP | 13.12/12.00 | W-1 | 0.02 | 0.05 | 0.85 | 2.7 | 17.0 |
| Example 102 | PGME/CyP | 13.12/12.00 | W-1 | 0.02 | 0.05 | 0.75 | 3.4 | 15.0 |
| Example 103 | PGME/CyP | 13.12/12.00 | W-1 | 0.02 | 0.05 | 0.60 | 2.9 | 12.0 |
| Example 104 | PGME/CyP | 13.12/12.00 | W-1 | 0.02 | 0.05 | 0.50 | 3.3 | 10.0 |
| Comparative | PGME/CyP | 13.12/12.00 | W-1 | 0.02 | 0.35 | 0.25 | 1.5 | 0.7 |
| Example 101 | | | | | | | | |

### Evaluation

The curable composition was evaluated by the following method.

### [Evaluation of Alignment Suitability]

Alignment suitability was evaluated by the following procedure to evaluate the ease of the registration between the support and the exposure mask in the exposure step.

A silicon wafer (8 inches) having an alignment mark in which L1=60 μm in FIG. 1 and H1=0.6 m in FIG. 2 was prepared as a substrate (support), and the curable composition of each of Comparative Examples or Examples was applied onto this substrate so that the film thickness of the obtained curable composition layer was 3.5 μm. The curable composition layer was disposed to cover the alignment mark. That is, the curable composition layer was disposed on the alignment mark.

The coated substrate was baked on a hot plate at 90° C. for 2 minutes to produce a substrate with a curable composition layer (step 1 or step 11). Thereafter, the wafer was placed in a semiconductor exposure device (FPA-5510 iZs, manufactured by Canon Inc.), and it was confirmed whether or not the alignment was possible before the exposure treatment using a mask corresponding to the alignment mark of the substrate (step 2 or step 12).

Based on the alignment mark on the substrate, those which could be registered before the exposure were evaluated as having alignment suitability, and those which could not be registered were evaluated as not having alignment suitability, since it was difficult to check the position of the alignment mark on the substrate.

### [Production of Cured Film (First Embodiment)]

A cured film in the first embodiment (evaluation using each curable composition described in Table 6) was produced by the following procedure.

The curable composition layer was exposed to an illuminance of 10,000 W/m² and an exposure amount of 1,000 mJ/cm² over the entire surface of each substrate with a curable composition layer, on which the registration was performed in [Evaluation of alignment suitability], using FPA-5510iZs (manufactured by Canon Inc.). In addition, for those which could not be registered, the registration step was skipped, and the entire surface of the substrate was exposed (step 3).

After the exposure, puddle development was carried out using an alkali developer CD-2000 (manufactured by Fujifilm Electronic Materials Co., Ltd.) at 23° C. for 60 seconds. Next, the coating film was rinsed by spin showering and was washed with pure water (step 4).

Subsequently, the substrate was heated at 220° C. for 5 minutes using a hot plate to obtain a substrate with a cured film (step 5).

### [Production of Cured Film (Second Embodiment)]

A cured film in the second embodiment (evaluation using each curable composition described in Table 7) was produced by the following procedure.

The curable composition layer was exposed to an illuminance of 10,000 W/m² and an exposure amount of 1,000 mJ/cm² over the entire surface of each substrate with a curable composition layer, on which the registration was performed in [Evaluation of alignment suitability], using FPA-5510iZs (manufactured by Canon Inc.). In addition, for those which could not be registered, the registration step was skipped, and the entire surface of the substrate was exposed (step 13).

After the exposure, puddle development was carried out using an alkali developer CD-2000 (manufactured by Fujifilm Electronic Materials Co., Ltd.) at 23° C. for 60 seconds. Thereafter, the substrate was rinsed by spin showering, washed with pure water, and naturally dried to obtain a substrate with a cured film (step 14).

### [Evaluation of Reflectivity]

With respect to the substrate with a cured film, produced as described in [Production of cured film (first embodiment)] or [Production of cured film (second embodiment)], light having a wavelength of 350 to 1,200 nm was incident at an incidence angle of 5° using a VAR unit of a spectrometer V7200 (product name) manufactured by JASCO Corporation, and reflectivity was evaluated from the reflectivity spectrum of the reflection angle of 5° obtained.

Specifically, an average value of specular reflectivity of light having a wavelength of 400 to 700 nm was evaluated as a standard for evaluation, and the evaluation was performed according to the following classification. In addition, in a case of angles of 450 and 60°, the evaluation was performed in the same manner as in the case of the angle of 5°.

In the following evaluation standard, in terms of practical use, an evaluation of “3” or higher is preferable, and an evaluation of “4” or higher is more preferable.

### (Evaluation Standard: Angle of 5°)

“5”: average value of specular reflectivity was less than 0.3%.
“4”: average value of specular reflectivity was 0.3% or more and less than 1.0%.
“3”: average value of specular reflectivity was 1.0% or more and less than 2.0%.
“2”: average value of specular reflectivity was 2.0% or more and less than 5.0%.
“1”: average value of specular reflectivity was 5.0% or more.

### (Evaluation Standard: Angle of 45°)

“5”: average value of specular reflectivity was less than 1%.
“4”: average value of specular reflectivity was 1% or more and less than 3%.
“3”: average value of specular reflectivity was 3% or more and less than 5%.
“2”: average value of specular reflectivity was 5% or more and less than 10%.
“1”: average value of specular reflectivity was 10% or more.

### (Evaluation Standard: Angle of 60°)

“5”: average value of specular reflectivity was less than 3%.
“4”: average value of specular reflectivity was 3% or more and less than 6%.
“3”: average value of specular reflectivity was 6% or more and less than 10%.
“2”: average value of specular reflectivity was 10% or more and less than 15%.
“1”: average value of specular reflectivity was 15% or more.

### [Evaluation of Light Shielding Properties (Measurement of OD)]

A substrate with a cured film was produced in the same manner as in the section of [Production of cured film (first embodiment)] or [Production of cured film (second embodiment)] described above, except that a glass substrate was used instead of the silicon wafer.

For the substrate with a cured film, a transmittance spectrum in a range of 400 to 1,100 nm was measured using a spectrophotometer U-4100 (manufactured by Hitachi High-Tech Corporation) and an integrating sphere type light-receiving unit.

An OD value was calculated from the following expression (01) based on the average value of the transmittance (%) at a wavelength of 400 to 700 nm, and the evaluation was performed based on the following classification.

$$OD value = - log 10 ( transmittance / 100 ) \qquad Expression ( O 1 )$$

In the following evaluation standard, 2.0 or more is preferable, 2.5 or more is more preferable, and 3.0 or more is still more preferable.

### (Evaluation Standard)

“5”: OD value was 3.5 or more.
“4”: OD value was 3.0 or more and less than 3.5.
“3”: OD value was 2.5 or more and less than 3.0.
“2”: OD value was 2.0 or more and less than 2.5.
“1”: OD value was less than 2.0.

### [Evaluation of Film Surface Roughness]

An arithmetic average surface roughness Ra, an average length Rsm of elements, and a root-mean-square tilt RΔq were measured according to JIS-B-0601: 2013 to evaluate a surface roughness of the curable composition layer and the cured film.

As a specific procedure, using a 3D laser measuring microscope (LEXT OLS5000 manufactured by Olympus Corporation), a surface shape of the produced cured film was measured with the substrate with a curable composition layer produced in [Evaluation of alignment suitability] described above (the substrate after the step 1 or the step 11) and the substrate with a cured film produced in [Evaluation of reflectivity] described above (the substrate after the step 5 or the step 14) at a magnification of 100 times with an objective lens, and a surface image file was obtained. The observation measurement range (lateral) in the measurement of the surface shape of the sample was set to 129 μm×129 μm.

Subsequently, analysis application was activated, the obtained surface image file was displayed, and then inclination correction was performed. The line thickness window was displayed, a horizontal line was selected from the measurement line button, the horizontal line was displayed at any place on the surface image, and the OK button was pressed to obtain the numerical values of Ra, Rsm, and RΔq. Furthermore, horizontal lines were displayed at four different positions in the surface image to obtain the numerical values of Ra, Rsm, and RΔq. An average value of the obtained five numerical values was calculated and defined as each value of Ra, Rsm, and RΔq.

### Result

The results of each of the above-described evaluations are shown in Table 8 and Table 9. Table 8 shows the evaluation results of each composition in the first embodiment, and Table 9 shows the evaluation results of each composition in the second embodiment.

TABLE 14

| | Evaluation | | | | |
|---|---|---|---|---|---|
| | Alignment | | Specular reflectivity | | |
| Table 8 | suitability | OD | 5° | 45° | 60° |
| Example 1 | Y | 3 | 5 | 5 | 4 |
| Example 2 | Y | 3 | 5 | 4 | 4 |
| Example 3 | Y | 3 | 5 | 4 | 4 |
| Example 4 | Y | 3 | 5 | 5 | 4 |
| Example 5 | Y | 3 | 5 | 5 | 4 |
| Example 6 | Y | 3 | 5 | 5 | 4 |
| Example 7 | Y | 3 | 5 | 5 | 4 |
| Example 8 | Y | 3 | 4 | 3 | 3 |
| Example 9 | Y | 3 | 4 | 3 | 3 |
| Example 10 | Y | 3 | 4 | 3 | 3 |
| Example 11 | Y | 5 | 5 | 5 | 4 |
| Example 12 | Y | 5 | 5 | 5 | 4 |
| Example 13 | Y | 3 | 5 | 5 | 4 |
| Example 14 | Y | 3 | 5 | 5 | 4 |
| Example 15 | Y | 4 | 5 | 5 | 4 |
| Example 16 | Y | 4 | 5 | 5 | 4 |
| Example 17 | Y | 3 | 5 | 5 | 4 |
| Example 18 | Y | 3 | 5 | 5 | 4 |
| Example 19 | Y | 5 | 5 | 5 | 4 |
| Example 20 | Y | 3 | 5 | 5 | 4 |
| Example 21 | Y | 3 | 5 | 4 | 4 |
| Example 22 | Y | 3 | 5 | 4 | 4 |
| Example 23 | Y | 3 | 5 | 4 | 4 |
| Example 24 | Y | 3 | 5 | 4 | 4 |
| Example 25 | Y | 3 | 5 | 5 | 4 |
| Example 26 | Y | 3 | 5 | 5 | 4 |
| Example 27 | Y | 3 | 5 | 5 | 4 |
| Example 28 | Y | 3 | 5 | 5 | 4 |
| Example 29 | Y | 3 | 5 | 5 | 4 |
| Example 30 | Y | 3 | 5 | 5 | 4 |
| Example 31 | Y | 3 | 5 | 4 | 4 |
| Example 32 | Y | 3 | 5 | 5 | 4 |
| Example 33 | Y | 3 | 3 | 3 | 3 |
| Example 34 | Y | 3 | 3 | 3 | 3 |
| Example 35 | Y | 3 | 5 | 5 | 4 |
| Example 36 | Y | 5 | 5 | 5 | 4 |
| Example 37 | Y | 3 | 5 | 5 | 4 |
| Example 38 | Y | 5 | 5 | 5 | 4 |
| Comparative Example 1 | Y | 3 | 2 | 2 | 2 |
| Comparative Example 2 | Y | 3 | 1 | 1 | 1 |
| Comparative Example 3 | Y | 3 | 1 | 1 | 1 |

TABLE 15

| | Evaluation | | | | |
|---|---|---|---|---|---|
| | Alignment | | Specular reflectivity | | |
| Table 9 | suitability | OD | 5° | 45° | 60° |
| Example 101 | Y | 3 | 4 | 4 | 3 |
| Example 102 | Y | 3 | 4 | 4 | 3 |
| Example 103 | Y | 3 | 3 | 3 | 3 |
| Example 104 | Y | 3 | 3 | 3 | 3 |
| Comparative Example 101 | Y | 3 | 1 | 1 | 1 |

Regarding the arithmetic average surface roughness Ra(a), the average length Rsm(a) of elements, and the root-mean-square tilt RΔq(a) of the curable composition layer, in Example 6, each of the values was 0.04 μm, 7 μm, and 3°; in Comparative Example 1, each of the values was 0.01 μm, 2 μm, and 1°; in Example 101, each of the values was 0.01 μm, 3 μm, and 1°; and in Comparative Example 101, each of the values was 0.01 μm, 2 μm, and 1°.

Regarding the arithmetic average surface roughness Ra(b), the average length Rsm(b) of elements, and the root-mean-square tilt RΔq(b) of the cured film, in Example 6, each of the values was 0.17 μm, 6 μm, and 15°; in Comparative Example 1, each of the values was 0.01 am, 2 μm, and 1°; in Example 101, each of the values was 0.06 μm, 10 μm, and 5°; and in Comparative Example 101, each of the values was 0.01 μm, 2 μm, and 1°.

In a case where the curable compositions of Examples 1 to 38 and Examples 101 to 104 were diluted at a proportion of 0.1 parts by mass of the curable composition and 10 parts by mass of PGMEA, and then measured with a particle size distribution analyzer Nanotrac UPA (manufactured by MicrotracBEL Corp.), in the obtained (volume-based) particle size distribution, a proportion of particles having a particle size of 200 nm or more was 3% or less in all of Examples.

In addition, the evaluations of Examples 201 to 205 were performed in the same manner as in Example 6, except that the heating temperature in the step 5 was changed. The results are shown in Table 10. Example 203 is the same example as Example 6.

TABLE 16

| | Step 5 | Evaluation | | | | |
|---|---|---|---|---|---|---|
| | Post-baking | | Physical properties after heat curing at 400 to 700 nm | | | |
| | temperature | Alignment | | 5° specular | 45° specular | 60° specular |
| Table 10 | (° C.) | suitability | OD | reflectivity | reflectivity | reflectivity |
| Example 201 | 180 | Y | 3 | 4 | 4 | 3 |
| Example 202 | 200 | Y | 3 | 5 | 4 | 4 |
| Example 203 | 220 | Y | 3 | 5 | 5 | 4 |
| Example 204 | 240 | Y | 3 | 5 | 5 | 5 |
| Example 205 | 260 | Y | 3 | 5 | 5 | 5 |

As shown in the table, it was found that, in the present manufacturing process, the positioning of the mask during the exposure could be easily performed, and thus the antireflection characteristics of the cured film to be obtained were excellent.

In addition, from the comparison of Examples 1, 11, 13, and 15, it was found that, in a case where the curable composition contained a coloring material and the coloring material includes a black organic pigment, the light shielding properties were more excellent; in a case where the coloring material includes carbon black, the light shielding properties were further excellent; and in a case where the coloring material includes titanium black, the light shielding properties were particularly excellent.

From the comparison of Examples 32 to 35, it was found that, in a case where the shrinkage ratio of the curable compound defined by the expression (X) was 7% or more, the antireflection characteristics of the cured film were more excellent; and from the comparison of Examples 1 to 10, it was found that, in a case where the HSP distance between the resin A and the resin B was 2.0 MPa^{1/2} or more, the antireflection characteristics of the cured film were further excellent.

From the comparison of Examples 1 to 10, it was found that, in a case where the HSP distance between the resin A and the resin B was 2.0 to 4.0 MPa^{1/2} and the difference (HSP distance (A)−HSP distance (B)) between the HSP distance (A) and the HSP distance (B) was 1.0 MPa^{1/2} or more, the antireflection characteristics (specular reflectivity with respect to the incidence ray at 45°) of the cured film were more excellent.

From the comparison of Examples 101 to 104, it was found that, in a case where the ratio T2/T1 of the dissolution rate T2 of the resin H in the developer to the dissolution rate T1 of the resin C in the developer was 15.0 or more, the antireflection characteristics (specular reflectivity with respect to the incidence ray at 5° and 45°) of the cured film were more excellent.

In addition, from the comparison of Examples 201 to 205, it was found that, in a case where the heating temperature in the step 5 was 180° C. or higher, the antireflection characteristics of the cured film were more excellent; in a case where the heating temperature in the step 5 was 200° C. or higher, the antireflection characteristics of the cured film were still more excellent; in a case where the heating temperature in the step 5 was 220° C. or higher, the antireflection characteristics of the cured film were particularly excellent; and in a case where the heating temperature in the step 5 was 240° C. or higher, the antireflection characteristics of the cured film were most excellent.

In addition, in a case where the evaluation described in [Evaluation of reflectivity] and [Evaluation of light shielding properties (measurement of OD)] above was performed on a cured film obtained by carrying out each of the procedures described in [Production of cured film (second embodiment)] above using the curable composition of each of Examples shown in Table 7 and further heating the cured film using a hot plate at 220° C. for 5 minutes, it was found that the same effects as those of each of Examples shown in Table 9 were obtained.

### EXPLANATION OF REFERENCES

10: alignment mark
12: square frame portion
14: vertical line
16: horizontal line
18: support

What is claimed is:

1. A method for manufacturing a cured film, comprising:
a step 1 of forming a curable composition layer on a support;
a step 2 of performing registration between the support and an exposure mask;
a step 3 of exposing the curable composition layer through the exposure mask;
a step 4 of performing a development treatment on the curable composition layer after the exposure to form a cured film in a patterned shape; and
a step 5 of performing a heating treatment on the patterned cured film,
wherein the curable composition contains a resin A, a resin B, and a polymerizable compound,
an HSP distance between the resin A and the resin B is more than 1.5 MPa^{1/2}, and
an HSP distance (A) between the resin A and the polymerizable compound is larger than an HSP distance (B) between the resin B and the polymerizable compound.

2. The method for manufacturing a cured film according to claim 1,
wherein at least one of a glass transition temperature of the resin A or a glass transition temperature of the resin B is a temperature lower than a heating temperature during the heating treatment by 120° C. or higher.

3. The method for manufacturing a cured film according to claim 1,
wherein a glass transition temperature of the resin B is 0° C. to 70° C.

4. The method for manufacturing a cured film according to claim 1,
wherein the resin A contains a repeating unit A1 having an acid group and a repeating unit A2 having at least one group of a polyoxyalkylene group having an average addition number of 3 or more or a polyoxyalkylene carbonyl group having an average addition number of 3 or more,
a content of the repeating unit A2 is 35% by mass or more with respect to all repeating units of the resin A,
the resin B contains a repeating unit B1 derived from a monomer selected from the group consisting of an alkyl acrylate and an alkyl methacrylate, a repeating unit B2 having a hydroxyl group, and a repeating unit B3 having a carboxylic acid group, and
a content of the repeating unit B1 is 60% by mass or more with respect to all repeating units of the resin B.

5. The method for manufacturing a cured film according to claim 4,
wherein an acid value of the resin A is 50 mgKOH/g or more.

6. The method for manufacturing a cured film according to claim 1,
wherein a shrinkage ratio of the polymerizable compound, which is defined by an expression (X), is 7% or more,
$$( 1 - ρ M / ρ P ) \times 100 … the expression ( X ) ,$$
in the expression (X),
ρM represents a specific gravity of the polymerizable compound measured in accordance with JIS-K-2249, and
ρP represents a specific gravity of a cured substance of the polymerizable compound measured in accordance with JIS-K-2249.

7. The method for manufacturing a cured film according to claim 1,
wherein the curable composition further contains a coloring material.

8. The method for manufacturing a cured film according to claim 7,
wherein the coloring material includes a black coloring material.

9. The method for manufacturing a cured film according to claim 8,
wherein the black coloring material includes a black organic pigment.

10. A method for manufacturing a cured film, comprising:
a step 11 of forming a curable composition layer on a support;
a step 12 of performing registration between the support and an exposure mask;
a step 13 of exposing the curable composition layer through the exposure mask; and
a step 14 of performing a development treatment on the curable composition layer after the exposure to form a cured film in a patterned shape,
wherein the curable composition contains a resin C, a resin H, and a polymerizable compound,
an HSP distance between the resin C and the resin H is more than 1.5 MPa^{1/2}, and
a ratio T2/T1 of a dissolution rate T2 of the resin H in a developer used in the development treatment to a dissolution rate T1 of the resin C in the developer is 10.0 or more.

11. The method for manufacturing a cured film according to claim 10,
wherein the resin C contains a repeating unit C1 having an acid group and a repeating unit C2 having at least one group of a polyoxyalkylene group having an average addition number of 3 or more or a polyoxyalkylene carbonyl group having an average addition number of 3 or more,
a content of the repeating unit C2 is 35% by mass or more with respect to all repeating units of the resin C,
the resin H is an acrylic resin or a methacrylic resin, and
an acid value of the resin H is higher than an acid value of the resin C by 70 mgKOH/g or more.

12. The method for manufacturing a cured film according to claim 10,
wherein an acid value of the resin C is 50 mgKOH/g or more.

13. The method for manufacturing a cured film according to claim 10,
wherein an acid value of the resin H is 140 mgKOH/g or more.

14. The method for manufacturing a cured film according to claim 10,
wherein the curable composition further contains a coloring material.

15. The method for manufacturing a cured film according to claim 14,
wherein the coloring material includes a black coloring material.

16. The method for manufacturing a cured film according to claim 15,
wherein the black coloring material includes a black organic pigment.

17. The method for manufacturing a cured film according to claim 2,
wherein a glass transition temperature of the resin B is 0° C. to 70° C.

18. The method for manufacturing a cured film according to claim 2,
wherein the resin A contains a repeating unit A1 having an acid group and a repeating unit A2 having at least one group of a polyoxyalkylene group having an average addition number of 3 or more or a polyoxyalkylene carbonyl group having an average addition number of 3 or more,
a content of the repeating unit A2 is 35% by mass or more with respect to all repeating units of the resin A,
the resin B contains a repeating unit B1 derived from a monomer selected from the group consisting of an alkyl acrylate and an alkyl methacrylate, a repeating unit B2 having a hydroxyl group, and a repeating unit B3 having a carboxylic acid group, and
a content of the repeating unit B1 is 60% by mass or more with respect to all repeating units of the resin B.

19. The method for manufacturing a cured film according to claim 2,
wherein an acid value of the resin A is 50 mgKOH/g or more.

20. The method for manufacturing a cured film according to claim 2,
wherein a shrinkage ratio of the polymerizable compound, which is defined by an expression (X), is 7% or more,
$$( 1 - ρ M / ρ P ) \times 100 … the expression ( X ) ,$$
in the expression (X),
ρM represents a specific gravity of the polymerizable compound measured in accordance with JIS-K-2249, and
ρP represents a specific gravity of a cured substance of the polymerizable compound measured in accordance with JIS-K-2249.
